(19) United States
(12) Patent Application Publication
(10) Pub. No.: US 2025/0031474 A1
(43) Pub. Date: Jan. 23, 2025

(54) LIGHT DETECTION APPARATUS AND ELECTRONIC DEVICE

(71) Applicant: SONY SEMICONDUCTOR SOLUTIONS CORPORATION, KANAGAWA (JP)

(72) Inventors: TAKAFUMI MORIKAWA, KANAGAWA (JP); KENGO NAGATA, KANAGAWA (JP); TOMOMI ITO, KANAGAWA (JP); ATSUSHI MASAGAKI, KANAGAWA (JP); KAZUYOSHI YAMASHITA, KANAGAWA (JP); SHOTA MATSUYAMA, KANAGAWA (JP); AKIRA DAICHO, KANAGAWA (JP); KAZUHIRO YONEDA, KANAGAWA (JP); JUNICHI MATSUO, KANAGAWA (JP); YUTA NAKAMOTO, KANAGAWA (JP); HIROSHI FUKUNAGA, KANAGAWA (JP); KYOSUKE ITO, KANAGAWA (JP); YUSUKE OTAKE, KANAGAWA (JP); TOSHIFUMI WAKANO, KANAGAWA (JP)

(21) Appl. No.: 18/715,347

(22) PCT Filed: Nov. 28, 2022
(86) PCT No.: PCT/JP2022/043792

§ 371 Date: May 31, 2024

(30) Foreign Application Priority Data
Dec. 8, 2021 (JP) 2021-199270

(51) Int. Cl. H01L 27/146

(52) U.S. Cl. CPC H01L 27/1463; H01L 27/14636; H01L 27/1464; H01L 27/14645

(57) ABSTRACT

To provide a technique for improving image quality. A light detection apparatus includes: a semiconductor layer including a first surface and a second surface mutually positioned on opposite sides in a thickness direction; a plurality of photoelectric conversion regions provided on the semiconductor layer so as to be adjacent to each other via a separation region that stretches in the thickness direction of the semiconductor layer; a transistor provided for each of the photoelectric conversion regions on the side of the first surface of the semiconductor layer; and a transparent electrode which is provided on the side of the second surface of the semiconductor layer and to which a potential is applied. In addition, the separation region includes a conductor which stretches in the thickness direction of the semiconductor layer and the conductor is electrically connected on the side of the second surface of the semiconductor layer to the transparent electrode.

### TECHNICAL FIELD

The present technique (technique according to the present disclosure) relates to a light detection apparatus and an electronic device, and in particular, relates to a technique that is effectively applied to a light detection apparatus including a photoelectric conversion unit partitioned by an embedded separation region and to an electronic device provided with the light detection apparatus.

### BACKGROUND ART

A light detection apparatus such as a solid-state imaging apparatus or a ranging apparatus includes a plurality of photoelectric conversion regions which are provided on a semiconductor layer and which are partitioned by a separation region. PTL 1 discloses an embedded separation region in which a silicon oxide film is embedded as an embedding material in an excavated portion that stretches in a thickness direction of a semiconductor layer as a separation region that partitions a photoelectric conversion region.

### CITATION LIST

### Patent Literature

### [PTL 1]

JP 2011-222900A

### SUMMARY

### Technical Problem

A capacitive coupling of a parasitic capacitance occurs even in a light detection apparatus in which a photoelectric conversion region is partitioned by an embedded separation region. Since the capacitive coupling of a parasitic capacitance may cause deterioration in image quality, there is room for improvement in terms of reliability.

An object of the present technique is to provide a technique that enables image quality to be improved.

### Solution to Problem

(1) A light detection apparatus according to an aspect of the present technique includes:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer;
a transistor provided for each of the photoelectric conversion regions on the side of the first surface of the semiconductor layer; and
a transparent electrode which is provided on the side of the second surface of the semiconductor layer and to which a potential is applied.

In addition, the separation region includes a conductor which stretches in the thickness direction of the semiconductor layer, and the conductor is electrically connected to the transparent electrode on the side of the second surface of the semiconductor layer.

(2) A light detection apparatus according to another aspect of the present technique includes:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer; and
a transistor provided for each of the photoelectric conversion units on the side of the first surface of the semiconductor layer.

In addition, the separation region includes a floating conductor which stretches in the thickness direction of the semiconductor layer and which is in an electrically floating state.

(3) A light detection apparatus according to another aspect of the present technique includes:
a semiconductor layer including a first surface and a second surface mutually positioned on opposite sides in a thickness direction; and
a plurality of photoelectric conversion regions provided on the semiconductor layer so as to be adjacent to each other via a separation region that stretches in the thickness direction of the semiconductor layer.

In addition, each of the plurality of photoelectric conversion regions includes:
a photoelectric conversion unit provided on the semiconductor layer;
a well region provided on the side of the first surface of the semiconductor layer so as to overlap with the photoelectric conversion unit in a plan view; and
a transistor provided in the well region.

In addition, the separation region includes a conductor which stretches in the thickness direction of the semiconductor layer, and
the well region of each of the photoelectric conversion regions which are adjacent to each other via the separation region is electrically connected via the conductor of the separation region.

(4) A light detection apparatus according to another aspect of the present technique includes:
a semiconductor layer including a first surface and a second surface mutually positioned on opposite sides in a thickness direction; and
a pixel array portion in which a pixel including a photoelectric conversion region partitioned by a separation region that stretches in the thickness direction of the semiconductor layer is arranged in plurality in a two-dimensional planar pattern on the semiconductor layer.

In addition, the photoelectric conversion region includes:
a photoelectric conversion unit provided on the semiconductor layer; and
a transistor provided on the side of the first surface of the semiconductor layer.

Furthermore, the separation region includes:
a conductor that stretches in the thickness direction of the semiconductor layer, wherein the conductor is electrically connected in a periphery of the pixel array portion to a wiring to which a potential is applied.

(5) A light detection apparatus according to another aspect of the present technique includes:
a semiconductor layer including a first surface and a second surface mutually positioned on opposite sides in a thickness direction;
a separation region provided on the semiconductor layer;
first and second transistors of which respective main electrode regions are provided so as to be adjacent to each other via the separation region on the side of the first surface of the semiconductor layer;
an insulating layer provided so as to cover the first and second transistors on the side of the first surface of the semiconductor layer;
first and second contact electrodes which are provided on the insulating layer and which are respectively individually electrically connected to the respective main electrode regions of the first and second transistors; and
a barrier conductor provided between the first contact electrode and the second contact electrode.

(6) An electronic device according to another aspect of the present technique includes:
the light detection apparatus described above; and an optical system configured to form an image of image light from a subject in the light detection apparatus.

### BRIEF DESCRIPTION OF DRAWINGS

FIG. 1 is a plan layout view schematically showing a configuration example of a solid-state imaging apparatus according to a first embodiment of the present technique.

FIG. 2 is a block diagram schematically showing a configuration example of the solid-state imaging apparatus according to the first embodiment of the present technique.

FIG. 3 is an equivalent circuit diagram showing a configuration example of a pixel of the solid-state imaging apparatus according to the first embodiment of the present technique.

FIG. 4 is a plan view schematically showing a planar pattern of a separation region and an arrangement pattern of a pixel transistor in a pixel array portion of the solid-state imaging apparatus according to the first embodiment of the present technique.

FIG. 5 is an enlarged plan view of a part of FIG. 4.

FIG. 6 is a longitudinal cross-sectional view schematically showing a longitudinal cross-sectional structure taken along a cut line a5-a5 in FIG. 5.

FIG. 7 is a longitudinal cross-sectional view schematically showing a cross-sectional structure taken along line b5-b5 in FIG. 5.

FIG. 8 is a longitudinal cross-sectional view schematically showing a longitudinal cross-sectional structure of a separation region according to a comparative example.

FIG. 9 is a plan layout view schematically showing a first modification of the first embodiment.

FIG. 10 is a plan layout view schematically showing a second modification of the first embodiment.

FIG. 11 is a plan layout view schematically showing a third modification of the first embodiment.

FIG. 12 is a plan layout view schematically showing a fourth modification of the first embodiment.

FIG. 13 is a longitudinal cross-sectional view schematically showing a longitudinal cross-sectional structure of a solid-state imaging apparatus according to a second embodiment of the present technique.

FIG. 14 is a plan view schematically showing a planar pattern of a separation region and an arrangement pattern of a pixel transistor in a pixel array portion of a solid-state imaging apparatus according to a third embodiment of the present technique.

FIG. 15 is a longitudinal cross-sectional view schematically showing a longitudinal cross-sectional structure taken along a cut line a14-a14 in FIG. 14.

FIG. 16 is a diagram showing a parasitic capacitance added to the separation region according to the third embodiment.

FIG. 17 is a longitudinal cross-sectional view schematically showing a longitudinal cross-sectional structure of a separation region according to a comparative example.

FIG. 18 is a longitudinal cross-sectional view showing a depth of a floating conductor in the separation region in the third embodiment.

FIG. 19 is a longitudinal cross-sectional view schematically showing a first modification of the third embodiment.

FIG. 20 is a longitudinal cross-sectional view schematically showing a second modification of the third embodiment.

FIG. 21 is a plan view schematically showing a planar pattern of a separation region and an arrangement pattern of a pixel transistor in a pixel array portion of a solid-state imaging apparatus according to a fourth embodiment of the present technique.

FIG. 22 is a longitudinal cross-sectional view schematically showing a longitudinal cross-sectional structure taken along a cut line a21-a21 in FIG. 21.

FIG. 23 is a longitudinal cross-sectional view schematically showing a longitudinal cross-sectional structure of a separation region according to a comparative example.

FIG. 24 is a plan view showing a first modification of the fourth embodiment.

FIG. 25 is a plan view showing a second modification of the fourth embodiment.

FIG. 26 is a longitudinal cross-sectional view schematically showing a longitudinal cross-sectional structure of a solid-state imaging apparatus according to a fifth embodiment of the present technique.

FIG. 27 is a longitudinal cross-sectional view schematically showing a longitudinal cross-sectional structure of a solid-state imaging apparatus according to a sixth embodiment of the present technique.

FIG. 28 is a longitudinal cross-sectional view schematically showing a longitudinal cross-sectional structure of a solid-state imaging apparatus according to a seventh embodiment of the present technique.

FIG. 29 is a plan view schematically showing a planar pattern of a separation region and an arrangement pattern of a pixel transistor in a pixel array portion of a solid-state imaging apparatus according to an eighth embodiment of the present technique.

FIG. 30 is a cross-sectional view schematically showing a longitudinal cross-sectional structure taken along cut line a29-a29 in FIG. 29.

FIG. 31 is a longitudinal cross-sectional view schematically showing a longitudinal cross-sectional structure of a solid-state imaging apparatus according to a ninth embodiment of the present technique.

FIG. 32 is a longitudinal cross-sectional view schematically showing a longitudinal cross-sectional structure of a solid-state imaging apparatus according to a tenth embodiment of the present technique.

FIG. 33 is a plan layout view schematically showing a configuration example of a solid-state imaging apparatus according to an eleventh embodiment of the present technique.

FIG. 34A is a plan view schematically showing a planar pattern of a separation region and an arrangement pattern of a pixel transistor in a pixel array portion of the solid-state imaging apparatus according to the eleventh embodiment of the present technique.

FIG. 34B is an enlarged plan view of a part of FIG. 34A.

FIG. 34C is an equivalent circuit diagram showing a configuration example of a pixel according to the eleventh embodiment of the present technique.

FIG. 35 is a diagram showing a transverse cross-sectional pattern of a separation region on a transverse cross-section that is perpendicular to a thickness direction of a semiconductor layer.

FIG. 36 is a cross-sectional view of a main part schematically showing a longitudinal cross-sectional structure taken along cut line a34-a34 in FIG. 34a.

FIG. 37 is a cross-sectional view of a main part schematically showing a longitudinal cross-sectional structure of a solid-state imaging apparatus according to a twelfth embodiment of the present technique.

FIG. 38 is a cross-sectional view of a main part schematically showing a longitudinal cross-sectional structure of a solid-state imaging apparatus according to a thirteenth embodiment of the present technique.

FIG. 39 is a cross-sectional view of a main part schematically showing a longitudinal cross-sectional structure of a solid-state imaging apparatus according to a fourteenth embodiment of the present technique.

FIG. 40 is a cross-sectional view of a main part schematically showing a longitudinal cross-sectional structure of a solid-state imaging apparatus according to a fifteenth embodiment of the present technique.

FIG. 41 is a plan view schematically showing a planar pattern of a separation region and an arrangement pattern of a pixel transistor in a pixel array portion of the solid-state imaging apparatus according to a sixteenth embodiment of the present technique.

FIG. 42 is a longitudinal cross-sectional view schematically showing a longitudinal cross-sectional structure taken along a cut line a41-a41 in FIG. 41.

FIG. 43 is a longitudinal cross-sectional view schematically showing a longitudinal cross-sectional structure taken along a cut line b41-b41 in FIG. 41.

FIG. 44 is a longitudinal cross-sectional view for describing an effect of the sixteenth embodiment.

FIG. 45 is a longitudinal cross-sectional view schematically showing a longitudinal cross-sectional structure according to a comparative example.

FIG. 46 is a plan view schematically showing a first modification of the sixteenth embodiment.

FIG. 47 is a plan view schematically showing a second modification of the sixteenth embodiment.

FIG. 48 is a plan view schematically showing a third modification of the sixteenth embodiment.

FIG. 49 is a plan view schematically showing a fourth modification of the sixteenth embodiment.

FIG. 50 is a longitudinal cross-sectional view schematically showing a longitudinal cross-sectional structure of a solid-state imaging apparatus according to a seventeenth embodiment of the present technique.

FIG. 51 is a longitudinal cross-sectional view schematically showing a longitudinal cross-sectional structure of a solid-state imaging apparatus according to an eighteenth embodiment of the present technique.

FIG. 52 is a longitudinal cross-sectional view schematically showing a longitudinal cross-sectional structure of a solid-state imaging apparatus according to a nineteenth embodiment of the present technique.

FIG. 53 is a diagram showing a schematic configuration example of an electronic device according to a twentieth embodiment of the present technique.

### DESCRIPTION OF EMBODIMENTS

Hereinafter, embodiments of the present technique will be described in detail with reference to the drawings.

In the descriptions of the drawings referred to in the following description, same or similar portions will be denoted by same or similar reference signs. However, it should be noted that the drawings are schematic and relationships between thicknesses and planar dimensions, ratios of thicknesses of respective layers, and the like differ from those in reality. Therefore, specific thicknesses and dimensions should be determined by taking the following description into consideration.

In addition, it goes without saying that the drawings include portions where dimensional relationships and ratios differ between the drawings. Furthermore, the advantageous effects described in the present specification are merely exemplary and not intended as limiting, and other advantageous effects may be produced.

In addition, a definition of transparency in the present specification is assumed to represent a state where transmittance of a member is close to 100% with respect to a wavelength range which a light detection apparatus is expected to receive. For example, even when a material of a member itself absorbs the expected wavelength range, the member is considered transparent if made extremely thin and transmittance is close to 100%. For example, in a case of a light detection apparatus used in a near-infrared region, a member with a transmittance close to 100% in the near-infrared region may be described as being transparent even if the member exhibits high absorption in the visible range. Alternatively, even when a member includes a minor absorption component or a minor reflection component, the member is assumed to be transparent if an effect of the component is within a permissible range as compared to sensitivity specifications of the light detection apparatus.

In addition, the following embodiments exemplify apparatuses and methods for embodying the technical ideas of the present technique and configurations are not limited to those described below. That is, the technical ideas of the present technique can be variously modified within the technical scope described in the claims.

In addition, it is to be understood that definitions of directions such as up and down in the following description are merely definitions provided for the sake of brevity and are not intended to limit the technical ideas of the present disclosure. For example, it should be understood that when an object is rotated by 90 degrees and observed, the up-down direction is interpreted as the left-right direction, and when an object is rotated by 180 degrees and observed, the up and down positions are reversed.

In addition, while a case where a first conductivity type is a p-type and a second conductivity type is an n-type will be described as an example of conductivity types of semiconductors in the following embodiments, the conductivity types may be selected in an inverse relationship so that the first conductivity type is the n-type and the second conductivity type is the p-type.

In addition, in the following embodiments, in the three directions orthogonal to each other in a space, a first direction and a second direction orthogonal to each other in the same plane will be referred to as an X direction and a Y direction, respectively, and a third direction orthogonal to each of the first direction and the second direction will be referred to as a Z direction. Furthermore, in the following embodiments, a thickness direction of a semiconductor layer 20 to be described later will be referred to as the Z direction.

### First Embodiment

In the first embodiment, an example in which the present technique is applied to a solid-state imaging apparatus that is a backside-illuminated CMOS (Complementary Metal Oxide Semiconductor) image sensor as a light detection apparatus will be described.

### <Overall Configuration of Solid-State Imaging Apparatus>

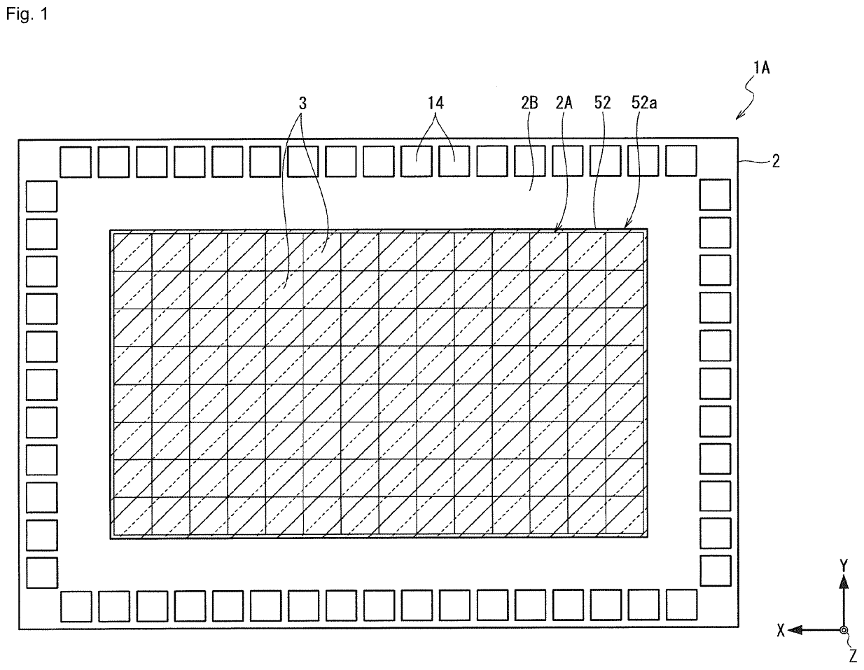

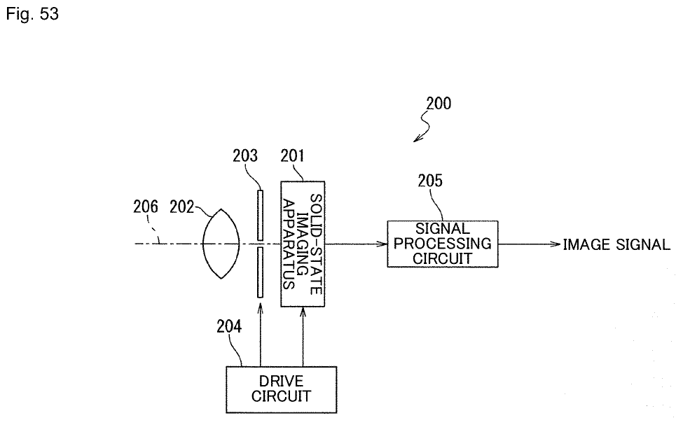

First, an overall configuration of a solid-state imaging apparatus 1A will be described. As shown in FIG. 1, the solid-state imaging apparatus 1A according to the first embodiment of the present technique is mainly constituted of a semiconductor chip 2 of which a two-dimensional planar shape is a rectangular shape in a plan view. In other words, the solid-state imaging apparatus 1A is mounted to the semiconductor chip 2 and the semiconductor chip 2 can be regarded as the solid-state imaging apparatus 1A. As shown in FIG. 53, the solid-state imaging apparatus 1A (201) takes in image light (incident light 206) from a subject through an optical lens 202, converts a quantity of the incident light 206 formed on an imaging surface into an electric signal in units of pixels, and outputs the electric signal as a pixel signal.

As shown in FIG. 1, the semiconductor chip 2 to which the solid-state imaging apparatus 1A is mounted has a pixel array portion 2A with a rectangular shape provided in a center part and a peripheral portion 2B provided on an outer side of the pixel array portion 2A so as to surround the pixel array portion 2A on a two-dimensional plane including an X direction and a Y direction which are mutually orthogonal.

The pixel array portion 2A is a light receiving surface that receives light collected by, for example, the optical lens (optical system) 202 shown in FIG. 53. In addition, in the pixel array portion 2A, a plurality of pixels 3 are arranged in a matrix on a two-dimensional plane including the X direction and the Y direction. In other words, the pixels 3 are respectively repeatedly arranged in the X and Y directions which are mutually orthogonal in a two-dimensional plane.

As shown in FIG. 1, a plurality of bonding pads 14 are disposed in the peripheral portion 2B. For example, each of the plurality of bonding pads 14 is arrayed along each of four sides in the two-dimensional plane of the semiconductor chip 2. Each of the plurality of bonding pads 14 is an input/output terminal used when electrically connecting the semiconductor chip 2 to an external apparatus.

### <Logic Circuit>

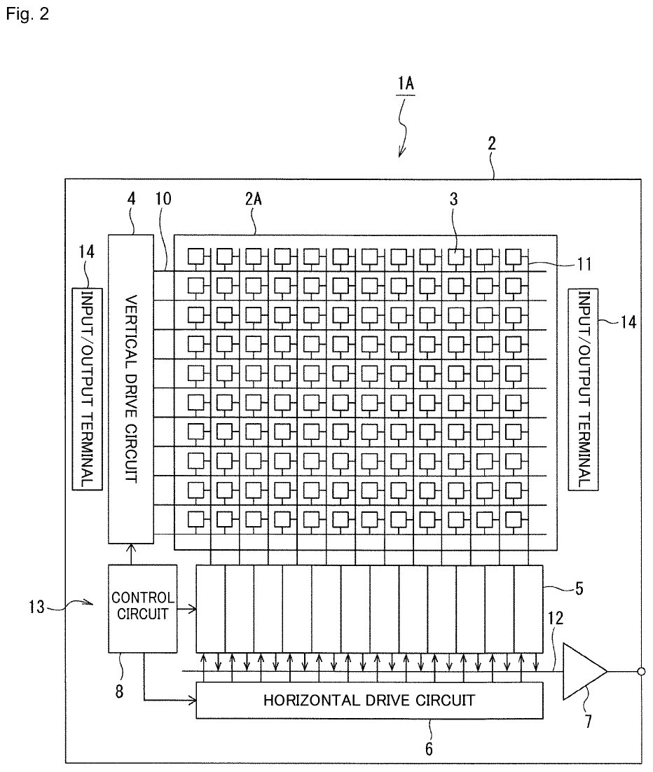

The semiconductor chip 2 includes a logic circuit 13 shown in FIG. 2. As shown in FIG. 2, the logic circuit 13 includes a vertical drive circuit 4, a column signal processing circuit 5, a horizontal drive circuit 6, an output circuit 7, and a control circuit 8. For example, the logic circuit 13 is constituted by CMOS (Complementary MOS) circuits having a MOSFET (Metal Oxide Semiconductor Field Effect Transistor) of an n-channel conductivity type and a MOSFET of a p-channel conductivity type as field-effect transistors.

For example, the vertical drive circuit 4 is constituted of a shift register. The vertical drive circuit 4 sequentially selects a desired pixel drive line 10, supplies a pulse for driving the pixels 3 to the selected pixel drive line 10, and drives the respective pixels 3 in unit of rows. In other words, the vertical drive circuit 4 sequentially performs selective scanning of the pixels 3 of the pixel array portion 2A in units of rows in a vertical direction and supplies a pixel signal from the pixels 3 based on a signal electric charge generated in accordance with a received light quantity by the photoelectric conversion element of each pixel 3 to the column signal processing circuit 5 through a vertical signal line 11.

For example, the column signal processing circuit 5 is provided for each column of the pixels 3 to perform signal processing such as noise removal on signals output from a row of pixels 3 on a pixel column basis. For example, the column signal processing circuit 5 performs signal processing such as CDS (Correlated Double Sampling) for removing pixel-specific fixed pattern noise and AD (Analog-Digital) conversion.

For example, the horizontal drive circuit 6 is constituted of a shift register. The horizontal drive circuit 6 sequentially selects each column signal processing circuit 5 by sequentially outputting a horizontal scanning pulse to the column signal processing circuit 5 and outputs a pixel signal on which signal processing has been performed from each column signal processing circuit 5 to a horizontal signal line 12.

The output circuit 7 performs signal processing on the pixel signals sequentially supplied from the respective column signal processing circuits 5 through the horizontal signal line 12 and outputs resultant pixel signals. As the signal processing, for example, buffering, black level adjustment, a column deviation correction, various types of digital signal processing, and the like can be used.

The control circuit 8 generates a clock signal or a control signal as a reference for operations of the vertical drive circuit 4, the column signal processing circuit 5, the horizontal drive circuit 6, and the like on the basis of a vertical synchronization signal, a horizontal synchronization signal, a master clock signal, and the like. In addition, the control circuit 8 outputs the generated clock signal or control signal to the vertical drive circuit 4, the column signal processing circuit 5, the horizontal drive circuit 6, and the like.

### <Circuit Configuration of Pixel>

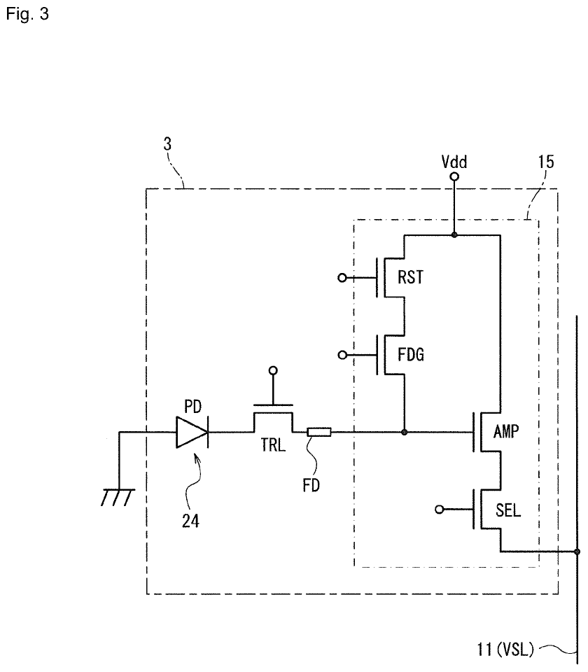

As shown in FIG. 3, each of the plurality of pixels 3 includes a photoelectric conversion unit 24, a transfer transistor TRL as a pixel transistor, and an electric charge holding region (Floating Diffusion) FD and further includes a readout circuit 15 which is electrically connected to the electric charge holding region FD. While a circuit configuration in which one readout circuit 15 is assigned to one pixel 3 is adopted as an example in the first embodiment, the circuit configuration is not restrictive and a circuit configuration in which one readout circuit 15 is shared by a plurality of pixels 3 may be adopted.

For example, the photoelectric conversion unit 24 shown in FIG. 3 is constituted of a p-n junction photodiode (PD) and generates a signal charge in accordance with a quantity of received light. A cathode side of the photoelectric conversion unit 24 is electrically connected to a source region of the transfer transistor TRL and an anode side of the photoelectric conversion unit 24 is electrically connected to a reference potential line (for example, a ground).

The transfer transistor TRL shown in FIG. 3 transfers the signal charge photoelectrically converted by the photoelectric conversion unit 24 to the electric charge holding region FD. A source region of the transfer transistor RTL is electrically connected to the cathode side of the photoelectric conversion unit 24 and a drain region of the transfer transistor TRL is electrically connected to the electric charge holding region FD. In addition, a gate electrode of the transfer transistor TRL is electrically connected to a transfer transistor drive line among the pixel drive lines 10 (refer to FIG. 2).

The electric charge holding region FD shown in FIG. 3 temporarily holds (accumulates) the signal charge transferred from the photoelectric conversion unit 24 via the transfer transistor TRL.

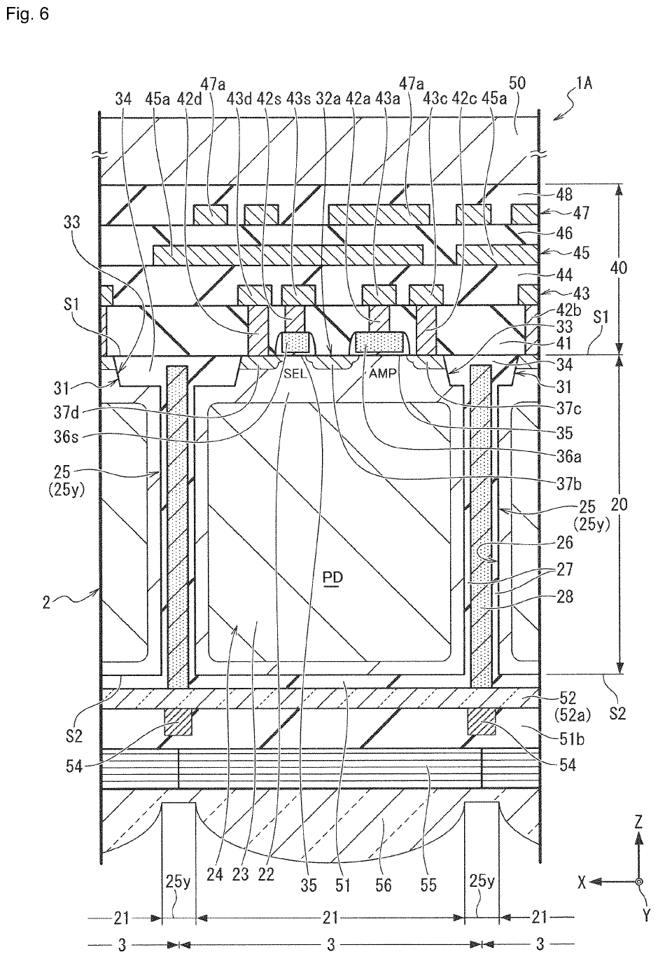

The photoelectric conversion unit 24, the transfer transistor TRL, and the electric charge holding region FD are mounted in a photoelectric conversion region 21 (refer to FIG. 6) of the semiconductor layer 20 to be described later.

The readout circuit 15 shown in FIG. 3 reads the signal charge held in the electric charge holding region FD and outputs a pixel signal based on the signal charge. The readout circuit 15 includes, but is not limited to, an amplifying transistor AMP, a selection transistor SEL, a reset transistor RST, and a switching transistor FDG as pixel transistors. Each of the transistors (AMP, SEL, RST, and FDG) and the transfer transistor TRL described earlier is constituted by, as a field-effect transistor, a MOSFET having a gate insulating film made of, for example, a silicon oxide film (a SiO₂ film), a gate electrode, and a pair of main electrode regions functioning as a source region and a drain region. Alternatively, each of the transistors may be a MISFET (Metal Insulator Semiconductor FET) of which a gate insulating film is a silicon nitride (Si₃N₄) film or a stacked film made up of the silicon nitride film and a silicon oxide film.

As shown in FIG. 3, the amplifying transistor AMP has a source region electrically connected to a drain region of the selection transistor SEL and a drain region electrically connected to a power supply line Vdd and a drain region of the reset transistor RST. In addition, the gate electrode of the amplifying transistor AMP is electrically connected to the electric charge holding region FD and a source region of the switching transistor RST.

In the selection transistor SEL, the source is electrically connected to the vertical signal line 11 (VSL) and a drain region is electrically connected to the source region of the amplifying transistor AMP. In addition, a gate electrode of the selection transistor SEL is electrically connected to a selection transistor drive line among the pixel drive lines 10 (refer to FIG. 2).

In the reset transistor RST, a source region is electrically connected to the drain region of the switching transistor FDG and the drain region is electrically connected to the power supply line Vdd and the drain region of the amplifying transistor AMP. In addition, a gate electrode of the reset transistor RST is electrically connected to a switching transistor drive line among the pixel drive lines 10 (refer to FIG. 2).

In the switching transistor FDG, the drain region is electrically connected to the source region of the reset transistor RST and the source region is electrically connected to the electric charge holding region FD and the gate electrode of the amplifying transistor AMP. In addition, a gate electrode of the switching transistor FDG is electrically connected to a switching transistor drive line among the pixel drive lines 10 (refer to FIG. 2).

When the transfer transistor TRL is turned on, the transfer transistor TRL transfers a signal charge generated by the photoelectric conversion unit 24 to the electric charge holding region FD.

When the reset transistor RST is turned on, the reset transistor RST resets a potential (signal charge) of the electric charge holding region FD to a potential of the power supply line Vdd. The selection transistor SEL controls an output timing of the pixel signal from the readout circuit 15.

The switching transistor FDG controls holding of an electric charge by the electric charge holding region FD and adjusts a multiplication factor of voltage in accordance with a potential that is amplified by the amplifying transistor AMP.

The amplifying transistor AMP generates a signal of a voltage in accordance with a level of a signal charge held in the electric charge holding region FD as a pixel signal. The amplifying transistor AMP constitutes a source follower amplifier and outputs a pixel signal of a voltage in accordance with the signal charge generated by the photoelectric conversion unit 24. When the selection transistor SEL is turned on, the amplifying transistor AMP amplifies the potential of the electric charge holding region FD and outputs a voltage in accordance with the potential to the column signal processing circuit 5 via the vertical signal line 11 (VSL).

During an operation of the solid-state imaging apparatus 1A according to the first embodiment, a signal charge generated by the photoelectric conversion unit 24 of the pixel 3 is held (accumulated) in the electric charge holding region FD via the transfer transistor TRL of the pixel 3. The signal charge held in the electric charge holding region FD is read out by the readout circuit 15 and applied to the gate electrode of the amplifying transistor AMP of the readout circuit 15. A selection control signal of a horizontal line is applied to the gate electrode of the selection transistor SEL of the readout circuit 15 from the vertical shift register. By changing the selection control signal to a high (H) level, the selection transistor SEL becomes conductive and a current corresponding to the potential of the electric charge holding region FD having been amplified by the amplifying transistor AMP flows through the vertical signal line 11. In addition, by changing a reset control signal to be applied to the gate electrode of the reset transistor RST of the readout circuit 15 to a high (H) level, the reset transistor RST becomes conductive and resets the signal charge accumulated in the electric charge holding region FD.

Note that the selection transistor SEL and the switching transistor FDG may be omitted as necessary. When omitting the selection transistor SEL, the source region of the amplifying transistor AMP is to be electrically connected to the vertical signal line 11 (VSL). In addition, when omitting the switching transistor FDG, the source region of the reset transistor RST is to be electrically connected to the gate electrode of the amplifying transistor AMP and the electric charge holding region FD.

### <Specific Configuration of Solid-State Imaging Apparatus>

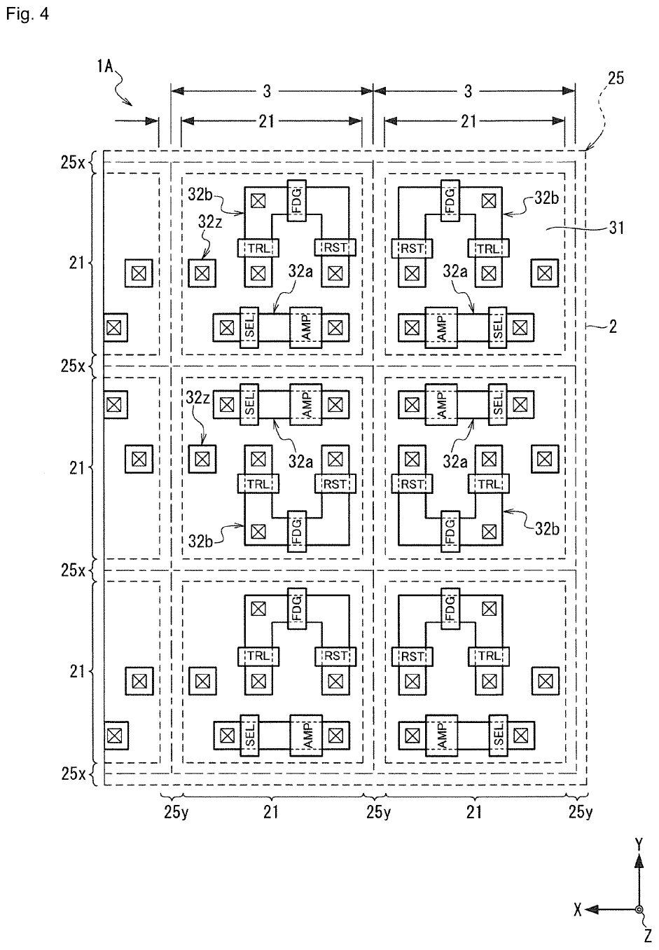

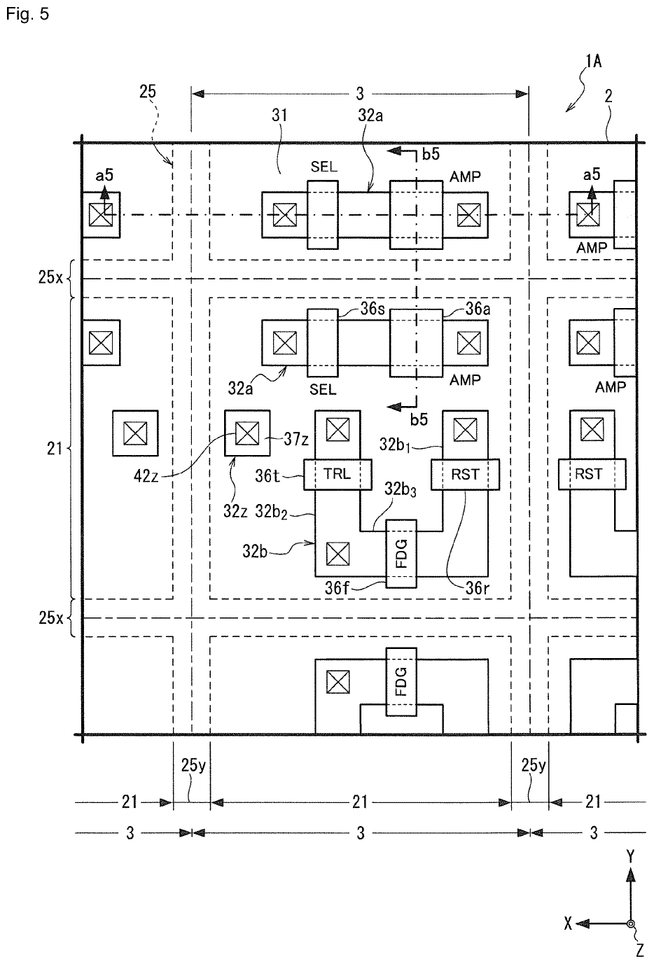

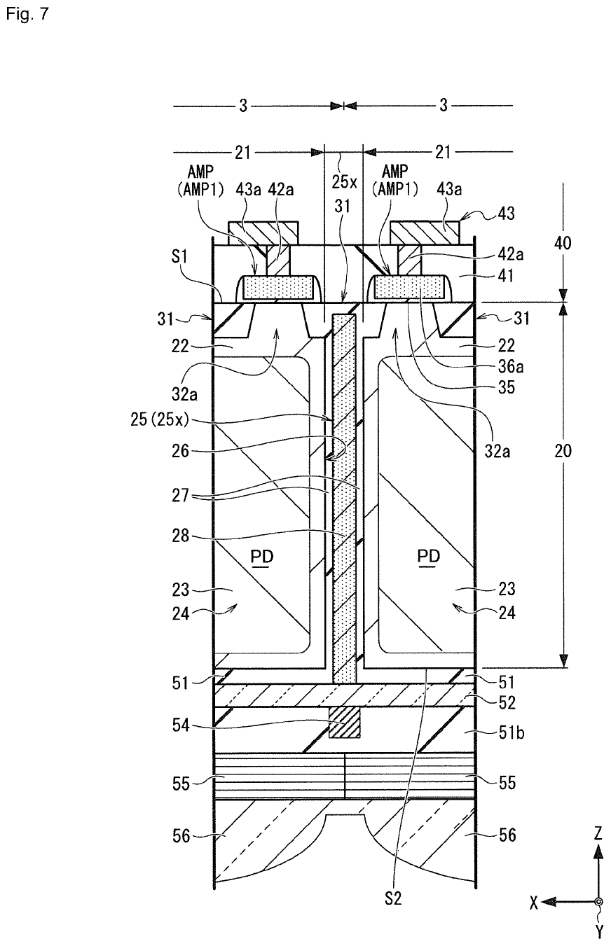

Next, a specific configuration of the semiconductor chip 2 (solid-state imaging apparatus 1A) will be described with reference to FIGS. 4 to 7. Note that FIGS. 4 and 5 are plan views from a side of a first surface S1 of the semiconductor layer 20 shown in FIG. 6. In addition, FIGS. 6 and 7 have been vertically inverted with respect to FIG. 1 in order to make the drawings more viewable. Furthermore, in FIG. 7, layers above a first wiring layer 43 of a multilayer wiring layer 40 have been omitted.

### <Semiconductor Chip>

As shown in FIG. 6, the semiconductor chip 2 includes: the semiconductor layer 20 which has a first surface S1 and a second surface S2 that are positioned opposite to each other in a thickness direction (Z direction); the multilayer wiring layer 40 provided on the side of the first surface S1 of the semiconductor layer 20; and a supporting substrate 50 provided on an opposite side to the side of the semiconductor layer 20 of the multilayer wiring layer 40.

In addition, the semiconductor chip 2 includes, on the side of the second surface S2 of the semiconductor layer 20, an insulating film 51, a transparent electrode 52, a light-shielding film 54, an insulating film 51b, a color filter 55, and a microlens (on-chip lens) 56 which are sequentially provided from the side of the second surface S2.

### <Semiconductor Layer>

As shown in FIGS. 4 to 7, the semiconductor layer 20 is provided with a separation region 25 which stretches in a thickness direction of the semiconductor layer 20 and a plurality of photoelectric conversion regions 21 which are partitioned by the separation region 25. Each photoelectric conversion region 21 of the plurality of photoelectric conversion regions 21 is provided for each pixel 3 and the photoelectric conversion regions 21 are adjacent to each other via the separation region 25 in a plan view. In other words, the solid-state imaging apparatus 1A according to the first embodiment includes the plurality of photoelectric conversion regions 21 provided so as to be adjacent to each over via the separation region 25 which stretches in the thickness direction (Z direction) of the semiconductor layer 20.

In addition, an element separation region (field separation region) 31 and an island-like first element formation region (active region) 32a and second element formation region 32b which are partitioned by the element separation region 31 are provided on the side of the first surface S1 of the semiconductor layer 20. Furthermore, a power feeding region 32z which is partitioned by the element separation region 31 is provided on the side of the first surface S1 of the semiconductor layer 20. The first element formation region 32a, the second element formation region 32b, and the power feeding region 32z are provided for each pixel 3. In other words, each of the plurality of pixels 3 disposed in the pixel array portion 2A includes the photoelectric conversion region 21, the first element formation region 32a and the second element formation region 32b, and the power feeding region 32z.

As the semiconductor layer 20, a Si substrate, a SiGe substrate, an InGaAs substrate, or the like can be used. In the first embodiment, for example, a p-type semiconductor substrate made of monocrystalline silicon is used as the semiconductor layer 20.

In this case, the first surface S1 of the semiconductor layer 20 may be referred to as an element formation surface or a main surface and the side of the second surface S2 may be referred to as a light incident surface or a rear surface. The solid-state imaging apparatus 1A according to the first embodiment photoelectrically converts light incident from the side of the second surface (light incident surface, rear surface) S2 of the semiconductor layer 20 with the photoelectric conversion region 21 provided on the semiconductor layer 20.

In addition, a plan view refers to a view from a direction along the thickness direction (Z direction) of the semiconductor layer 20. Furthermore, a cross-sectional view refers to a view of a cross section along the thickness direction (Z direction) of the semiconductor layer 20 from a direction (X direction or a Y direction) that is orthogonal to the thickness direction (Z direction) of the semiconductor layer 20. Furthermore, the photoelectric conversion region 21 can also be referred to as a photoelectric conversion cell. Moreover, the separation region 25 can be referred to as a first separation region and the element separation region 31 can be referred to as a second separation region.

### <Photoelectric Conversion Region>

As shown in FIGS. 6 and 7, each photoelectric conversion region 21 of the plurality of photoelectric conversion regions (photoelectric conversion cells) 21 is provided with, for example, a p-type well region 22 constituted of a p-type semiconductor region and an n-type semiconductor region 23. The p-type well region 22 is provided across the first surface S1 and the second surface S2 of the semiconductor layer 20.

The n-type semiconductor region 23 is provided in the p-type well region 22 on the first surface S1 and the second surface S2 of the semiconductor layer 20 and from the side of the first surface S1 to the side of the second surface S2 of the semiconductor layer 20 in a state of being separated from each of the separation regions 25. That is, of the n-type semiconductor region 23, an upper surface portion on the side of the first surface S1 of the semiconductor layer 20, a lower surface portion on the side of the second surface S2 of the semiconductor layer 20, and side surface portions on the side of the separation region 25 are respectively enclosed by the p-type well region 22. In other words, the p-type well region 22 is provided so as to overlap with the n-type semiconductor region 23 between the first surface S1 of the semiconductor layer 20 and the upper surface portion and the lower surface portion of the n-type semiconductor region 23. In addition, the p-type well region 22 is provided along the thickness direction (Z direction) of the semiconductor layer 20 between the separation regions 25 and the n-type semiconductor region 23.

In this case, the photoelectric conversion unit 24 described above is mainly constituted of the n-type semiconductor region 23 and configured as a p-n junction photodiode (PD) made up of the p-type well region 22 and the n-type semiconductor region 23.

### <Element Separation Region>

As shown in FIGS. 6 and 7, the element separation region 31 is constructed of, but not limited to, an STI (Shallow Trench Isolation) structure in which an insulating film (field insulating film) 34 is selectively embedded in a groove 33 that is depressed from the side of the first surface S1 toward the side of the second surface S2 of the semiconductor layer 20. As the insulating film 34, for example, a silicon oxide film can be used.

### <Element Formation Region>

As shown in FIGS. 6 and 7, the p-type well region 22 is provided in each of the first and second element formation regions 32a and 32b which are partitioned by the element separation region 31.

As shown in FIG. 5, the first element formation region 32a and the second element formation region 32b are disposed so as to be adjacent to each other in the Y direction in one photoelectric conversion region 21. The first element formation region 32a is constituted of a striped planar pattern created by stretching a planar pattern in a plan view in the X direction. The second element formation region 32b is constituted of a C-shaped planar pattern having a first portion 32b₁ and a second portion 32b₂, each of which stretches in the Y direction and separates from each other in the X direction, and a third portion 32c₃ which stretches in the X direction and which is coupled to a side of one end of each of the first portion 32b₁ and the second portion 32b₂. In addition, the second element formation region 32b is disposed in an orientation which causes another end of each of the first portion 32b₁ and the second portion 32b₂ to be positioned on the side of the first element formation region 32a.

As shown in FIG. 5, the amplifying transistor AMP and the selection transistor SEL described above are provided so as to be connected in series in the first element formation region 32a. The transfer transistor TRL, the switching transistor FDG, and the reset transistor RST are provided so as to be connected in series in the second element formation region 32b. In other words, for example, the amplifying transistor AMP, the selection transistor SEL, the reset transistor RST, the switching transistor FDG, and the transfer transistor TSL described above are provided as pixel transistors in each photoelectric conversion region 21 of the plurality of photoelectric conversion regions 21. In addition, the pixel transistors (AMP, SEL, RST, FDG, and TSL) are provided in the p-type well region 22 which is provided so as to overlap with the photoelectric conversion unit 24 in a plan view on the side of the first surface S1 of the semiconductor layer 20. In addition, the pixel 3 including the photoelectric conversion region 21, the photoelectric conversion unit 24, and the pixel transistors are disposed in plurality in a matrix (two-dimensional matrix) in the pixel array portion 2A. In the photoelectric conversion region 21, a signal charge corresponding to an amount of incident light is generated and the generated signal charge is accumulated.

### <Amplifying Transistor and Selection Transistor>

As shown in FIG. 6, the amplifying transistor AMP includes a gate insulating film 35 provided on the first element formation region 32a on the side of the first surface S1 of the semiconductor layer 20, a gate electrode 36a provided on the first element formation region 32a via the gate insulating film 35, and a side wall spacer provided on a side wall of the gate electrode 36a so as to enclose the gate electrode 36a. In addition, the amplifying transistor AMP further includes a channel formation region in which a channel (conduction path) is formed in the p-type well region 22 directly beneath the gate electrode 36a and a pair of main electrode regions 37b and 37c which are provided in the p-type well region 22 so as to separate from each other in a channel length direction (gate length direction) and to sandwich the channel formation region and which function as a source region and a drain region. The amplifying transistor AMP controls the channel formed in the channel formation region by a gate voltage which is applied to the gate electrode 36a.

As shown in FIG. 6, the selection transistor SEL includes the gate insulating film 35 provided on the first element formation region 32a on the side of the first surface S1 of the semiconductor layer 20, a gate electrode 36s provided on the first element formation region 32a via the gate insulating film 35, and a side wall spacer provided on a side wall of the gate electrode 36s so as to enclose the gate electrode 36s. In addition, the selection transistor SEL further includes a channel formation region in which a channel (conduction path) is formed in the p-type well region 22 directly beneath the gate electrode 36s and the pair of main electrode regions 37d and 37b which are provided in the p-type well region 22 so as to separate from each other in the channel length direction (gate length direction) and to sandwich the channel formation region and which function as a source region and a drain region. The selection transistor SEL controls the channel formed in the channel formation region by a gate voltage which is applied to the gate electrode 36s. In other words, the selection transistor SEL and the amplifying transistor AMP have a lateral configuration.

As shown in FIG. 6, the amplifying transistor AMP and the selection transistor SEL share one main electrode region (source region) 37b of the amplifying transistor AMP and the other main electrode region (drain region) 37b of the selection transistor SEL.

The main electrode region 37b includes, but is not limited to, an extension region which is constituted of an n-type semiconductor region and which is formed by self-alignment with respect to the gate electrode 36a, an extension region which is constituted of an n-type semiconductor region and which is formed by self-alignment with respect to the gate electrode 36s, and a contact region which is constituted of an n-type semiconductor region with a higher impurity concentration than the extension regions and which is formed by self-alignment with respect to the side wall spacers of the respective side walls of the gate electrodes 36a and 36s.

The main electrode region 37c includes, but is not limited to, an extension region which is constituted of an n-type semiconductor region and which is formed by self-alignment with respect to the gate electrode 36a and a contact region which is constituted of an n-type semiconductor region with a higher impurity concentration than the extension region and which is formed by self-alignment with respect to the side wall spacer of the side wall of the gate electrode 36a.

The main electrode region 37d includes, but is not limited to, an extension region which is constituted of an n-type semiconductor region and which is formed by self-alignment with respect to the gate electrode 36s and a contact region which is constituted of an n-type semiconductor region with a higher impurity concentration than the extension region and which is formed by self-alignment with respect to the side wall spacer of the side wall of the gate electrode 36s.

The gate insulating film 35 and each of the side wall spacers are constituted of, for example, a silicon oxide (SiO₂) film. Each of the gate electrodes 36a and 36s is constituted of, for example, a silicon film (doped polysilicon film) into which an impurity for reducing a resistance value has been introduced.

### <Reset Transistor and Switching Transistor>

As shown in FIG. 5, the reset transistor RST is provided in the first portion 32b₁ of the second element formation region 32b. The switching transistor FDG is provided in a third portion 32b₃ of the second element formation region 32b.

Although not illustrated in detail, each of the reset transistor RST and the switching transistor FDG is configured in a similar manner to the amplifying transistor AMP and the selection transistor SEL described above. In addition, the reset transistor RST and the switching transistor FDG share one main electrode region (source region) of the reset transistor RST and the other main electrode region (drain region) of the switching transistor FDG.

### <Transfer Transistor>

As shown in FIG. 5, the transfer transistor TRL is provided in the second portion 32b₂ of the second element formation region 32b. Although not illustrated in detail, the transfer transistor TRL is configured in a similar manner to the amplifying transistor AMP and the selection transistor SEL described above. In addition, one main electrode region (source region) of the transfer transistor TRL is electrically connected to the n-type semiconductor region 23 of the photoelectric conversion unit 24 shown in FIG. 6 and the other main electrode region (drain region) of the transfer transistor TRL is shared with the one main electrode region (source region) of the switching transistor FDG. In addition, the other main electrode region (drain region) of the transfer transistor TRL functions as the electric charge holding region FD shown in FIG. 2.

In a similar manner to the other pixel transistors (AMP, SEL, RST, and FDG), the transfer transistor TRL has a lateral configuration in which the pair of main electrode regions (source region and drain region) are disposed so as to be separated from each other in a direction (X direction or a Y direction) that is orthogonal to the thickness direction (Z direction) of the semiconductor layer 20. Alternatively, the transfer transistor TRL may have a vertical configuration in which a part or all of a gate electrode is embedded in a groove part of the semiconductor layer 20 via a gate insulating film.

FIG. 5 respectively illustrates a gate electrode 36r of the reset transistor RST, a gate electrode 36f of the switching transistor FDG, and a gate electrode 36t of the transfer transistor TRL.

### <Power Feeding Region>

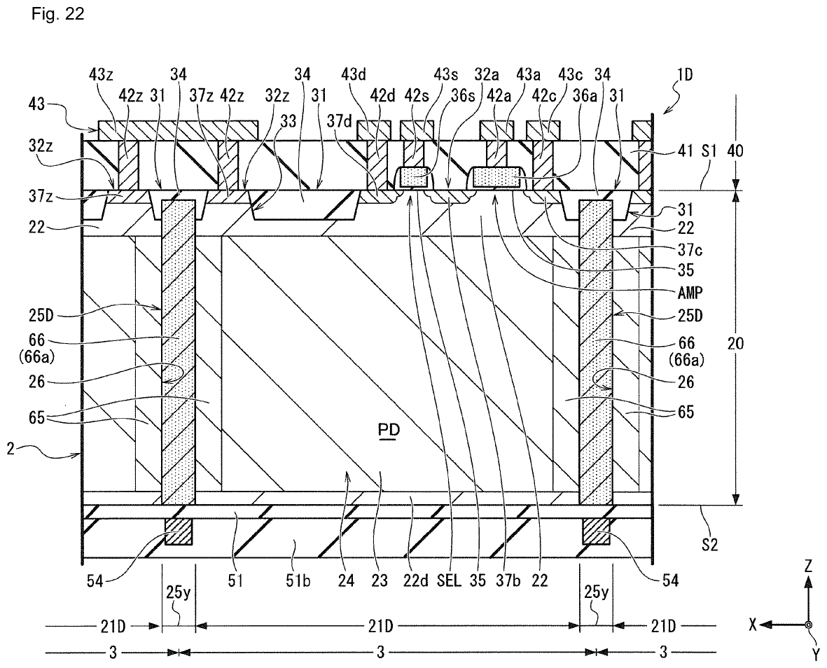

Although not illustrated in detail, the power feeding region 32z shown in FIG. 5 is provided with a p-type power feeding contact region 37z. While the p-type power feeding contact region 37z will be explained in detail in a fourth embodiment to be described later, with reference to FIG. 22, the p-type power feeding contact region 37z is provided in the p-type well region 22 of a photoelectric conversion region 21D (21) so as to come into contact with the p-type well region 22 and the p-type power feeding contact region 37z is electrically connected to the p-type well region 22. In addition, the p-type power feeding contact region 37z is electrically connected to a power feeding wiring 43z formed on a first wiring layer 43 via a power feeding contact electrode 42z which is embedded in an interlayer insulating film 41. The p-type power feeding contact region 37z is constituted of a p-type semiconductor region having a higher impurity concentration than the p-type well region 22 and reduces ohmic contact resistance with the power feeding contact electrode 42z.

### <Multilayer Wiring Layer>

As shown in FIG. 6, the multilayer wiring layer 40 is disposed on the side of the first surface S1 which is opposite to the side of the light incident surface (the second surface S2) of the semiconductor layer 20. In addition, for example, the multilayer wiring layer 40 has a three-layer wiring structure including, but not limited to, interlayer insulating films 41, 44, and 46, wiring layers 43, 45, and 47, and a protective film 48.

The interlayer insulating film 41 is provided on the side of the first surface S1 of the semiconductor layer 20 so as to cover the gate electrodes of the pixel transistors (AMP, SEL, RST, FDG, and STL). FIG. 6 illustrates a state where the respective gate electrodes 36a and 36s of the amplifying transistor AMP and the selection transistor SEL as pixel transistors are covered by the interlayer insulating film 41.

The first wiring layer 43 is provided on the interlayer insulating film 41 and the first wiring layer 43 is covered by an upper interlayer insulating film 44. In addition, a second wiring layer 45 is provided on the interlayer insulating film 44, and the second wiring layer 45 is covered by an upper interlayer insulating film 46. Furthermore, a third wiring layer 47 is provided on the interlayer insulating film 46 and the third wiring layer 47 is covered by an upper protective film 48.

Various wirings are formed in each of the first to third wiring layers 43, 45, and 47. FIG. 6 respectively illustrates wirings 43a, 43s, 43c, and 43d formed on the first wiring layer 43, a wiring 45a formed on the second wiring layer 45, and a wiring 47a formed on the third wiring layer 47.

The wiring 43a is electrically connected to the gate electrode 36a of the amplifying transistor AMP via a contact electrode (conductive plug) 42a embedded in the interlayer insulating film 41. The wiring 43c is electrically connected to the other main electrode region (drain region) 37c of the amplifying transistor AMP via a contact electrode 42c embedded in the interlayer insulating film 41. The wiring 43s is electrically connected to the gate electrode 36s of the selection transistor SEL via a contact electrode (conductive plug) 42s embedded in the interlayer insulating film 41. The wiring 43d is electrically connected to the one main electrode region 37d of the selection transistor SEL via a contact electrode (conductive plug) 42d embedded in the interlayer insulating film 41.

Each of the wiring layers 43, 45, and 47 of the first to third layers is constituted of, for example, a metal film made of Cu or an alloy having Cu as its main component. The interlayer insulating films 41, 44, and 46 and the protective film 48 are constituted of, for example, a monolayer film of one of a silicon oxide film, a silicon nitride (Si₃N₄) film, and a nitride silicon carbide (SiCN) film or a laminated film created by laminating two or more of these films. Each of the contact electrodes 42a, 42c, 42d, and 42s is constituted of, for example, a high-melting point metal film such as a tungsten (W) film or a titanium (Ti) film.

The pixel transistors included in the readout circuit 15 are driven via wirings of each of the wiring layers 43, 45, and 47. In addition, since the multilayer wiring layer 40 is disposed on an opposite side of the light incident surface side (the side of the second surface S2) of the semiconductor layer 20, a layout of the wirings can be freely set.

### <Supporting Substrate>

The supporting substrate 50 is provided on an opposite side to the side of the semiconductor layer 20 of the multilayer wiring layer 40. The supporting substrate 50 is a substrate for securing strength of the semiconductor layer 20 during production of the solid-state imaging apparatus 1A. For example, silicon (Si) can be used as a material of the supporting substrate 50.

### (Planar Arrangement Pattern of Transistors)

As shown in FIG. 4, the two photoelectric conversion regions 21 (pixels 3) that are adjacent to each other in the X direction via the separation region 25 in a plan view are constituted of an inverse pattern of an arrangement pattern of the pixel transistors (AMP, SEL, RST, FDG, and TRL) included in one photoelectric conversion region 21 and an arrangement pattern of the pixel transistors (AMP, SEL, RST, FDG, and TRL) included in the other photoelectric conversion region 21, with the separation region 25 between the respective photoelectric conversion regions 21 as an inversion axis. In addition, the two photoelectric conversion regions 21 (pixels 3) that are adjacent to each other in the Y direction via the separation region 25 in a plan view are also constituted of an inverse pattern of an arrangement pattern of the pixel transistors (AMP, SEL, RST, FDG, and TRL) included in one photoelectric conversion region 21 and an arrangement pattern of the pixel transistors (AMP, SEL, RST, FDG, and TRL) included in the other photoelectric conversion region 21, with the separation region 25 between the respective photoelectric conversion regions 21 as an inversion axis. In other words, as shown in FIGS. 4 and 5, the pixel array portion 2A according to the first embodiment include the photoelectric conversion regions 21 of which pixel transistors with the same functions are adjacent to each other via the separation region 25 in a plan view. FIG. 7 illustrates, as an example, photoelectric conversion regions 21 of which respective amplifying transistors AMP are adjacent to each other.

### <Separation Region>

As shown in FIGS. 4 and 5, the separation region 25 includes a first portion 25x which stretches in the X direction in a plan view and a second portion 25y which stretches in the Y direction in a plan view. In addition, the first portion 25x and the second portion 25y are orthogonal to each other.

The first portion 25x is repetitively arranged in the Y direction at predetermined intervals. In addition, the second portion 25y is repetitively arranged in the X direction at predetermined intervals. In other words, a planar pattern of the separation region 25 in a plan view is a grid-like planar pattern. Furthermore, in each photoelectric conversion region 21 of the plurality of photoelectric conversion regions 21, both ends in the X direction are partitioned by the two second portions 25y adjacent to each other of the separation region 25 and both ends in the Y direction are partitioned by the two first portions 25x adjacent to each other of the separation region 25.

As shown in FIGS. 6 and 7, each of the first portions 25x and the second portions 25y in the separation region 25 stretches in the thickness direction of the semiconductor layer 20 and electrically and optically separates, from each other, the photoelectric conversion regions 21 which are adjacent to each other in a plan view. In each of the first portions 25x and the second portions 25y, one end in the thickness direction of the semiconductor layer 20 is coupled to the element separation region 31 and another end in the thickness direction of the semiconductor layer 20 reaches the second surface S2 of the semiconductor layer 20.

Each of the first portions 25x and the second portions 25y of the separation region 25 includes a separation insulating film 27 provided along an inner wall of an excavated portion 26 which stretches in the thickness direction (Z direction) of the semiconductor layer 20 and a conductor 28 provided via the separation insulating film 27 in the excavated portion 26 of the semiconductor layer 20. The conductor 28 is insulated and separated from the semiconductor layer 20 by the separation insulating film 27. In other words, the separation region 25 includes the conductor 28 which is embedded in the semiconductor layer 20 via the separation insulating film 27 and which is insulated and separated from the semiconductor layer 20. The separation insulating film 27 and the conductor 28 stretch in the thickness direction of the semiconductor layer 20, and one end of each of the separation insulating film 27 and the conductor 28 is coupled to the element separation region 31 while another end of each of the separation insulating film 27 and the conductor 28 reaches the second surface S2 of the semiconductor layer 20.

As the separation insulating film 27, for example, a silicon oxide film can be used. As the conductor 28, for example, a semiconductor film into which an impurity that reduces a resistance value has been introduced can be used. For example, the conductor 28 according to the first embodiment is constituted of, but not limited to, a p-type doped polysilicon film into which boron (B) has been introduced as an impurity.

In this case, the excavated portion 26 includes a groove portion formed by selectively removing a part of the semiconductor layer 20 and a through-hole.

### <Insulating Film and Light-Shielding Film>

As shown in FIGS. 6 and 7, the insulating film 51 is provided on the side of the second surface S2 of the semiconductor layer 20. In addition, the insulating film 51 entirely covers the side of the second surface S2 (light incident surface) of the semiconductor layer 20 in the pixel array portion 2A so that the side of the second surface S2 of the semiconductor layer 20 becomes a flat surface without any irregularities. As the insulating film 51, for example, a translucent silicon oxide film is used.

The light-shielding film 54 is provided on an opposite side to the side of the semiconductor layer 20 of the transparent electrode 52. A planar pattern of the light-shielding film 54 in a plan view is a grid-like planar pattern which opens a side of the light-receiving surface of each of the plurality of photoelectric conversion regions 21 so that light incident to a predetermined photoelectric conversion region 21 does not leak into an adjacent photoelectric conversion region 21. The light-shielding film 54 is constituted of a same grid-like planar pattern as the grid-like planar pattern of the separation region 25 and is disposed at a position overlapping the separation region 25 in a plan view. As the light-shielding film 54, for example, a light-shielding tungsten (W) film is used.

The insulating film 51b is provided so as to cover the light-shielding film 54 on an opposite side to the side of the semiconductor layer 20 of the transparent electrode 52. In addition, the insulating film 51b entirely covers the side of the second surface S2 (light incident surface) of the semiconductor layer 20 in the pixel array portion 2A so that the side of the second surface S2 of the semiconductor layer 20 becomes a flat surface without any irregularities. As the insulating film 51b, for example, a translucent silicon oxide film is used in a similar manner to the insulating film 51.

### <Color Filter and Microlens>

As shown in FIGS. 6 and 7, the color filter 55 is provided for each photoelectric conversion region 21 (pixel 3) on an opposite side (light incident surface side) to the side of the semiconductor layer 20 of the transparent electrode 52. The color filter 55 separates incident light that is incident from the side of the light incident surface of the semiconductor chip 2 into colors. Examples of the color filter 55 include a first color filter of red (R), a second color filter of green (G), and a third color filter of blue (B). The first embodiment includes color filters 55 corresponding to the three colors of R, G, and B.

The microlens 56 is provided for each photoelectric conversion region 21 (pixel 3) on an opposite side (light incident surface side) to the side of the transparent electrode 52 of the color filter 55. The microlens 56 collects irradiating light and causes the collected light to efficiently enter the photoelectric conversion region 21.

### <Transparent Electrode>

As shown in FIGS. 6 and 7, the transparent electrode 52 is provided via the insulating film 51 on the side of the second surface S2 of the semiconductor layer 20 and is insulated and separated from the semiconductor layer 20. The transparent electrode 52 overlaps with the separation region 25 in a plan view. In addition, the transparent electrode 52 is electrically connected to the conductor 28 of the separation region 25 on the side of the second surface S2 of the semiconductor layer 20.

While the transparent electrode 52 according to the first embodiment is directly connected to the conductor 28 of the separation region 25, the transparent electrode 52 is not limited thereto. For example, the transparent electrode 52 may be indirectly connected to the conductor 28 of the separation region 25 via another conductive film. In addition, as shown in FIGS. 6 and 7, the transparent electrode 52 according to the first embodiment is constituted of, but not limited to, a solid planar pattern 52a which spreads over a plurality of the photoelectric conversion regions 21 in a plan view and, as shown in FIG. 1, provided over the entire pixel array portion 2A. As the transparent electrode 52, for example, a transparent conductive film such as an indium oxide (ITO: Indium Tin Oxide) film, a tin oxide (SnO₂) film, or a zinc oxide (ZnO) film can be used.

A first reference potential is applied to the transparent electrode 52 as a power supply potential (power supply voltage). In addition, a potential of the conductor 28 of the separation region 25 is fixed to the first reference potential that is applied to the transparent electrode 52. Although not illustrated, the transparent electrode 52 is electrically connected to a power generation circuit (drive circuit) which supplies a constant power supply potential and the power supply potential supplied from the power generation circuit is applied to the transparent electrode 52. In the first embodiment, for example, 0 V is applied as the first reference potential to the transparent electrode 52 although the first reference potential is not limited thereto. The application of the first reference potential to the transparent electrode 52 and the potential fixing of the first reference potential of the conductor 28 are held during photoelectric conversion by the photoelectric conversion unit 24 or during driving of the pixel transistors (AMP, SEL, RST, FDG, and TRL) included in the readout circuit 15.

Note that the transparent electrode 52 may be configured to be electrically connected to the bonding pad 14 to which the power supply potential is applied from the outside among the plurality of bonding pads 14 shown in FIG. 1.

### Main Effects of First Embodiment

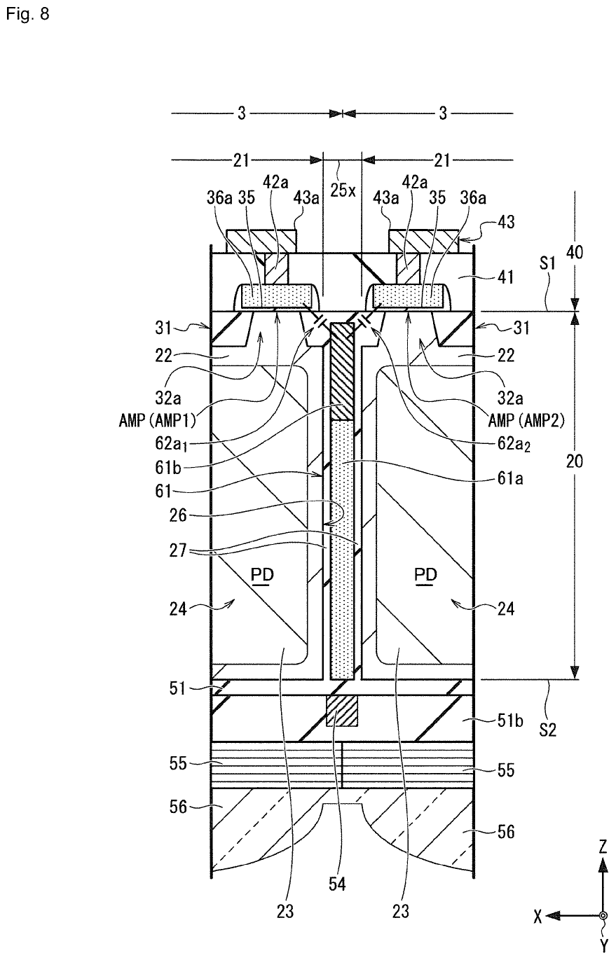

Next, the main effects of the first embodiment will be described with reference to FIGS. 7 and 8. FIG. 8 is a cross-sectional view schematically showing a longitudinal cross-sectional structure of a separation region according to a comparative example.

As shown in FIG. 8, a separation region 61 according to the comparative example has an embedded separation structure in which a non-conductor 61a made of, for example, a non-doped silicon film is embedded in the excavated portion 26 of the semiconductor layer 20 via the separation insulating film 27. On the other hand, a manufacturing process of a solid-state imaging apparatus includes several impurity ion implantation steps. For example, the source region and the drain region of the amplifying transistor AMP shown in FIG. 8 are formed by ion implantation of impurities.

In the ion implantation step of impurities, impurity ions are also implanted in an upper part of the non-conductor 61a of the separation region 61 and the upper part of the non-conductor 61a becomes conductive. In addition, due to the upper part of the non-conductor 61a becoming conductive, a conductive portion 61b may be formed in an upper part of the separation region 61 as shown in FIG. 8. The conductive portion 61b is in an electrically floating state.

When the conductive portion 61b described above is formed, as shown in FIG. 8, in two photoelectric conversion regions 21 in which respective amplifying transistors AMP (AMP1, AMP2) are adjacent to each other via the separation region 25, a first parasitic capacitance (first capacitive coupling) 62a₁ with the gate electrode 36a of the amplifying transistor AMP1 disposed in one of the photoelectric conversion regions 21 as one electrode and the conductive portion 61b of the separation region 61 as another electrode is formed. In addition, a second parasitic capacitance (second capacitive coupling) 62a₂ with the gate electrode 36a of the amplifying transistor AMP2 disposed in the other photoelectric conversion region 21 as one electrode and the conductive portion 61b of the separation region 61 as another electrode is formed. In addition, the first parasitic capacitance 62a₁ and the second parasitic capacitance 62a₂ are capacitively coupled via the conductive portion 61b of the separation region 61. Via the capacitive coupling, noise during an operation of the one amplifying transistor AMP1 propagates to the other amplifying transistor AMP2 and, conversely, noise during an operation of the other amplifying transistor AMP2 propagates to the one amplifying transistor AMP1. The propagation of noise between the amplifying transistors AMP (AMP1, AMP2) causes a decline in image quality and results in lower reliability.

Specifically, between pixels 3 (Gr pixels 3) including the red (R) color filter 55 and pixels 3 (Gb pixels 3) including the blue (B) color filter 55, the photoelectric conversion units 24 are connected via conductive paths to the amplifying transistors AMP of different readout circuits 15. Therefore, due to the propagation of noise between the amplifying transistors AMP (AMP1, AMP2) via the capacitive coupling between the first parasitic capacitance 62a₁ and the second parasitic capacitance 62a₂, an output level difference occurs between the Gr pixels 3 and the Gb pixels 3 and a variance in output is created among the pixels 3. The variance in output among the pixels 3 causes a decline in image quality and results in lower reliability.

In contrast, as shown in FIG. 7, the separation region 25 according to the first embodiment has an embedded separation structure in which the conductor 28 is embedded in the excavated portion 26 of the semiconductor layer 20 via the separation insulating film 27. In addition, the transparent electrode 52 to which a power supply potential is applied is electrically connected to the conductor 28 of the separation region 25 on the side of the second surface S2 of the semiconductor layer 20. As a result, although the first parasitic capacitance 62a₁ and the second parasitic capacitance 62a₂ are formed in a similar manner to the comparative example described above, the propagation of noise between the amplifying transistors AMP can be suppressed. In addition, since the propagation of noise between the amplifying transistors AMP (AMP1, AMP2) can be suppressed, a variance in output among the pixels 3 attributable to an output level difference between the Gr pixels 3 and the Gb pixels 3 can be suppressed and a decline in image quality can be suppressed. In other words, image quality can be improved. Therefore, the solid-state imaging apparatus 1A according to the first embodiment is capable of improving image quality. In addition, the solid-state imaging apparatus 1A according to the first embodiment is capable of suppressing a decline in image quality and further improving reliability.

In addition, since the transparent electrode 52 is disposed on the side of the light incident surface (the side of the second surface S2) on the opposite side to the side of the multilayer wiring layer 40 (the side of the first surface S1) of the semiconductor layer 20, even if wiring density of the multilayer wiring layer 40 increases due to miniaturization of the pixels 3 (the photoelectric conversion regions 21), potential fixing (power feeding) to the conductor 28 can be readily performed.

Furthermore, since the transparent electrode 52 is constituted of a solid planar pattern, a potential variance (unevenness) in which the potential of the conductor 28 of the separation region 25 differs from one location to the next can be suppressed. In particular, a potential difference between a center region and a peripheral region of the pixel array portion 2A can be suppressed.

In the first embodiment, the suppression of propagation of noise between respective amplifying transistors AMP of two photoelectric conversion regions 21 adjacent to each other has been described as an example. However, it is needless to say that the present technique is not limited to the suppression of propagation of noise between the amplifying transistors AMP and that propagation of noise can also be suppressed between other pixel transistors that are adjacent to each other via the separation region 25.

### Modifications of First Embodiment

The solid planar pattern 52a which spreads over a plurality of the photoelectric conversion regions 21 (pixels 3) in a plan view has been described as the planar pattern of the transparent electrode 52 in the first embodiment described above. However, the present technique is not limited to the solid planar pattern 52a as the planar pattern of the transparent electrode 52 and other planar patterns may be adopted.

### First Modification

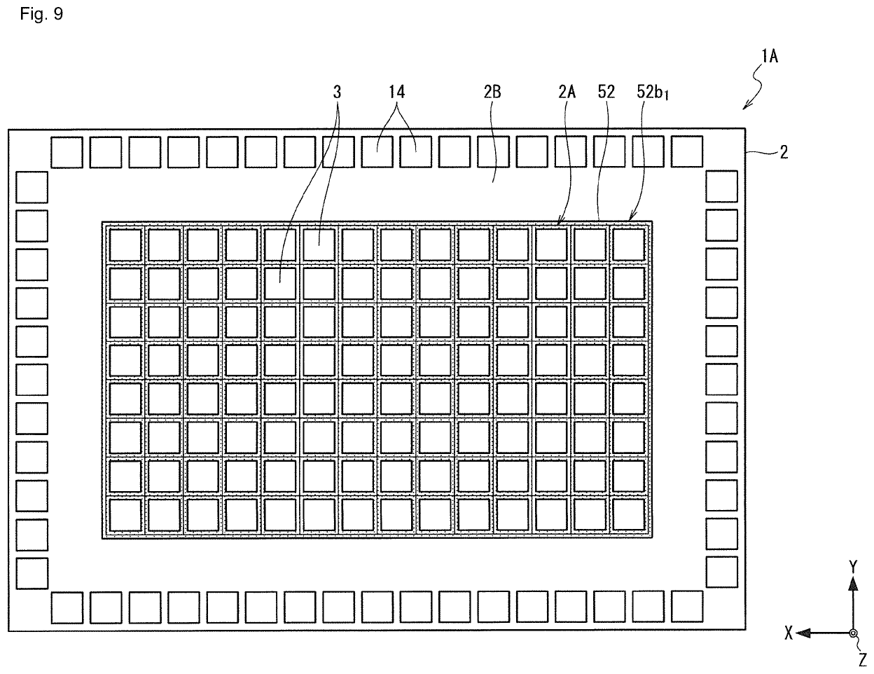

For example, as shown in FIG. 9, the transparent electrode 52 may be constituted of a planar pattern 52b₁ with a similar grid shape as the separation region 25. The transparent electrode 52 according to the first modification is preferably disposed at a position overlapping the separation region 25 in a plan view. In addition, a connection portion where the transparent electrode 52 according to the first modification and the conductor 28 of the separation region 25 are connected to each other may be performed continuously or intermittently along the grid-like planar pattern 52b₁. Even in the first modification of the first embodiment, the same effects as in the first embodiment described above can be obtained.

### Second Modification

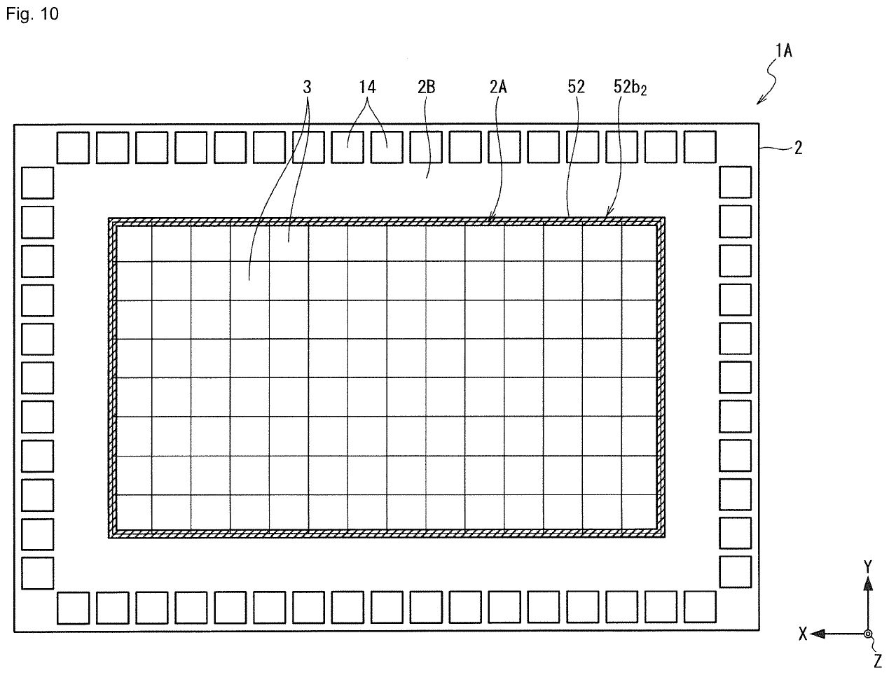

In addition, as shown in FIG. 10, the transparent electrode 52 may be constituted of a ring-like planar pattern 52b₂ along a periphery of the pixel array portion 2A. The transparent electrode 52 according to the second modification is also preferably disposed at a position overlapping the separation region 25 in a plan view.

Furthermore, a connection portion where the transparent electrode 52 according to the second modification and the conductor 28 of the separation region 25 are connected to each other may be performed continuously or intermittently along the ring-like planar pattern 52b₂. Even in the second modification of the first embodiment, the same effects as in the first embodiment described above can be obtained.

### Third Modification

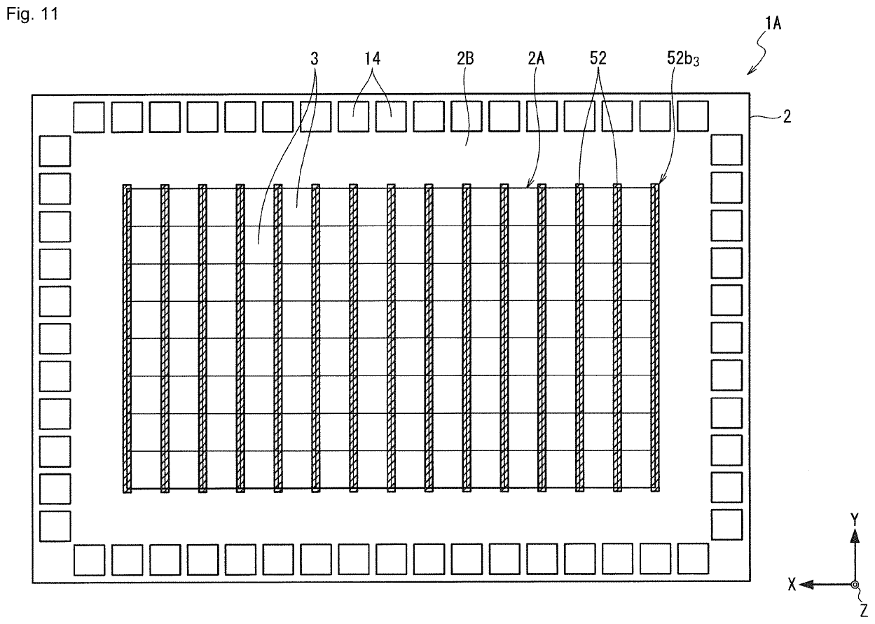

In addition, as shown in FIG. 11, the transparent electrode 52 may be constituted of a striped planar pattern 52b₃ that stretches in the Y direction. The transparent electrode 52 according to the third modification is preferably repetitively disposed in the X direction at positions overlapping the separation region 25 in a plan view. Furthermore, a connection portion where the transparent electrode 52 according to the third modification and the conductor 28 of the separation region 25 are connected to each other may be performed continuously or intermittently along the striped planar pattern 52b₃. Even in the third modification of the first embodiment, the same effects as in the first embodiment described above can be obtained.

### Fourth Modification

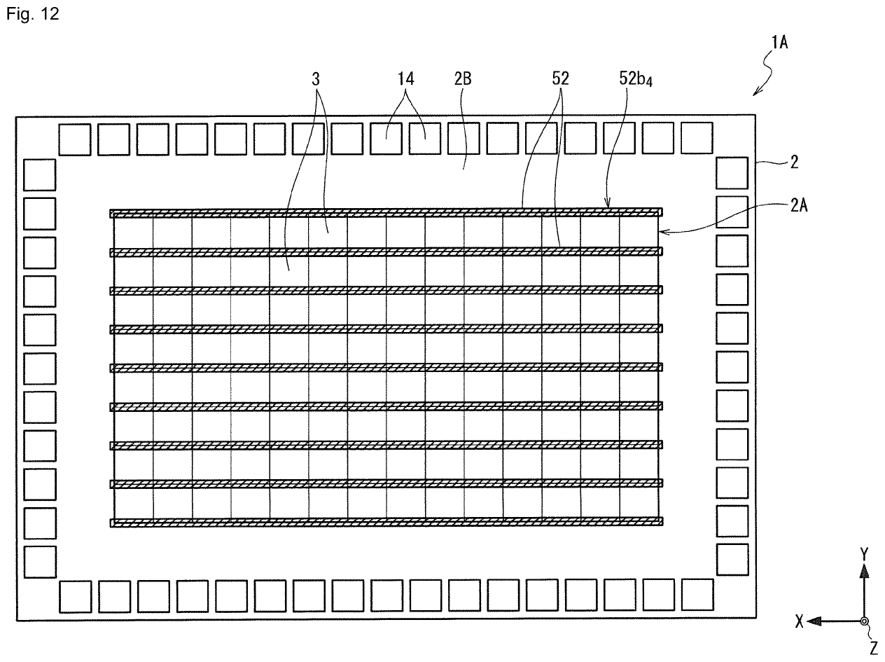

In addition, as shown in FIG. 12, the transparent electrode 52 may be constituted of a striped planar pattern 52b₄ that stretches in the X direction. The transparent electrode 52 according to the fourth modification is preferably repetitively disposed in the Y direction at positions overlapping the separation region 25 in a plan view. Furthermore, a connection portion where the transparent electrode 52 according to the fourth modification and the conductor 28 of the separation region 25 are connected to each other may be performed continuously or intermittently along the striped planar pattern 52b₄. Even in the fourth modification of the first embodiment, the same effects as in the first embodiment described above can be obtained.

### Second Embodiment

A solid-state imaging apparatus 1B according to a second embodiment of the present technique is basically configured in a similar manner to the solid-state imaging apparatus 1A according to the first embodiment described above but differs in the following aspects.

Specifically, as shown in FIGS. 6 and 7, the first embodiment described above adopts a configuration in which the transparent electrode 52 is directly connected to the conductor 28 of the separation region 25.

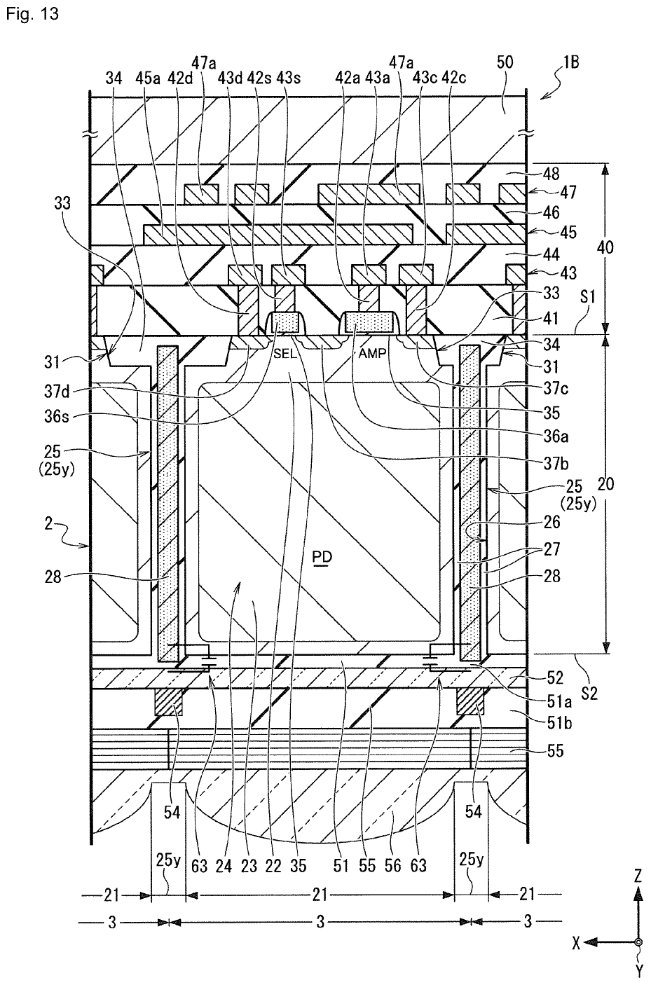

In contrast, in the second embodiment, the transparent electrode 52 is connected to the conductor 28 of the separation region 25 via a tunnel insulating film 51a as shown in FIG. 13. In addition, a power supply potential applied to the transparent electrode 52 is supplied by a capacitive coupling 63 and a potential of the conductor 28 is fixed to the supplied power supply potential. Since other configurations are more or less the same as those in the first embodiment described above, a description thereof in the second embodiment will be omitted.

Even with the solid-state imaging apparatus 1B according to the second embodiment, similar effects to those of the solid-state imaging apparatus 1A according to the first embodiment described above can be obtained.

### Third Embodiment

In a third embodiment, a technique of suppressing image quality degradation due to a capacitive coupling by causing a conductor of a separation region to float will be described.

A solid-state imaging apparatus 1C according to the third embodiment of the present technique is basically configured in a similar manner to the solid-state imaging apparatus 1A according to the first embodiment described above but differs in the following aspects.

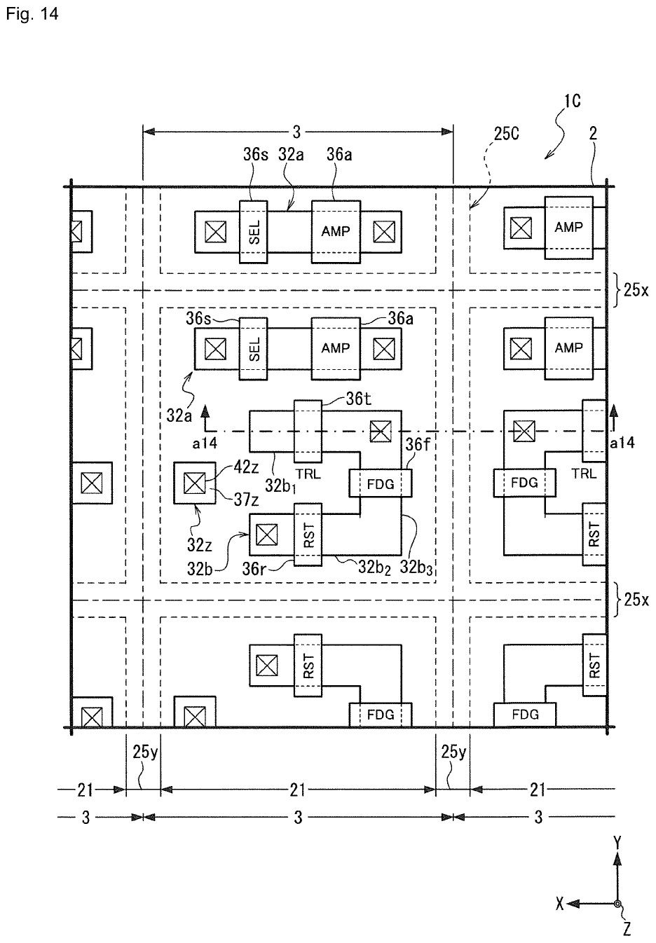

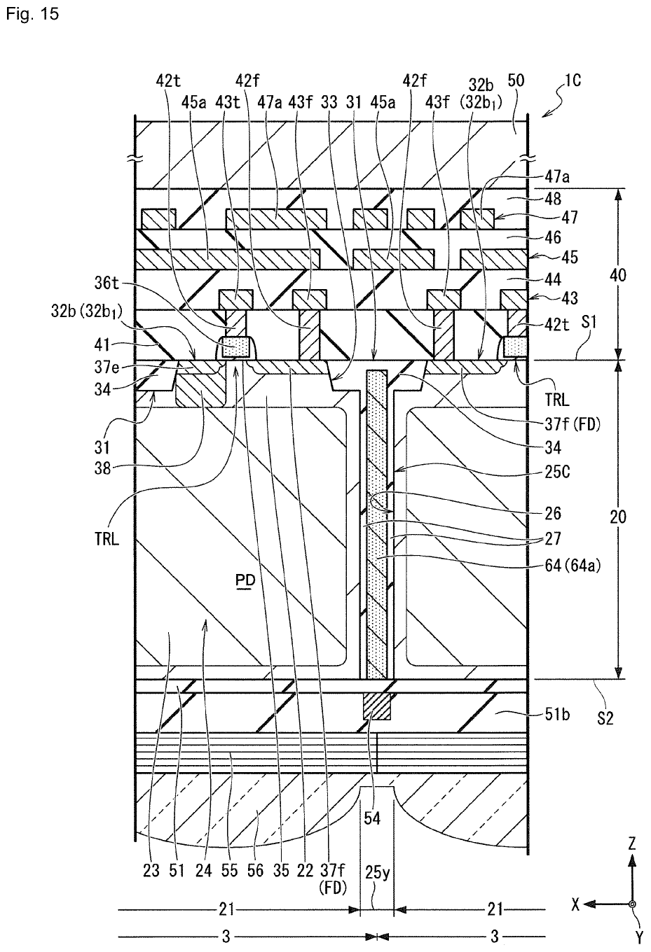

Specifically, as shown in FIG. 14, the solid-state imaging apparatus 1C according to the third embodiment differs in an orientation of the second element formation region 32b included in the photoelectric conversion region 21. In addition, as shown in FIG. 15, the solid-state imaging apparatus 1C according to the third embodiment includes a separation region 25C in place of the separation region 25 shown in FIGS. 6 and 7 according to the first embodiment described above. Furthermore, while the transparent electrode 52 is provided in the first embodiment described above, the transparent electrode 52 is not provided in the present third embodiment.

### <Second Element Separation Region>

As shown in FIG. 14, in the second element formation region 32b according to the third embodiment, the second portion 32b₂ is positioned closer to the side of the first element formation region 32a than the first portion 32b₁ and each of the first portion 32b₁ and the second portion 32b₂ is disposed so as to be aligned with the third portion 32b₃ in the Y direction.

Unlike in the first embodiment described above, in the second element formation region 32b according to the third embodiment, the second portion 32b₂ is provided with the reset transistor RST and the third portion 32b₃ is provided with the switching transistor FDG. In addition, the first portion 32b₁ is provided with the transfer transistor RTL.

### <Transfer Transistor>

As shown in FIG. 15, the transfer transistor TRL includes the gate insulating film 35 provided on the second element formation region 32b on the side of the first surface S1 of the semiconductor layer 20, the gate electrode 36t provided on the second element formation region 32b via the gate insulating film 35, and a side wall spacer provided on a side wall of the gate electrode 36t so as to enclose the gate electrode 36t in a similar manner to the amplifying transistor AMP and the selection transistor SEL. In addition, the transfer transistor TRL further includes a channel formation region in which a channel (conduction path) is formed in the p-type well region 22 directly beneath the gate electrode 36t and a pair of main electrode regions 37e and 37f which are provided in the p-type well region 22 so as to separate from each other in the channel length direction (gate length direction) and to sandwich the channel formation region and which function as a source region and a drain region. Furthermore, unlike the amplifying transistor AMP and the selection transistor SEL described above, the transfer transistor TRL further includes an n-type relay region 38 which is provided in the p-type well region 22 between one main electrode region 37e and the n-type semiconductor region 23 and which is electrically connected to each of the one main electrode region 37e and the n-type semiconductor region 23. The n-type relay region 38 is constituted of an n-type semiconductor region.

As shown in FIG. 15, each of the pair of main electrode regions 37e and 37f includes, but is not limited to, an extension region which is constituted of an n-type semiconductor region and which is formed by self-alignment with respect to the gate electrode 36t and a contact region which is constituted of an n-type semiconductor region with a higher impurity concentration than the extension region and which is formed by self-alignment with respect to the side wall spacer of the side wall of the gate electrode 36t.

One main electrode region (source region) of the transfer transistor TRL is electrically connected to the n-type semiconductor region 23 of the photoelectric conversion unit 24 via the n-type relay region 38 and the other main electrode region (drain region) of the transfer transistor TRL is shared with the one main electrode region (source region) of the switching transistor FDG. In addition, the other main electrode region (drain region) 37f of the transfer transistor TRL functions as the electric charge holding region FD shown in FIG. 2.

As shown in FIG. 15, the first wiring layer 43 is also provided with a wiring 43f and a wiring 43t. The wiring 43t is electrically connected to the gate electrode 36t of the transfer transistor TRL via a contact electrode (conductive plug) 42t embedded in the interlayer insulating film 41. The wiring 43f is electrically connected to the other main electrode region 37f (electric charge holding region FD) of the transfer transistor TRL via a contact electrode (conductive plug) 42f embedded in the interlayer insulating film 41. The wiring 43f is electrically connected to an input side of the readout circuit 15 described earlier.

### <Separation Region>

While the separation region 25C according to the third embodiment is basically configured in a similar manner to the separation region 25 according to the first embodiment described above, the separation region 25C differs in a structure of a longitudinal cross-section along the thickness direction (Z direction) of the semiconductor layer 20. In other words, as shown in FIG. 15, the separation region 25C according to the third embodiment includes a separation insulating film 27 provided along the inner wall of the excavated portion 26 that stretches in the thickness direction (Z direction) of the semiconductor layer 20 and a floating conductor 64 provided in the excavated portion 26 of the semiconductor layer 20 via the separation insulating film 27. In other words, the separation region 25C includes the floating conductor 64 which is embedded in the semiconductor layer 20 via the separation insulating film 27 and which is insulated and separated from the semiconductor layer 20. The separation insulating film 27 and the floating conductor 64 stretch in the thickness direction of the semiconductor layer 20, and one end of each of the separation insulating film 27 and the floating conductor 64 is coupled to the element separation region 31 while another end of each of the separation insulating film 27 and the floating conductor 64 reaches the second surface S2 of the semiconductor layer 20.

The floating conductor 64 is enclosed by an insulator that includes the separation insulating film 27 and is insulated from conductors and semiconductors to which a power supply potential is applied. In addition, while the floating conductor 64 is conductive, unlike the conductor 28 according to the first embodiment, a potential of the floating conductor 64 is not fixed to the power supply potential and the floating conductor 64 is used in an electrically floating state. For example, the floating conductor 64 is constituted of an n-type silicon film 64a into which phosphorus (P) as an impurity for reducing a resistance value has been introducing during film formation (deposition) as a conductive semiconductor layer.

The separation region 25C has a grid-like planar pattern in which the first portion 25x which stretches in the X direction and the second portion 25y which stretches in the Y direction are orthogonal to each other in a similar manner to the separation region 25 according to the first embodiment. In addition, the floating conductor 64 of the separation region 25C also has a grid-like planar pattern.

### Main Effect of Third Embodiment

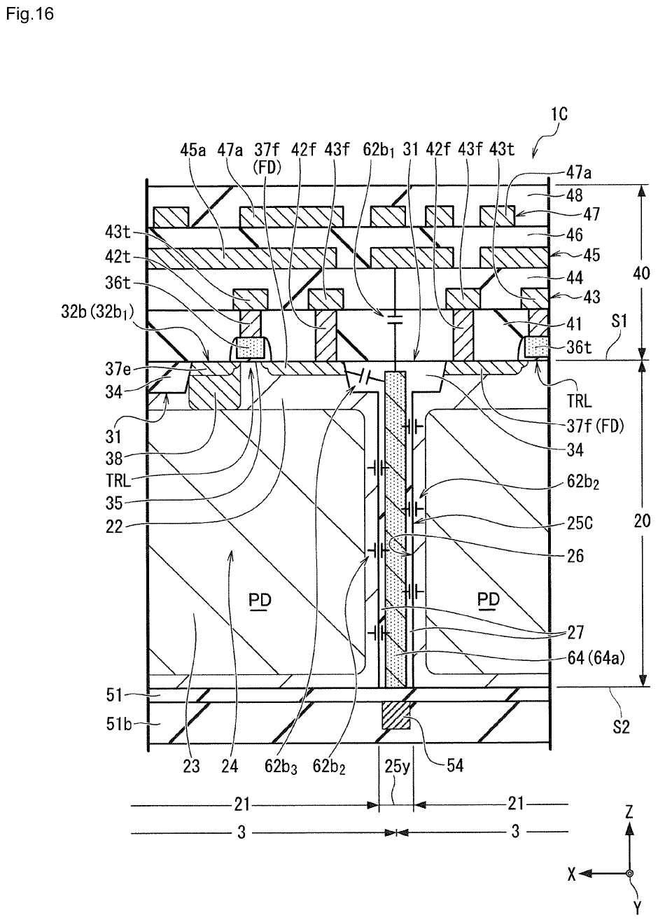

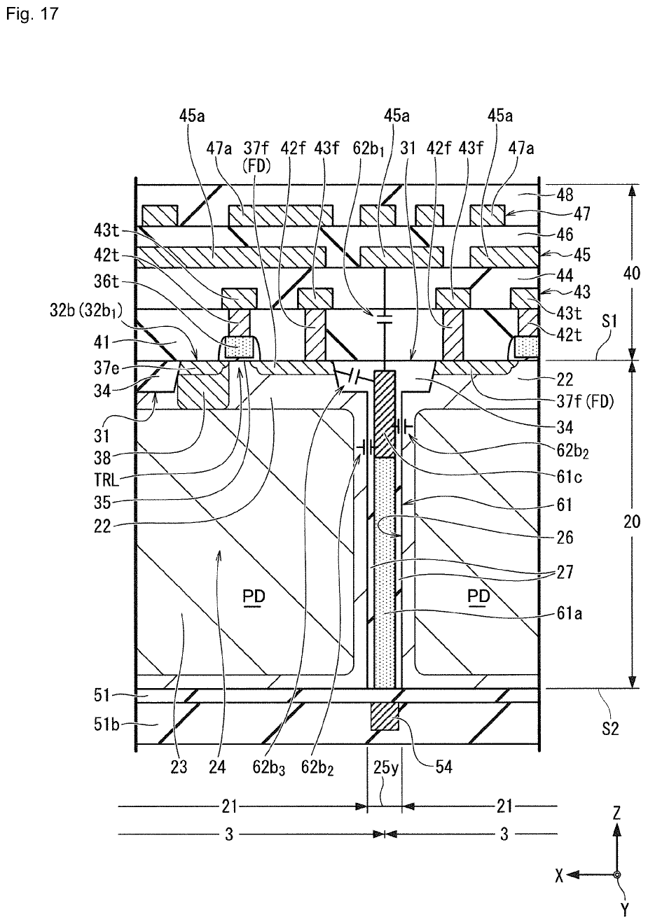

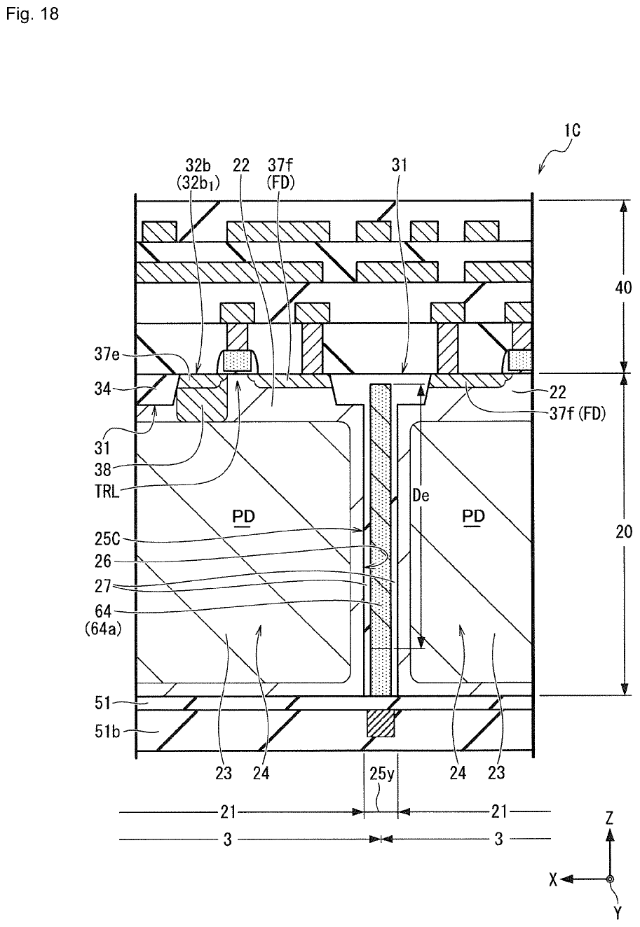

Next, the main effects of the third embodiment will be described with reference to FIGS. 16 and 17. FIG. 16 is a diagram showing a parasitic capacitance which is added to the separation region 25C according to the third embodiment. FIG. 17 is a cross-sectional view schematically showing a longitudinal cross-sectional structure of a separation region according to a comparative example. FIG. 18 is a longitudinal cross-sectional view showing a depth of the separation region 25C. Note that the color filter 55, the microlens 56, and the supporting substrate 50 shown in FIG. 15 have been omitted in FIGS. 16 to 18.

As shown in FIG. 17, the separation region 61 according to the comparative example has an embedded separation structure in which the non-conductor 61a made of, for example, a non-doped silicon film is embedded in the excavated portion 26 of the semiconductor layer 20 via the separation insulating film 27. On the other hand, a manufacturing process of a solid-state imaging apparatus includes several impurity ion implantation steps.

In the ion implantation step of impurities, impurity ions are also implanted in an upper part of the non-conductor 61a of the separation region 61 and the upper part of the non-conductor 61a becomes conductive. In addition, due to the upper part of the non-conductor 61a becoming conductive, for example, a p-type conductive portion 61c may be formed in an upper part of the separation region 61 as shown in FIG. 17. The conductive portion 61c is in an electrically floating state.

When the conductive portion 61c described above is formed, as shown in FIG. 17, a first parasitic capacitance (first capacitive coupling) 62b₁ with the wiring 45a of the multilayer wiring layer as one electrode and the conductive portion 61c of the separation region 61 as another electrode is formed. In addition, a second parasitic capacitance (second capacitive coupling) 62b₂ with the p-type well region 22 of the semiconductor layer 20 as one electrode and the conductive portion 61c of the separation region 61 as another electrode is formed. Furthermore, a third parasitic capacitance (third capacitive coupling) 62b₃ with the electric charge holding region FD (the other main electrode region 37f of the transmission transistor TRL) as one electrode and the conductive portion 61c of the separation region 61 as another electrode is formed. In addition, the first to third parasitic capacitances 62b₁, 62b₂, and 62b₃ are capacitively coupled via the conductive portion 61c of the separation region 61.

Furthermore, when a signal is applied to the wiring 45a, a potential of the conductive portion 62c of the separation region 61 fluctuates via the first parasitic capacitance 62b₁. At this point, since a depth of the conductive portion 61c in the Z direction is shallow and the second parasitic capacitance 62b₂ is small, the fluctuation of the potential of the conductive portion 61c increases. In addition, due to the large fluctuation of the potential of the conductive portion 61c, the potential of the electric charge holding region FD fluctuates greatly via the third parasitic capacitance 62b₃. Specifically, noise of the wiring 45a propagates to the electric charge holding region FD (the n-type semiconductor region 37f) via the capacitive coupling of the first to third parasitic capacitances 62b₁, 62b₂, and 62b₃. Since a state of a signal of the wiring changes significantly in a state where signal charges of the Gr pixels 3 and the Gb pixels 3 are read out and the signal state of the wiring changes for each readout, an output level difference occurs between the Gr pixels 3 and the Gb pixels 3 and a variance in output is created among the pixels 3. In addition, random noise (RN) is also generated. The variance in output among the pixels 3 and the random noise cause a decline in image quality and results in lower reliability.

In contrast, as shown in FIG. 16, the separation region 25C according to the third embodiment has an embedded separation structure in which the floating conductor 64 which stretches in the thickness direction (Z direction) of the semiconductor layer 20 and which is in an electrically floating state is embedded in the excavated portion 26 of the semiconductor layer 20 via the separation insulating film 27. Even in the case of the separation region 25C with the embedded separation structure, first to third parasitic capacitances 62b₁, 62b₂, and 62b₃ are formed in a similar manner to the separation region 61 according to the comparative example described above as shown in FIG. 16. However, since the second parasitic capacitance 62b₂ can be increased in accordance with the length of the floating conductor 64 in the Z direction (the thickness direction of the semiconductor layer 20), a fluctuation of potential which occurs in the floating conductor 64 of the separation region 61 can be suppressed via the first parasitic capacitance 62b₁ when a signal is applied to the wiring 45a. In addition, since the fluctuation of potential which occurs in the floating conductor 64 of the separation region 61 can be suppressed, a fluctuation of potential which occurs in the electric charge holding region FD via the third parasitic capacitance 62b₃ can be suppressed. As a result, an effect on a variance in output among the pixels 3 attributable to an output level difference between the Gr pixels 3 and the Gb pixels 3 and on random noise (RN) can be suppressed and a decline in image quality can be suppressed. In other words, image quality can be improved. Therefore, the solid-state imaging apparatus 1C according to the third embodiment is capable of improving image quality. In addition, the solid-state imaging apparatus 1C according to the third embodiment is capable of suppressing a decline in image quality and further improving reliability.

In this case, as shown in FIG. 18, a depth (length) De of the floating conductor 64 in the Z direction is preferably 2 μm or more. Signal fluctuation can be suppressed to 1/10 if the depth De of the floating conductor 64 in the Z direction is 2 μm or more. In this case, the floating conductor 64 may reach the second surface S2 of the semiconductor layer 20 or be separated from the second surface S2 of the semiconductor layer 20. FIG. 18 shows a state where the floating conductor 64 has reached the second surface S2 of the semiconductor layer 20.

In addition, in the case of a backside-illuminated image sensor, a thickness of the semiconductor layer 20 in the photoelectric conversion region 21 is usually 2.5 μm or more and an entire length of the floating conductor 64 of the separation region 25C in the depth direction (Z direction) becomes an object of the second parasitic capacitance 62b₂.

On the other hand, with an infrared sensor or the like, the thickness of the semiconductor layer 20 may equal or exceed 6 μm and the separation region 25C may be constructed by embedding material from both the side of the first surface S1 and the side of the second surface S2 of the semiconductor layer 20, in which case only the embedding material from the side of the first surface S1 of the semiconductor layer 20 may be considered the floating conductor 64.

### Modifications of Third Embodiment

A case where the floating conductor 64 is constructed using, for example, the n-type silicon film 64a into which phosphorus (P) is introduced as a conductive semiconductor film has been described in the third embodiment presented above. However, the present technique is not limited to the n-type silicon film 64a as a material of the floating conductor 64.

### First Modification

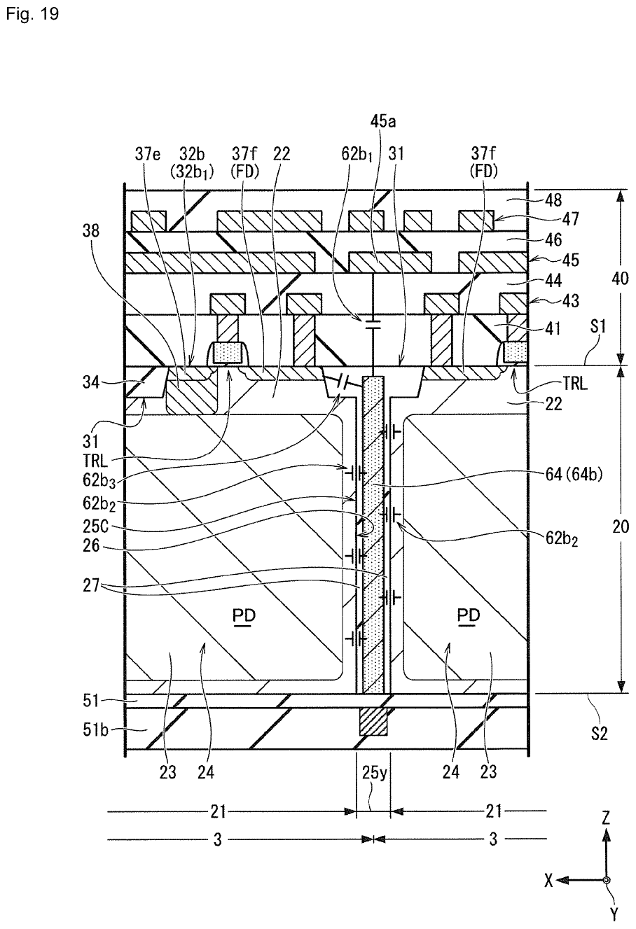

For example, as shown in FIG. 19, the floating conductor 64 may be constituted of a p-type silicon film 64b as a conductive semiconductor film. For example, boron is introduced to the p-type silicon film 64b as an impurity that reduces a resistance value. Even when the floating conductor 64 is constituted of the p-type silicon film 64b, since the second parasitic capacitance 62b₂ can be increased in accordance with the length of the floating conductor 64 in the Z direction, a similar effect to the third embodiment described above can be obtained.

### Second Modification

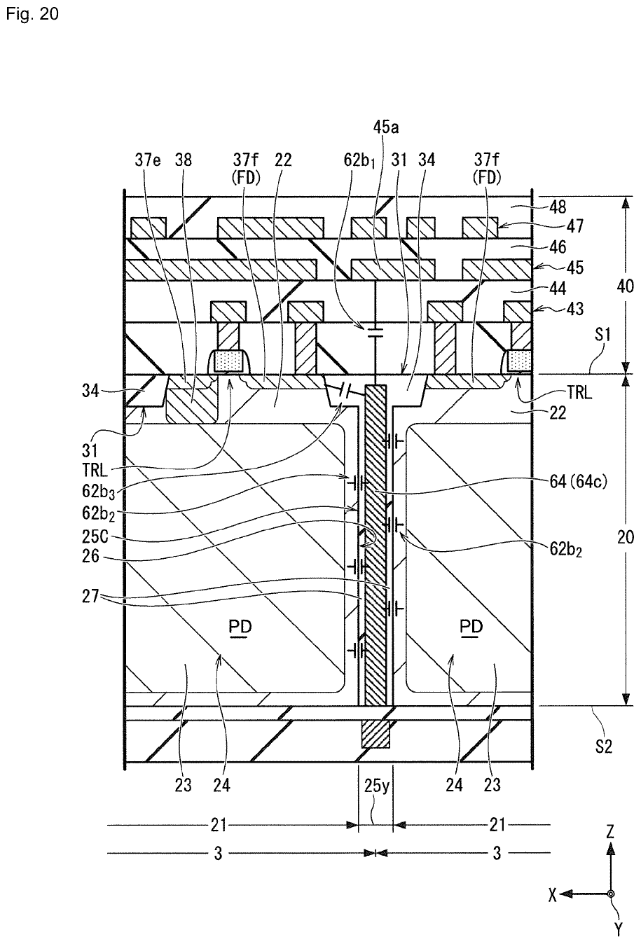

In addition, as shown in FIG. 20, the floating conductor 64 may be constituted of a metal film 64c. As the metal film 64c, a high-melting point metal film such as tungsten (W), titanium (Ti), or molybdenum (Mo) can be used. Even when the floating conductor 64 is constituted of the metal film 64c, since the second parasitic capacitance 62b₂ can be increased in accordance with the length of the floating conductor 64 in the Z direction, a similar effect to the third embodiment described above can be obtained.

Note that the color filter 55, the microlens 56, and the supporting substrate 50 shown in FIG. 15 have been omitted in FIGS. 19 and 20.

### Fourth Embodiment

In a fourth embodiment, potential fixing of a well region will be described.

A solid-state imaging apparatus 1D according to the fourth embodiment of the present technique is basically configured in a similar manner to the solid-state imaging apparatus 1A according to the first embodiment described above but differs in the following aspects.

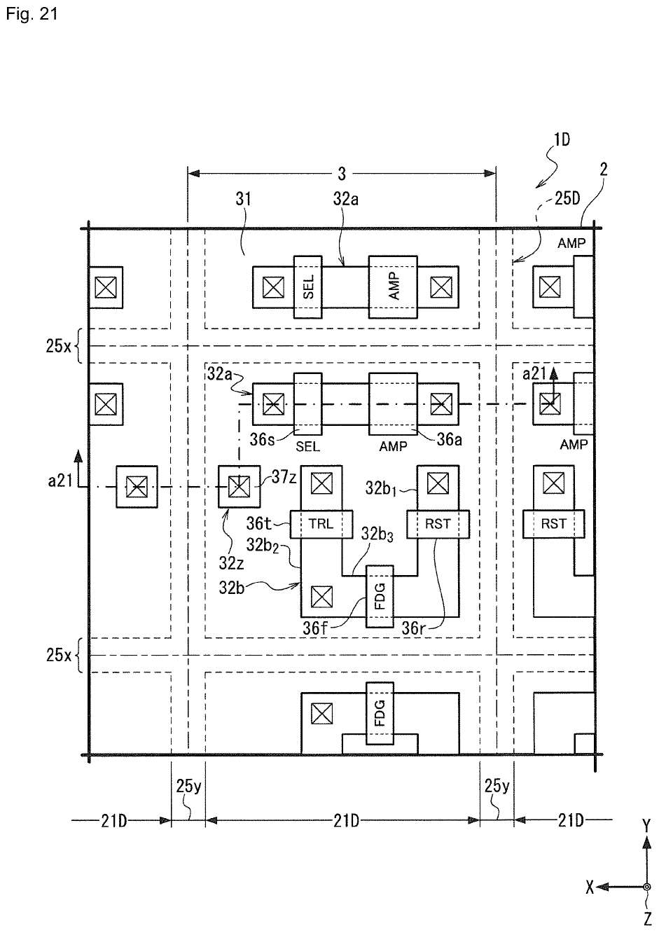

Specifically, as shown in FIGS. 21 and 22, the solid-state imaging apparatus 1D according to the fourth embodiment includes the photoelectric conversion region 21D and a separation region 25D in place of the photoelectric conversion region 21 and the separation region 25 shown in FIGS. 5 and 6 of the first embodiment described above. In addition, even in the solid-state imaging apparatus 1D according to the fourth embodiment, the transparent electrode 52 is not provided in a similar manner to the solid-state imaging apparatus 1C according to the third embodiment described above.

As shown in FIGS. 21 and 22, the solid-state imaging apparatus 1D according to the fourth embodiment includes: the semiconductor layer 20 having the first surface S1 and the second surface S2 positioned on opposite sides to each other; the separation region 25D which is provided on the semiconductor layer 20 and which is a separation region stretching in the thickness direction (Z direction) of the semiconductor layer 20; and a plurality of photoelectric conversion regions 21D provided adjacent to each other via the separation region 25D on the semiconductor layer 20.

### <Photoelectric Conversion Region>

As shown in FIGS. 21 and 22, each photoelectric conversion region 21D of the plurality of photoelectric conversion regions 21D is partitioned by the separation region 25D. In addition, the photoelectric conversion region 21D is provided for each pixel 3 in a similar manner to the photoelectric conversion region 21 according to the first embodiment described above.

Each photoelectric conversion region 21D of the plurality of photoelectric conversion regions 21D includes the photoelectric conversion unit 24 provided on the semiconductor layer 20, the p-type well region 22 provided so as to overlap with the photoelectric conversion unit 24 in a plan view on the side of the first surface S1 of the semiconductor layer 20, and pixel transistors provided in the p-type well region 22. As the pixel transistor, the amplifying transistor AMP, the selection transistor SEL, the reset transistor RST, the switching transistor FDG, and the transfer transistor TRL included in the readout circuit 15 are provided in a similar manner to the first embodiment described above. The amplifying transistor AMP and the selection transistor SEL are provided in the first element formation region 32a partitioned by the element separation region 31. The reset transistor RST, the switching transistor FDG, and the transfer transistor TRL are provided in the second element formation region 32b partitioned by the element separation region 31.

In addition, as shown in FIG. 22, each photoelectric conversion region 21D of the plurality of photoelectric conversion regions 21D includes: an n-type semiconductor region 65 provided along the thickness direction (Z direction) of the semiconductor layer 20 between a side surface portion of the photoelectric conversion unit 24 and the separation region 25D; and a p-type well region 22d provided between a bottom surface portion of the photoelectric conversion unit 24 and the second surface S2 of the semiconductor layer 20.

The photoelectric conversion region 21D is provided for each pixel 3. As described above, the photoelectric conversion unit 24 is mainly constituted of the n-type semiconductor region 23 and configured as a p-n junction photodiode (PD) between the p-type well regions 22 and 22d and the n-type semiconductor region 23. The p-type well region 22d is constituted of a p-type semiconductor region in a similar manner to the p-type well region 22. The n-type semiconductor region 65 is constituted of a higher impurity concentration than the n-type semiconductor region 23. The n-type semiconductor region 65 functions as an electric charge accumulation region for accumulating charges.

In addition, as shown in FIGS. 21 and 22, each photoelectric conversion region 21D of the plurality of photoelectric conversion regions 21D includes the power feeding region 32z that is partitioned by the element separation region 31 in a similar manner to the first embodiment described above.

### <Power Feeding Region>

As shown in FIG. 22, the power feeding region 32z is provided with a p-type power feeding contact region 37z. The p-type power feeding contact region 37z is provided in contact with the p-type well region 22 provided in the photoelectric conversion region 21D and is electrically connected to the p-type well region 22. In addition, the p-type power feeding contact region 37z is electrically connected to a power feeding wiring 43z formed on the first wiring layer 43 via the power feeding contact electrode 42z which is embedded in the interlayer insulating film 41. The p-type power feeding contact region 37z is composed of a p-type semiconductor region having a higher impurity concentration than the p-type well region 22, and reduces ohmic contact resistance with the power feeding contact electrode 42z.

Although not illustrated, for example, a power supply generation circuit which generates a certain power supply voltage is electrically connected to the power feeding wiring 43z. In other words, a power supply potential is applied (supplied) via the power feeding wiring 43z, power feeding contact electrode 42z, and the like from the power supply generation circuit to the p-type power feeding contact region 37z of each of the plurality of photoelectric conversion regions 21D. In addition, a potential of the p-type well region 22 of each of the plurality of photoelectric conversion regions 21D is fixed to the power supply potential that is applied to each p-type power feeding contact region 37z. In the fourth embodiment, although not limited thereto, a first reference potential of, for example, 0 V is applied as the power supply potential to the p-type power feeding contact region 37z. The application of the power supply potential to the p-type power feeding contact region 37z and the potential fixing of the power supply potential of the p-type well region 22 are held during photoelectric conversion by the photoelectric conversion unit 24 or during driving of the pixel transistors (AMP, SEL, RST, FDG, and TRL) included in the readout circuit 15.

Note that a configuration in which the bonding pad 14 to which the power supply potential is applied from the outside among the plurality of bonding pads 14 shown in FIG. 1 and the p-type power feeding contact region 37z are electrically connected to each other may be adopted.

### <Separation Region>

As shown in FIG. 22, the separation region 25D includes a conductor 66. In addition, the p-type well regions 22 of the respective photoelectric conversion regions 21D which are adjacent to each other via the separation region 25D are electrically connected to each other via the conductor 66 of the separation region 25D. In other words, the separation region 25D includes the conductor 66 which is electrically connected to the p-type well regions 22 of the photoelectric conversion regions 21D that are adjacent to each other.

The conductor 66 is provided in the excavated portion 26 which stretches in the thickness direction (Z direction) of the semiconductor layer 20. The conductor 66 stretches in the thickness direction of the semiconductor layer 20 in a similar manner to the excavated portion 26, and one end of the conductor 66 is coupled to the element separation region 31 while another end on the opposite side to the one end reaches the second surface S2 of the semiconductor layer 20. In addition, the one end of the conductor 66 is directly connected inside the semiconductor layer 20 to the p-type well regions 22 of the respective photoelectric conversion regions 21D which are adjacent to each other and electrically and mechanically connected to each p-type well region 22. Furthermore, the other end of the conductor 66 is directly connected inside the semiconductor layer 20 to the p-type well regions 22d of the respective photoelectric conversion regions 21D which are adjacent to each other and electrically and mechanically connected to each p-type well region 22d.

The conductor 66 is constituted of a semiconductor film of a same conductivity type as the p-type well region 22. For example, the conductor 66 is constituted of a p-type silicon film 66a into which boron (B) has been introduced as an impurity for reducing a resistance value.

The conductor 66 made of the p-type silicon film 66a is provided between the respective n-type semiconductor regions 65 of the photoelectric conversion regions 21D that are adjacent to each other so as to form a p-n junction with the respective n-type semiconductor regions 65. In other words, on the one hand, the conductor 66 according to the fourth embodiment is electrically separated from the respective n-type semiconductor regions 65 and the n-type semiconductor regions 23 of the photoelectric conversion regions 21D that are adjacent to each other due to the p-n junction with the n-type semiconductor regions 65 and, on the other hand, the conductor 66 is electrically connected to the respective p-type well regions 22 of the photoelectric conversion regions 21D that are adjacent to each other.

The separation region 25D according to the fourth embodiment has a grid-like planar pattern in which the first portion 25x which stretches in the X direction and the second portion 25y which stretches in the Y direction are orthogonal to each other in a similar manner to the separation region 25 according to the first embodiment described earlier. In addition, the conductor 66 also has a grid-like planar pattern that is similar to the separation region 25D. Therefore, the respective p-type well regions 22 of the plurality of photoelectric conversion regions 21D that are respectively repetitively disposed in the X direction and the Y direction via the separation region 25D in the pixel array portion 2A are electrically connected via the conductor 66 of the separation region 25D.

### Main Effects of Fourth Embodiment

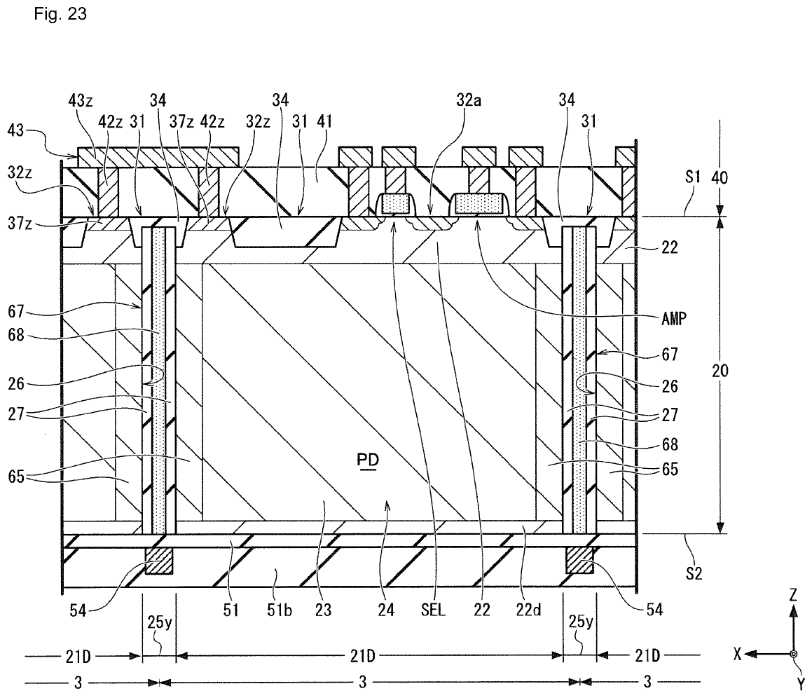

Next, the main effects of the fourth embodiment will be described using FIGS. 22 and 23. FIG. 23 is a longitudinal cross-sectional view schematically showing a longitudinal cross-sectional structure of a separation region according to a comparative example.

As shown in FIG. 23, a separation region 67 according to the comparative example has an embedded separation structure in which, for example, a non-doped silicon film 68 is embedded in the excavated portion 26 of the semiconductor layer 20 via the separation insulating film 27. In addition, in two photoelectric conversion regions 21D that are adjacent to each other via the separation region 67, the p-type well region 22 of one photoelectric conversion region 21D and the p-type well region 22 of the other photoelectric conversion region 21D are electrically and structurally separated by the separation region 67.

On the other hand, in the respective p-type well regions 22 of two photoelectric conversion regions 21D that are adjacent to each other via the separation region 67, the power feeding contact region 37z for supplying a power supply potential to the respective p-type well regions 22 is provided for each photoelectric conversion region 21D. In addition, the power feeding wiring 43z is electrically connected via the power feeding contact electrode 42z embedded in the interlayer insulating film 41 to the power feeding contact region 37z of each photoelectric conversion region 22D.

The power feeding contact electrode 42z is formed by forming a connection hole in the interlayer insulating film 41 and selectively embedding a conductive film in the connection hole. Therefore, when a conduction failure occurs between the power feeding contact region 37z and the power feeding contact electrode 42z due to a misalignment of a mask when forming the connection hole in the interlayer insulating film 41 or a decline in step coverage when embedding the conductive film in the connection hole during the formation step of the power feeding contact electrode 42z, the well region 22 of the photoelectric conversion region 21D enters a floating state and the photoelectric conversion region 21D (pixel 3) becomes defective. Since such a defect of the photoelectric conversion region 21D reduces production yield, there is room for improvement from the perspective of reliability.

In contrast, the separation region 25D according to the fourth embodiment includes the conductor 66. In addition, the respective p-type well regions 22 of two photoelectric conversion regions 21D that are adjacent to each other via the separation region 25D are electrically connected to each other via the conductor 66 of the separation region 25D. Therefore, by applying (supplying) a power supply potential to the power feeding contact region 37z of any one photoelectric conversion region 21D of the two photoelectric conversion regions 21D that are adjacent to each other via the separation region 25D, potentials of the respective p-type well regions 22 of the two photoelectric conversion regions 21D can be fixed. As a result, even if a conduction failure occurs between the power feeding contact region 37z and the power feeding contact electrode 42z in any one photoelectric conversion region 21D of the two photoelectric conversion regions 21D that are adjacent to each other via the separation region 25D, the potential of the p-type well region 22 of the one photoelectric conversion region 21D can be fixed to the power supply potential and the one photoelectric conversion region 21D can be prevented from becoming defective. Therefore, with the solid-state imaging apparatus 1D according to the fourth embodiment, an improvement in production yield can be achieved. In addition, with the solid-state imaging apparatus 1D according to the fourth embodiment, since an improvement in production yield can be achieved, reliability can be further improved.

Furthermore, since the conductor 66 of the separation region 25D is electrically connected to the p-type well region 22, by applying the power supply potential to the power feeding contact region 37z, the potential of the conductor 66 of the separation region 25D is fixed together with the p-type well region 22. Therefore, in two photoelectric conversion regions 21D that are adjacent to each other via the separation region 25D, propagation of noise that is attributable to a capacitive coupling of parasitic capacitances between pixel transistors of one photoelectric conversion region 21D and pixel transistors of the other photoelectric conversion region 21D can be suppressed in a similar manner to the first embodiment described earlier. Accordingly, the solid-state imaging apparatus 1D according to the fourth embodiment can also improve image quality in a similar manner to the solid-state imaging apparatus 1A according to the first embodiment described earlier.

Although not illustrated in FIG. 22, even in the solid-state imaging apparatus 1D according to the fourth embodiment, the color filter 55 and the microlens 56 shown in FIG. 6 are provided on the side of the light incident surface (the side of the second surface S2) of the semiconductor layer 20.

### Modifications of Fourth Embodiment

In the fourth embodiment presented above, a case where the power feeding contact region 37z is provided for each photoelectric conversion region 21D has been described. However, since the separation region 25D and the conductor 66 are in a grid-like planar pattern, one power feeding contact region 37z may be shared by a plurality of separation regions 25D.

### First Modification

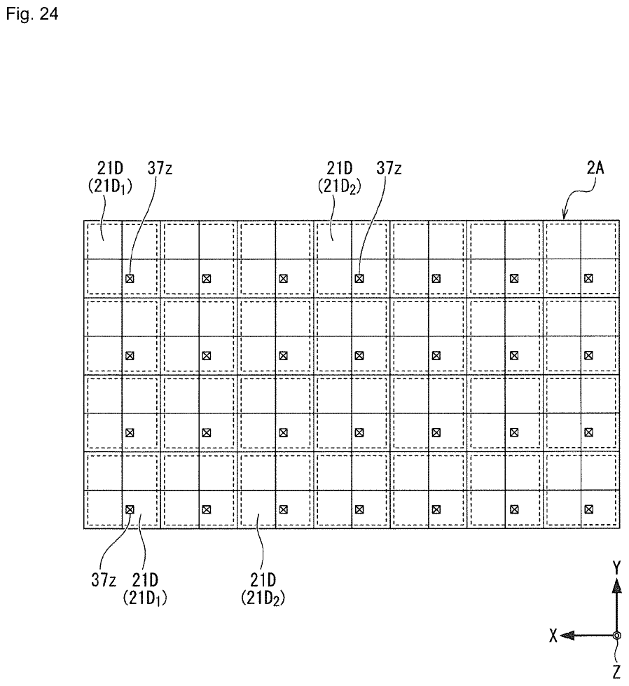

For example, as shown in FIG. 24, one power feeding contact region 37z may be shared by four photoelectric conversion regions 21D enclosed by dotted lines. In the case of the first modification shown in FIG. 24, the plurality of photoelectric conversion regions 21D constituting the pixel array portion 2A include a first photoelectric conversion region 21D₁ which includes the power feeding contact region 37z to which a power supply potential is applied and a second photoelectric conversion region 21D₂ which does not include the power feeding contact region 37z.

### Second Modification

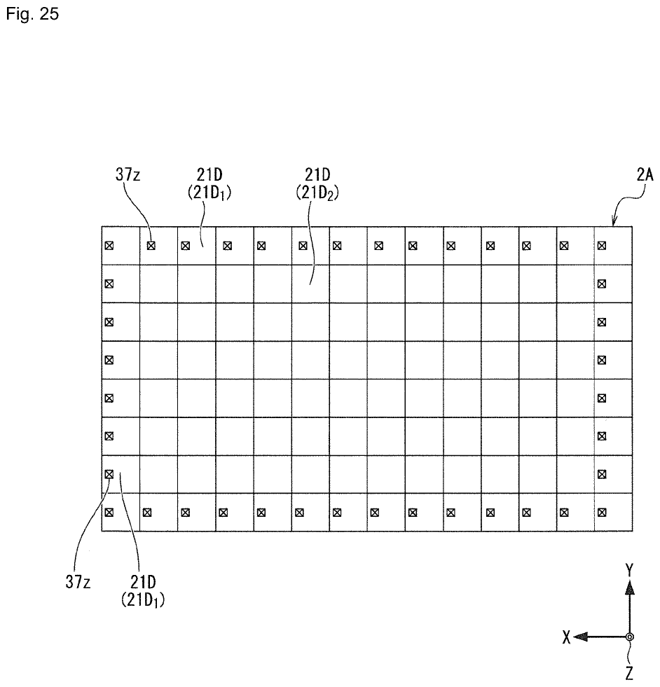

In addition, as shown in FIG. 25, one or two or more power feeding contact regions 37z may be shared by every plurality of photoelectric conversion regions 21D disposed in a single row in the X direction or the Y direction. Even in the second modification shown in FIG. 25, the plurality of photoelectric conversion regions 21D constituting the pixel array portion 2A include the first photoelectric conversion region 21D₁ which includes the power feeding contact region 37z to which a power supply potential is applied and the second photoelectric conversion region 21D₂ which does not include the power feeding contact region 37z.

By having every plurality of photoelectric conversion regions 21D share one power feeding contact region 37z as in the first modification and the second modification of the fourth embodiment, the numbers of power feeding contact regions 37z and the power feeding contact electrodes 42z can be reduced and a further improvement in production yield can be achieved.

In addition, in the second photoelectric conversion region 21D₂ which does not include the power feeding contact region 37z, a degree of freedom of arrangement of the pixel transistors (AMP, SEL, RST, FDG, and TRL) is increased, a volume of the photoelectric conversion unit 24 (n-type semiconductor region 23) can be increased when a planar size of the second photoelectric conversion region 21D₂ is made constant, and a saturation signal amount Qs can be improved. As a result, image quality can be improved. Furthermore, when the volume of the photoelectric conversion unit 24 is made constant, miniaturization of the photoelectric conversion region 21D can be achieved.

### Fifth Embodiment

A solid-state imaging apparatus 1E according to a fifth embodiment of the present technique is basically configured in a similar manner to the solid-state imaging apparatus 1D according to the fourth embodiment described above but differs in the following aspects.

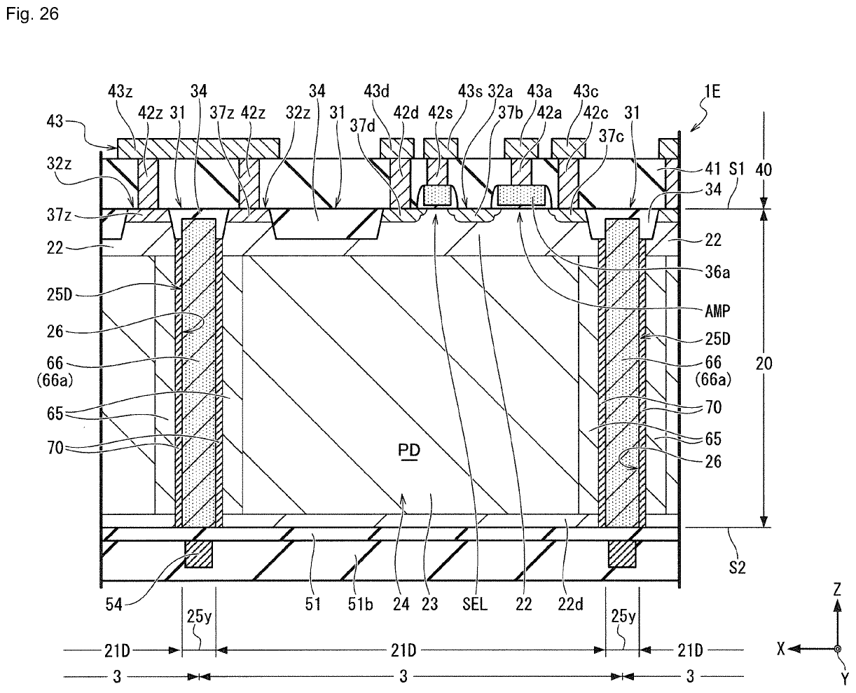

Specifically, as shown in FIG. 26, the solid-state imaging apparatus 1E according to the fifth embodiment further includes a p-type semiconductor region 70 provided on a side of the separation region 25D of the photoelectric conversion region 21D.

The p-type semiconductor region 70 is provided along the depth direction of the semiconductor layer 20 between the n-type semiconductor region 65 and the conductor 66 (p-type silicon film 66a) of the separation region 25D. The p-type semiconductor region 70 is constituted of a higher impurity concentration than the p-type well region 22. One end of the p-type semiconductor region 70 is coupled to the element separation region 31 while another end on the opposite side to the one end reaches the second surface S2 of the semiconductor layer 20. In addition, the one end of the p-type semiconductor region 70 is provided between the p-type well region 22 and the conductor 66 and the p-type well region 22 and the conductor 66 are electrically connected to each other via the one end of the p-type semiconductor region 70. Furthermore, respective p-type well regions 22 of photoelectric conversion regions 21D that are adjacent to each other are electrically connected to each other via the p-type semiconductor region 70 and the conductor 66. In addition, the other end of the p-type semiconductor region 70 is provided between the p-type well region 22d and the conductor 66 and the p-type well region 22d and the conductor 66 are electrically connected to each other via the other end of the p-type semiconductor region 70. Furthermore, respective p-type well regions 22d of photoelectric conversion regions 21D that are adjacent to each other are electrically connected to each other via the p-type semiconductor region 70 and the conductor 66. The p-type semiconductor region 70 functions as a pinning layer which secures pinning of the side wall of the separation region 25D.

Even with the solid-state imaging apparatus 1E according to the fifth embodiment, similar effects to those of the solid-state imaging apparatus 1D according to the fourth embodiment described above can be obtained.

Although not illustrated in FIG. 26, even in the solid-state imaging apparatus 1E according to the fifth embodiment, the color filter 55 and the microlens 56 shown in FIG. 6 are provided on the side of the light incident surface (the side of the second surface S2) of the semiconductor layer 20.

### Sixth Embodiment

A solid-state imaging apparatus 1F according to a sixth embodiment of the present technique is basically configured in a similar manner to the solid-state imaging apparatus 1D according to the fourth embodiment described above but differs in the following aspects.

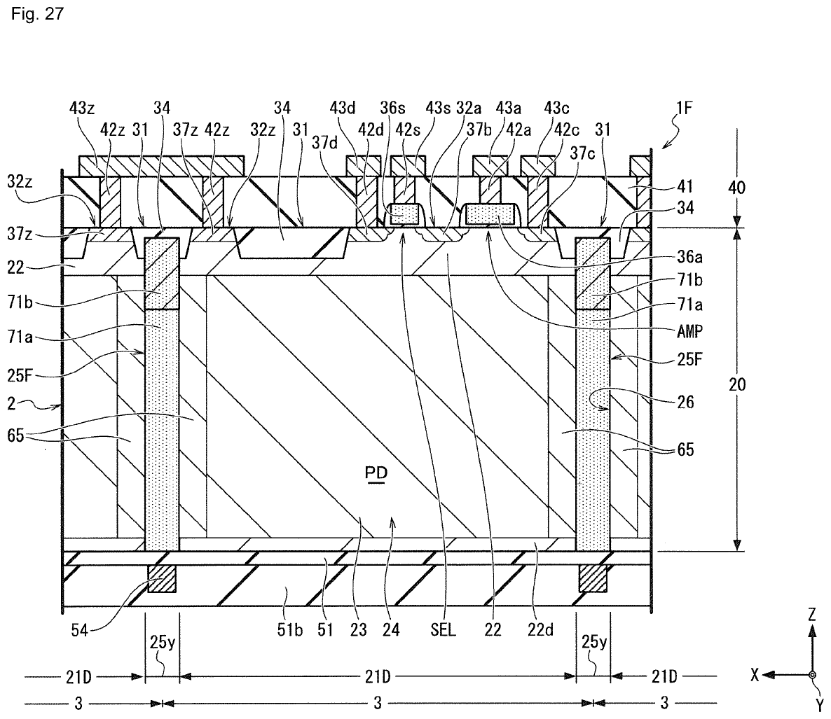

Specifically, as shown in FIG. 27, the solid-state imaging apparatus 1F according to the sixth embodiment includes a separation region 25F in place of the separation region 25D shown in FIG. 22 according to the fourth embodiment described above.

As shown in FIG. 27, the separation region 25F according to the sixth embodiment includes, in the excavated portion 26 of the semiconductor layer 20, a non-conductor 71a and a conductor 71b provided in series in the thickness direction (Z direction) of the semiconductor layer 20. In addition, the respective p-type well regions 22 of photoelectric conversion regions 21D that are adjacent to each other via the separation region 25F are electrically connected to each other via the conductor 71b of the separation region 25F. In other words, the separation region 25F includes the conductor 71b that is electrically connected to the respective p-type well regions 22 of photoelectric conversion regions 21D that are adjacent to each other.

The non-conductor 71a stretches in the thickness direction (Z direction) of the semiconductor layer 20, and one end of the non-conductor 71a is coupled to the conductor 71b while another end on the opposite side to the one end reaches the second surface S2 of the semiconductor layer 20. The conductor 71b stretches in the thickness direction (Z direction) of the semiconductor layer 20, and one end of the conductor 71b is coupled to the element separation region 31 while another end on the opposite side to the one end is coupled to the one end of the non-conductor 71a.

Each of the non-conductor 71a and the conductor 71b is constituted of, for example, a semiconductor film. For example, the non-conductor 71a is constituted of a non-conductive (non-conducting) silicon film (non-doped silicon film) into which an impurity for reducing a resistance value has not been introduced. For example, the conductor 71b is constituted of a p-type silicon film (doped silicon film) into which boron (B) has been introduced as an impurity for reducing a resistance value and has a same conductivity type as the p-type well region 22.

The non-conductor 71a is provided between respective n-type semiconductor regions 65 of the photoelectric conversion regions 21D that are adjacent to each other and insulates and separates the respective n-type semiconductor regions 65. In addition, the non-conductor 71a is provided between respective p-type well regions 22d of the photoelectric conversion regions 21D that are adjacent to each other.

The conductor 71b is provided between respective p-type well regions 22 of the photoelectric conversion regions 21D that are adjacent to each other and across the respective n-type semiconductor regions 65. The conductor 71b is directly connected inside the semiconductor layer 20 to the respective p-type well regions 22 of the photoelectric conversion regions 21D which are adjacent to each other and electrically and mechanically connected to the respective p-type well regions 22. The conductor 71b forms a p-n junction with respective n-type semiconductor regions 65 of the photoelectric conversion regions 21D which are adjacent to each other and insulates and separates the respective n-type semiconductor regions 65. In other words, on the one hand, the conductor 71b according to the sixth embodiment is electrically connected to the respective p-type well regions 22 of the photoelectric conversion regions 21D that are adjacent to each other and, on the other hand, the conductor 71b is electrically separated from the respective n-type semiconductor regions 65 of the photoelectric conversion regions 21D that are adjacent to each other.

The separation region 25F according to the sixth embodiment has a grid-like planar pattern in which the first portion 25x which stretches in the X direction and the second portion 25y which stretches in the Y direction are orthogonal to each other in a similar manner to the separation region 25 according to the first embodiment described earlier. In addition, the non-conductor 71a and the conductor 71b also have a grid-like planar pattern that is similar to the separation region 25F. Therefore, the respective p-type well regions 22 of the plurality of photoelectric conversion regions 21D that are respectively repetitively disposed in the X direction and the Y direction via the separation region 25F in the pixel array portion 2A are electrically connected via the conductor (conductive portion) 71b of the separation region 25D in the entire pixel array portion 2A.

Even with the solid-state imaging apparatus 1F according to the sixth embodiment, similar effects to those of the solid-state imaging apparatus 1D according to the fourth embodiment described above can be obtained.

Even in the sixth embodiment, the p-type semiconductor region 70 which is shown in FIG. 26 of the fifth embodiment described above and which functions as a pinning layer may be provided. In the sixth embodiment, the p-type semiconductor region 70 is preferably provided on respective sides of the separation region 25F of the p-type well region 22, the n-type semiconductor region 65, and the p-type well region 22d across each of the p-type well region 22, the n-type semiconductor region 65, and the p-type well region 22d.

Furthermore, although not illustrated in FIG. 27, even in the solid-state imaging apparatus 1F according to the sixth embodiment, the color filter 55 and the microlens 56 shown in FIG. 6 are provided on the side of the light incident surface (the side of the second surface S2) of the semiconductor layer 20.

### Seventh Embodiment

A solid-state imaging apparatus 1G according to a seventh embodiment of the present technique is basically configured in a similar manner to the solid-state imaging apparatus 1E according to the fifth embodiment described above but differs in the following aspects.

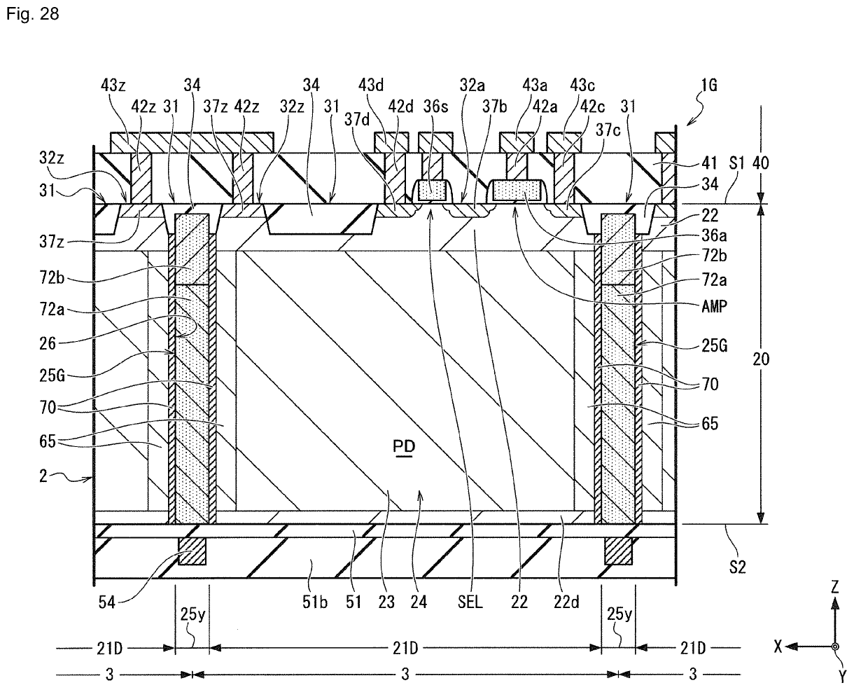

Specifically, as shown in FIG. 28, the solid-state imaging apparatus 1G according to the seventh embodiment includes a separation region 25G in place of the separation region 25D shown in FIG. 26 according to the fifth embodiment described above.

As shown in FIG. 28, the separation region 25G according to the seventh embodiment includes, in the excavated portion 26 of the semiconductor layer 20, a first conductor 72a and a second conductor 72b provided in series in the thickness direction (Z direction) of the semiconductor layer 20. In addition, the respective p-type well regions 22 of photoelectric conversion regions 21D that are adjacent to each other via the separation region 25G are electrically connected to each other via the second conductor 72b of the separation region 25F and the p-type semiconductor region 70 provided on a side wall of the second conductor 72b. In other words, the separation region 25G includes the second conductor 72b that is electrically connected via the p-type semiconductor region 70 to the respective p-type well regions 22 of photoelectric conversion regions 21D that are adjacent to each other.

The first conductor 72a stretches in the thickness direction (Z direction) of the semiconductor layer 20, and one end of the first conductor 72a is coupled to the second conductor 72b while another end on the opposite side to the one end reaches the second surface S2 of the semiconductor layer 20. The second conductor 72b stretches in the thickness direction (Z direction) of the semiconductor layer 20, and one end of the conductor 72b is coupled to the element separation region 31 while another end on the opposite side to the one end is coupled to the one end of the first non-conductor 71a.

Each of the first conductor 72a and the second conductor 72b is constituted of, for example, a semiconductor film. For example, the first conductor 72a is constituted of an n-type silicon film into which phosphorus (P) has been introduced as an impurity for reducing a resistance value. For example, the conductor 71b is constituted of a p-type silicon film into which boron (B) has been introduced as an impurity for reducing a resistance value and has a same conductivity type as the p-type well region 22.

The first conductor 71a is provided between respective n-type semiconductor regions 65 of the photoelectric conversion regions 21D that are adjacent to each other. The second conductor 71b is provided between respective p-type well regions 22 of the photoelectric conversion regions 21D that are adjacent to each other and across the respective n-type semiconductor regions 65.

As shown in FIG. 28, the p-type semiconductor region 70 is provided on the side of the separation region 25D of the photoelectric conversion region 21D in a similar manner to the fifth embodiment described above. The p-type semiconductor region 70 stretches in the depth direction of the semiconductor layer 20 and is provided between the p-type well region 22, the n-type semiconductor region 65, and the p-type well region 22d and the first conductor 72a (n-type silicon film) and the second conductor 72b (p-type silicon film) of the separation region 25D. One end of the p-type semiconductor region 70 is coupled to the element separation region 31 while another end reaches the second surface S2 of the semiconductor layer 20.

Each of the first conductor 72a and the second conductor 72b is electrically separated via the p-type semiconductor region 70 from the respective n-type semiconductor regions 65 of the photoelectric conversion regions 21D that are adjacent to each other. In addition, the second conductor 72b is electrically connected via the p-type semiconductor region 70 to the respective p-type well regions 22 of the photoelectric conversion regions 21D that are adjacent to each other. Furthermore, the first conductor 72a s electrically connected via the p-type semiconductor region 70 to the respective p-type well regions 22 of the photoelectric conversion regions 21D that are adjacent to each other.

The separation region 25G according to the seventh embodiment has a grid-like planar pattern in which the first portion 25x which stretches in the X direction and the second portion 25y which stretches in the Y direction are orthogonal to each other in a similar manner to the separation region 25 according to the first embodiment described earlier. In addition, the first conductor 72a and the second conductor 72b also have a grid-like planar pattern that is similar to the separation region 25G. Therefore, the respective p-type well regions 22 of the plurality of photoelectric conversion regions 21D that are respectively repetitively disposed in the X direction and the Y direction via the separation region 25G in the pixel array portion 2A are electrically connected via the second conductor 72b of the separation region 25G.

Even with the solid-state imaging apparatus 1G according to the seventh embodiment, similar effects to those of the solid-state imaging apparatus 1D according to the fourth embodiment described above can be obtained.

Note that the p-type semiconductor region 70 need not be provided between the n-type semiconductor region 65 and the p-type well region 22, and the second conductor 72b. Furthermore, although not illustrated in FIG. 28, even in the solid-state imaging apparatus 1G according to the seventh embodiment, the color filter 55 and the microlens 56 shown in FIG. 6 are provided on the side of the light incident surface (the side of the second surface S2) of the semiconductor layer 20.

### Eighth Embodiment

A solid-state imaging apparatus 1H according to an eighth embodiment of the present technique is basically configured in a similar manner to the solid-state imaging apparatus 1D according to the fourth embodiment described above but differs in the following aspects.

Specifically, in the fourth embodiment described above, as shown in FIGS. 21 and 22, the photoelectric conversion region 21D includes the power feeding contact region 37z. In addition, the power feeding wiring 43z is electrically connected via the power feeding contact electrode 42z to the power feeding contact region 37z. A configuration is adopted in which a potential of the p-type well region 22 is fixed to a power supply potential (the power supply potential is applied to the p-type well region 22) by applying (supplying) the power supply potential to the power feeding contact electrode 37z from a power supply generation circuit via the power feeding wiring 43z, the power feeding contact electrode 42z, and the like.

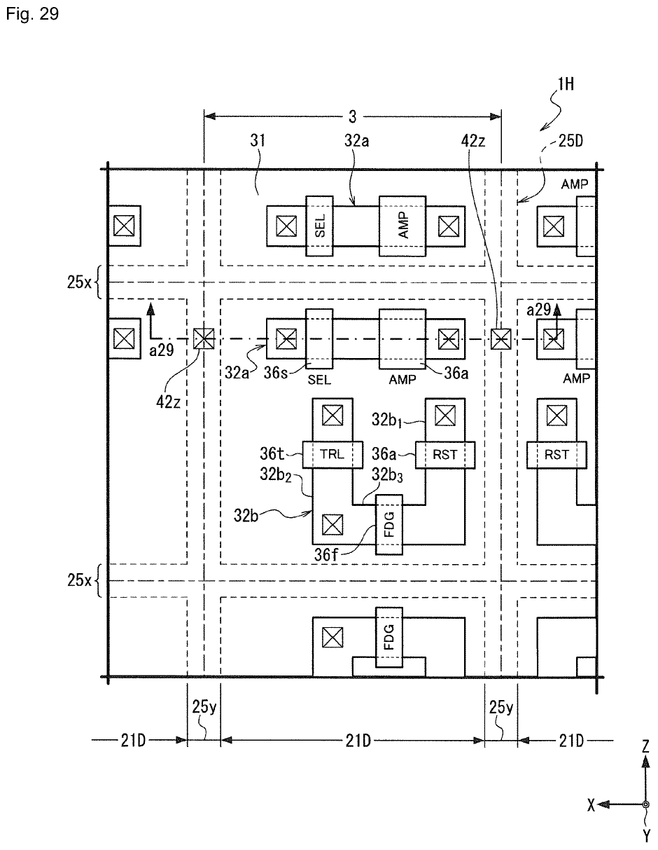

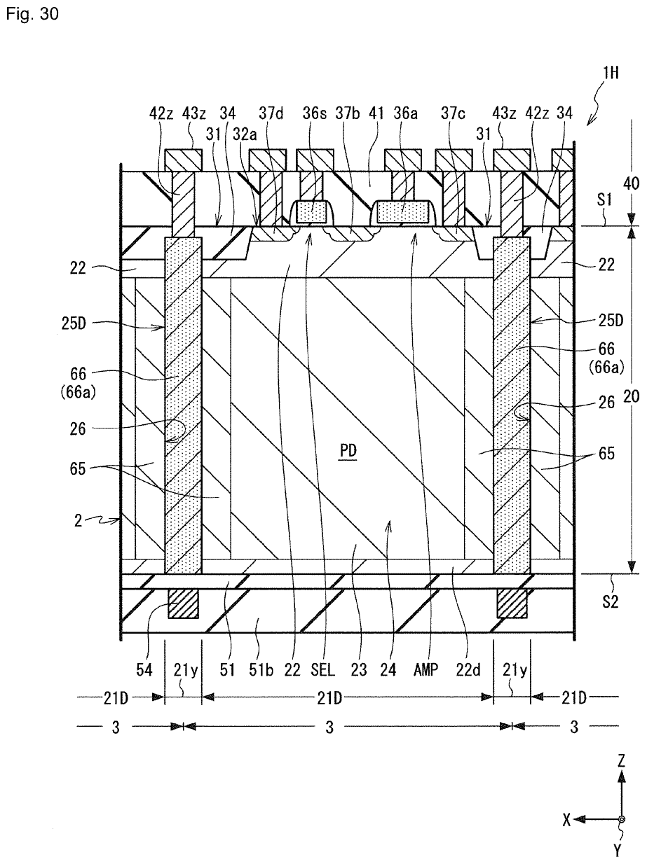

In contrast, as shown in FIGS. 29 and 30, in the eighth embodiment, the photoelectric conversion region 21D does not include the power feeding contact region 37z unlike in the fourth embodiment described earlier. In addition, the power feeding contact electrode 42z is electrically and mechanically connected to the conductor 66 of the separation region 25D. In other words, the conductor 66 of the separation region 25D is electrically and mechanically connected to the power feeding contact electrode 42z to which the power supply potential is applied on the side of the first surface S1 of the semiconductor layer 20.

As described above, in the eighth embodiment, since the conductor 66 of the separation region 25D and the power feeding contact electrode 42z to which the power supply potential is applied is electrically and mechanically connected to each other and the potential of the respective p-type well regions 22 of the photoelectric conversion regions 21D that are adjacent to each other via the separation region 25D can be fixed, the power feeding contact region 37z shown in FIGS. 21 and 22 according to the fourth embodiment described above can be eliminated.

In addition, by eliminating the power feeding contact region 37z, a degree of freedom of arrangement of the pixel transistors (AMP, SEL, RST, FDG, and TRL) in the photoelectric conversion region 21D is increased, a volume of the photoelectric conversion unit 24 can be increased when a planar size of the photoelectric conversion region 21D is made constant, and a saturation signal amount Qs can be improved. As a result, image quality can be improved. Furthermore, when the volume of the photoelectric conversion unit 24 is made constant, miniaturization of the photoelectric conversion region 21D can be achieved.

In addition, by applying the power supply potential to the power feeding contact electrode 42z, the potential of the conductor 66 of the separation region 25D becomes fixed. Therefore, in two photoelectric conversion regions 21D that are adjacent to each other via the separation region 25D, propagation of noise that is attributable to a capacitive coupling of parasitic capacitances between pixel transistors of one photoelectric conversion region 21D and pixel transistors of the other photoelectric conversion region 21D can be suppressed in a similar manner to the first embodiment described earlier. Accordingly, the solid-state imaging apparatus 1H according to the eighth embodiment can also improve image quality in a similar manner to the solid-state imaging apparatus 1A according to the first embodiment described earlier.

Even in the eighth embodiment, the p-type semiconductor region 70 which is shown in FIG. 26 of the fifth embodiment described above and which functions as a pinning layer may be provided. In the eighth embodiment, the p-type semiconductor region 70 is preferably provided on respective sides of the separation region 25D of the p-type well region 22, the n-type semiconductor region 65, and the p-type well region 22d across each of the p-type well region 22, the n-type semiconductor region 65, and the p-type well region 22d.

Furthermore, although not illustrated in FIG. 30, even in the solid-state imaging apparatus 1H according to the eighth embodiment, the color filter 55 and the microlens 56 shown in FIG. 6 are provided on the side of the light incident surface (the side of the second surface S2) of the semiconductor layer 20.

### Ninth Embodiment

A solid-state imaging apparatus 1I according to a ninth embodiment of the present technique is basically configured in a similar manner to the solid-state imaging apparatus 1D according to the eighth embodiment described above but differs in the following aspects.

Specifically, in the eighth embodiment, as shown in FIG. 30, the conductor 66 of the separation region 25D and the power feeding contact electrode 42z to which a power supply potential is applied is electrically and mechanically connected to each other on the side of the first surface S1 of the semiconductor layer 20.

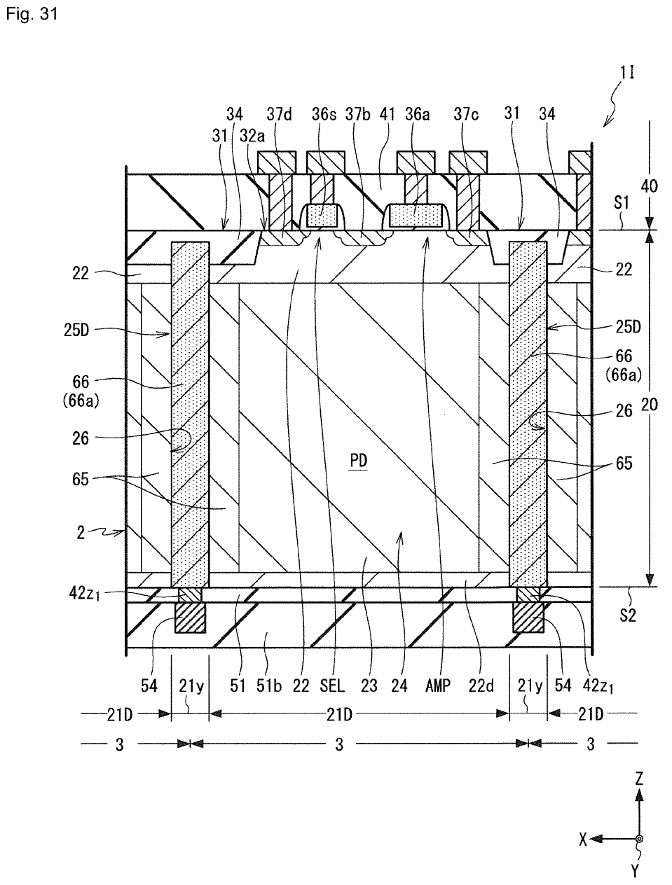

In contrast, as shown in FIG. 31, in the ninth embodiment, the conductor 66 of the separation region 25D and a power feeding contact electrode 42z₁ to which a power supply potential is applied is electrically and mechanically connected to each other on the side of the second surface S2 of the semiconductor layer 20. In other words, the conductor 66 of the separation region 25D is electrically and mechanically connected on the side of the second surface S2 of the semiconductor layer 20 to the power feeding contact electrode 42z₁ to which a power supply potential is applied. In addition, the light-shielding film 54 is used as a power feeding wiring to which a power supply potential is applied and the light-shielding film 54 and the power feeding contact electrode 42z₁ are electrically and mechanically connected to each other.

In this manner, in the ninth embodiment, since the conductor 66 of the separation region 25D and the power feeding contact electrode 42z₁ to which a power supply potential is applied is electrically and mechanically connected to each other on the side of the second surface S2 of the semiconductor layer 20, applying the power supply potential to the power feeding contact electrode 42z₁ enables a potential of the respective p-type well regions 22 of the photoelectric conversion regions 21D that are adjacent to each other via the separation region 25D to be fixed and the power feeding contact region 37z shown in FIGS. 21 and 22 according to the fourth embodiment described above can be eliminated in a similar manner to the eighth embodiment described above.

In addition, since the power feeding contact electrode 37z can be eliminated, a saturation signal amount Qs can be improved when a planar size of the photoelectric conversion region 21D is made constant and image quality can be improved in a similar manner to the eighth embodiment described above. Furthermore, when the volume of the photoelectric conversion unit 24 is made constant, miniaturization of the photoelectric conversion region 21D can be achieved.

In addition, in two photoelectric conversion regions 21D that are adjacent to each other via the separation region 25D, propagation of noise that is attributable to a capacitive coupling of parasitic capacitances between pixel transistors of one photoelectric conversion region 21D and pixel transistors of the other photoelectric conversion region 21D can be suppressed in a similar manner to the first embodiment described earlier. Accordingly, the solid-state imaging apparatus 1I according to the ninth embodiment can also improve image quality in a similar manner to the solid-state imaging apparatus 1A according to the first embodiment described earlier.

Even in the ninth embodiment, the p-type semiconductor region 70 which is shown in FIG. 26 of the fifth embodiment described above and which functions as a pinning layer may be provided. In the ninth embodiment, the p-type semiconductor region 70 is preferably provided on respective sides of the separation region 25D of the p-type well region 22, the n-type semiconductor region 65, and the p-type well region 22d across each of the p-type well region 22, the n-type semiconductor region 65, and the p-type well region 22d.

Furthermore, although not illustrated in FIG. 31, even in the solid-state imaging apparatus 1I according to the ninth embodiment, the color filter 55 and the microlens 56 shown in FIG. 6 are provided on the side of the light incident surface (the side of the second surface S2) of the semiconductor layer 20.

### Tenth Embodiment

A solid-state imaging apparatus 1J according to a tenth embodiment of the present technique is basically configured in a similar manner to the solid-state imaging apparatus 1D according to the fourth embodiment described above but differs in the following aspects.

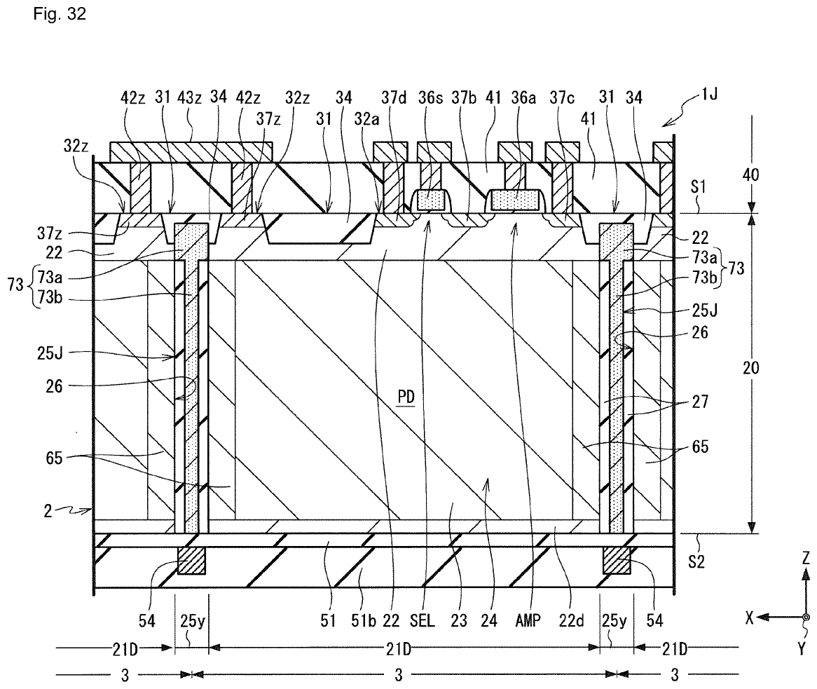

Specifically, as shown in FIG. 32, the solid-state imaging apparatus 1J according to the tenth embodiment includes a separation region 25J in place of the separation region 25D shown in FIG. 22 according to the fourth embodiment described above. Other configurations are more or less the same as those in the fourth embodiment described above.

The separation region 25J according to the tenth embodiment includes the separation insulating film 27 provided along the inner wall of the excavated portion 26 that stretches in the thickness direction (Z direction) of the semiconductor layer 20 and a conductor 73 provided in the excavated portion 26 of the semiconductor layer 20 via the separation insulating film 27. In other words, the separation region 25J includes the conductor 73 which is embedded in the semiconductor layer 20 via the separation insulating film 27 and which is insulated and separated from the semiconductor layer 20.

The conductor 73 stretches in the thickness direction (Z direction) of the semiconductor layer 20, and one end of the conductor 73 is coupled to the element separation region 31 while another end on the opposite side to the one end reaches the second surface S2 of the semiconductor layer 20. The conductor 73 includes: a head portion 73a which is provided on the side of the first surface S1 of the semiconductor layer 20 and which is electrically connected to the respective p-type well regions 22 of the photoelectric conversion regions 21D that are adjacent to each other via the separation region 25J; and a body portion 73b which protrudes from the head portion 73a to the side of the second surface S2 of the semiconductor layer 20 and of which a width is narrower than that of the head portion 73a.

The separation insulating film 27 stretches in the thickness direction (Z direction) of the semiconductor layer 20, and one end of the separation insulating film 27 terminates in a lower surface portion of the head portion 73a of the conductor 73 while another end on the opposite side to the one end reaches the second surface S2 of the semiconductor layer 20.

The head portion 73a of the conductor 73 is provided between respective p-type well regions 22 of the photoelectric conversion regions 21D that are adjacent to each other and is electrically connected to the respective p-type well regions 22. The body portion 73b of the conductor 73 is respectively provided via the separation insulating film 27 between the respective n-type semiconductor regions 65 of the photoelectric conversion regions 21D that are adjacent to each other and is insulated and separated from the respective n-type semiconductor regions 65. In addition, the body portion 73b of the conductor 73 is respectively provided via the separation insulating film 27 between the respective p-type well regions 22d of the photoelectric conversion regions 21D that are adjacent to each other and is insulated and separated from the respective p-type well regions 22d.

The conductor 73 including the head portion 73a and the body portion 73b is constituted of a semiconductor film of a same conductivity type as, for example, the p-type well region 22. For example, the conductor 73 is constituted of a p-type silicon film into which boron (B) has been introduced as an impurity for reducing a resistance value.

The separation region 25J according to the tenth embodiment has a grid-like planar pattern in which the first portion 25x which stretches in the X direction and the second portion 25y which stretches in the Y direction are orthogonal to each other in a similar manner to the separation region 25 according to the first embodiment described earlier. In addition, the conductor 73 which includes the head portion 73a and the body portion 73b also has a grid-like planar pattern that is similar to the separation region 25J. Therefore, the respective p-type well regions 22 of the plurality of photoelectric conversion regions 21J that are respectively repetitively disposed in the X direction and the Y direction via the separation region 25J in the pixel array portion 2A are electrically connected via the conductor 73 of the separation region 25J.

Even with the solid-state imaging apparatus 1J according to the tenth embodiment, similar effects to those of the solid-state imaging apparatus 1D according to the fourth embodiment described above can be obtained.

Even in the tenth embodiment, the p-type semiconductor region 70 which is shown in FIG. 26 of the fifth embodiment described above and which functions as a pinning layer may be provided. In the tenth embodiment, the p-type semiconductor region 70 is preferably provided on respective sides of the separation region 25J of the p-type well region 22, the n-type semiconductor region 65, and the p-type well region 22d across each of the p-type well region 22, the n-type semiconductor region 65, and the p-type well region 22d.

In addition, although not illustrated in FIG. 32, even in the solid-state imaging apparatus 1J according to the tenth embodiment, the color filter 55 and the microlens 56 shown in FIG. 6 are provided on the side of the light incident surface (the side of the second surface S2) of the semiconductor layer 20.

### Eleventh Embodiment

In an eleventh embodiment, an arrangement of a power feeding contact portion which electrically connects a conductor of a separation region and a power feeding wiring to each other will be described.

A solid-state imaging apparatus 1K according to the eleventh embodiment of the present technique is basically configured in a similar manner to the solid-state imaging apparatus 1A according to the first embodiment described above but differs in the following aspects.

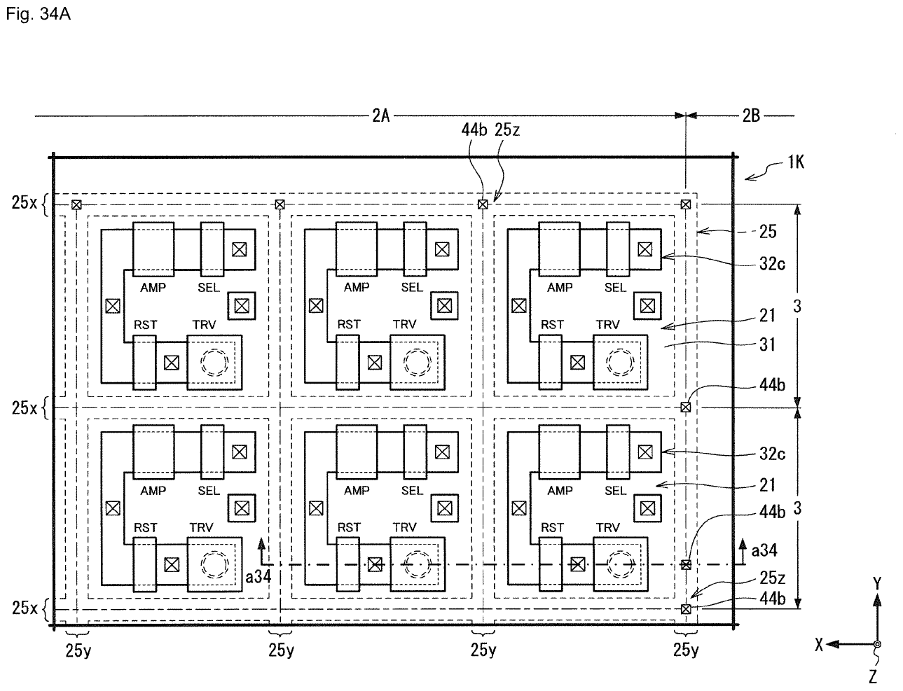

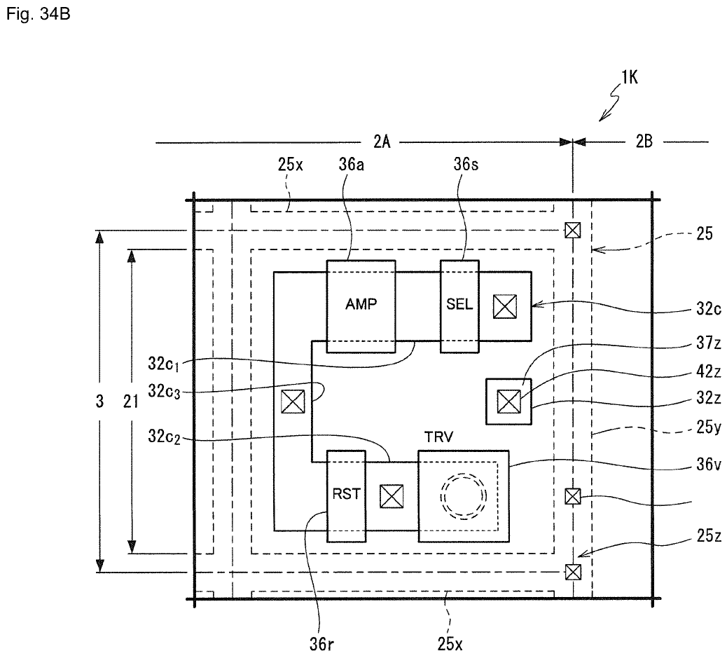

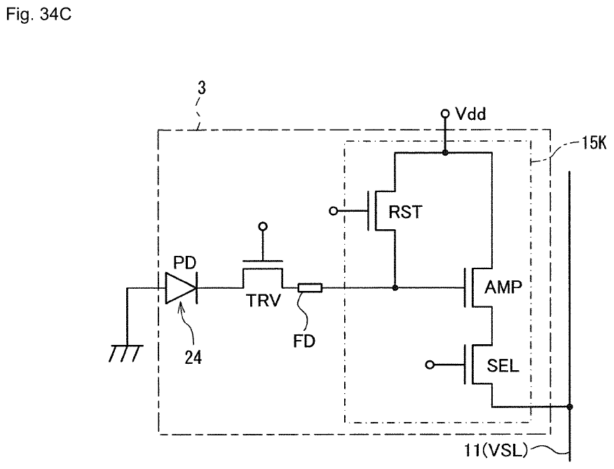

Specifically, the solid-state imaging apparatus 1K according to the eleventh embodiment includes a transfer transistor TRV and a readout circuit 15K shown in FIG. 34C in place of the transfer transistor TRL and the readout circuit 15 shown in FIG. 3 of the first embodiment described earlier.

In addition, the solid-state imaging apparatus 1K according to the eleventh embodiment includes a third element formation region 32c shown in FIG. 34B in place of the first and second element formation regions 32a and 32b shown in FIGS. 5 and 6 of the first embodiment described earlier.

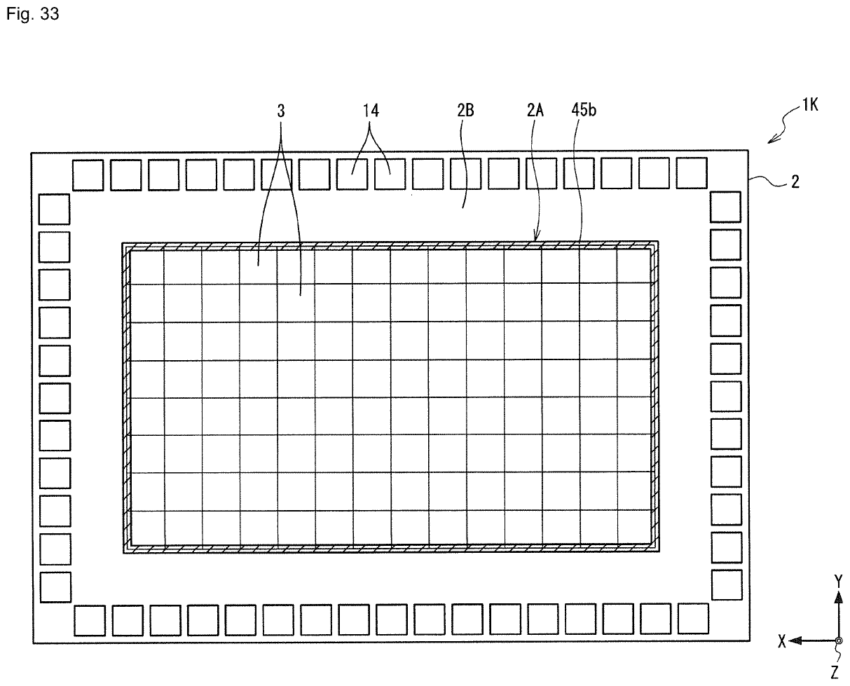

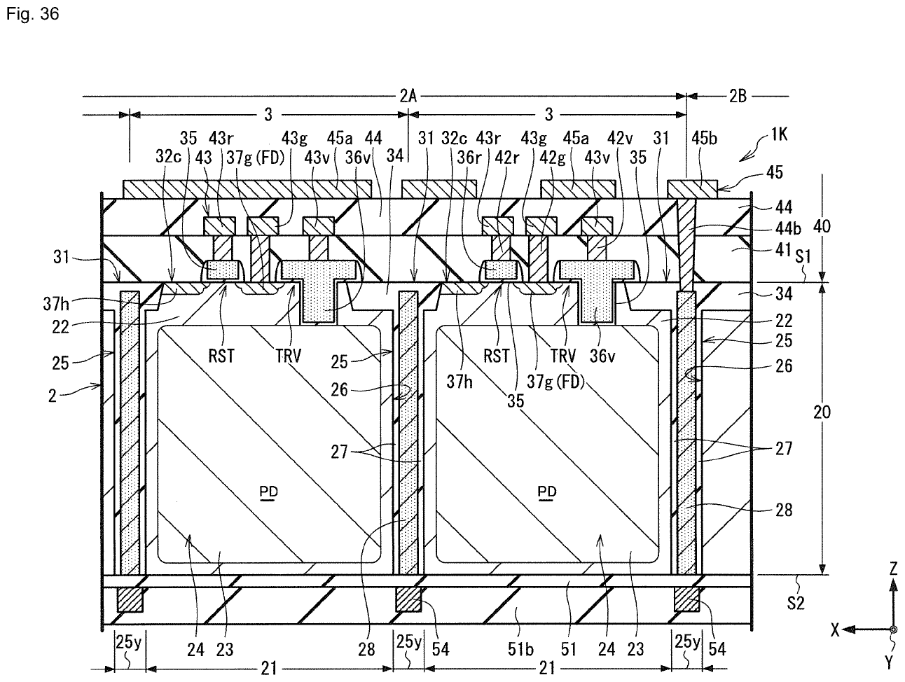

Furthermore, the solid-state imaging apparatus 1K according to the eleventh embodiment includes a power feeding wiring 45b shown in FIGS. 33 and 36 in place of the transparent electrode 52 shown in FIGS. 1 and 6 of the first embodiment described earlier. Other configurations are more or less the same as those in the first embodiment described above.

### <Readout Circuit>

As shown in FIG. 34C, the readout circuit 15K according to the eleventh embodiment includes the amplifying transistor AMP, the selection transistor SEL, and the reset transistor RST as pixel transistors. The readout circuit 15K reads out a signal charge held in the electric charge holding region FD and outputs a pixel signal based on the signal charge in a similar manner to the readout circuit 15 according to the first embodiment.

### <Third Element Formation Region>

As shown in FIGS. 34B and 36, the third element formation region 32c according to the eleventh embodiment is interval by the element separation region 31 on the side of the first surface S1 of the semiconductor layer 20 and provided for each photoelectric conversion region 21. In addition, the third element formation region 32c overlaps with the photoelectric conversion unit 24 of the photoelectric conversion region 21 in a plan view. In other words, the photoelectric conversion region 21 according to the eleventh embodiment includes the third element formation region 32c in place of the first and second element formation regions 32a and 32b according to the first embodiment.

The third element formation region 32c is constituted of a C-shaped planar pattern including a first portion 32c₁ and a second portion 32c₂, each of which stretch in the X direction and which separate from each other in the Y direction and the third portion 32c₃ which stretches in the Y direction and which is coupled to one end of each of the first portion 32c₁ and the second portion 32c₂. The amplifying transistor AMP and the selection transistor SEL are arranged so as to be connected in series in the first portion 32c₁. The reset transistor RST and the transfer transistor TRV are arranged so as to be connected in series in the second portion 32c₂. In the eleventh embodiment, as shown in FIG. 34A, an orientation of the third element formation region 32c is the same among a plurality of photoelectric conversion regions.

### <Reset Transistor and Transfer Transistor>

As shown in FIG. 36, the reset transistor RST includes the gate insulating film 35 provided on the third element formation region 32c on the side of the first surface S1 of the semiconductor layer 20, the gate electrode 36r provided on the third element formation region 32c via the gate insulating film 35, and a side wall spacer provided on a side wall of the gate electrode 36r so as to enclose the gate electrode 36a. In addition, the reset transistor RST further includes a channel formation region in which a channel (conduction path) is formed in the p-type well region 22 directly beneath the gate electrode 36r and a pair of main electrode regions 37g and 37h which are provided in the p-type well region 22 so as to separate from each other in the channel length direction (gate length direction) and to sandwich the channel formation region and which function as a source region and a drain region. The reset transistor RST controls the channel formed in the channel formation region by a gate voltage applied to the gate electrode 36r. Each of the pair of main electrode regions 37g and 37h includes an extension region and a contact region made of n-type semiconductor regions in a similar manner to the amplifying transistor AMP and the selection transistor SEL.

As shown in FIG. 36, the transfer transistor TRV according to the eleventh embodiment is constructed in the p-type well region 22 of the third element formation region 32c. In addition, the transfer transistor TRV is constructed in a vertical shape. Specifically, the transfer transistor TRV includes a gate electrode 36v provided in a gate groove portion on the side of the first surface S1 of the semiconductor layer 20, the gate insulating film 35 interposed between the gate electrode 36v and the semiconductor layer 20, and a channel formation region made up of p-type well regions 22 lined up on a side wall of the gate electrode 36v via the gate insulating film 35. In addition, the transfer transistor TRV includes a pair of main electrode regions which function as a source region and a drain region. Of the pair of main electrode regions, one main electrode region is constituted of the n-type semiconductor region 23 (photoelectric conversion unit 24) and the other main electrode region is constituted of a main electrode region 37g which functions as a source region of the reset transistor RST. In other words, the transfer transistor TRV and the reset transistor RST share the main electrode region 37g which functions as the drain region of the transfer transistor TRV and the main electrode region 37g which functions as the source region of the reset transistor RST. In addition, the main electrode regions 37g function as the electric charge holding region FD shown in FIG. 34C. The transfer transistor TRV controls the channel formed in the channel formation region by a gate voltage which is applied to the gate electrode 36v. The gate electrode 36v includes a first portion (vertical gate electrode portion) which is provided via the gate insulating film 35 in the gate groove portion of the semiconductor layer 20 and a second portion which is integrally molded with the first portion and which protrudes from the gate groove portion. The second portion is made wider than the first portion.

As shown in FIG. 36, the gate electrode 36r of the reset transistor RST is electrically connected to a wiring 43r formed on the first wiring layer 43 via a contact electrode (conductive plug) 42r which is embedded in the interlayer insulating film 41. The gate electrode 36v of the transfer transistor TRV is electrically connected to a wiring 43v formed on the first wiring layer 43 via a contact electrode 42v which is embedded in the interlayer insulating film 41. The main electrode region 37g which functions as the electric charge holding region FD is electrically connected to a wiring 43g formed on the first wiring layer 44 via a contact electrode 42g which is embedded in the interlayer insulating film 41. The wiring 43g of is electrically connected to the input side of the readout circuit 15K described earlier.

### <Power Feeding Wiring and Power Feeding Contact Electrode>

As shown in FIG. 33, the power feeding wiring 45b is provided in a periphery of the pixel array portion 2A. In addition, the power feeding wiring 45b has, for example, an annular planar pattern which stretches so as to enclose the periphery of the pixel array portion 2A. Although not illustrated, the power feeding wiring 45b is electrically connected to a power supply generation circuit (drive circuit) which is provided in the peripheral portion 2B of the semiconductor chip 2 and which supplies a certain power supply potential and the power supply potential supplied from the power supply generation circuit is applied to the power feeding wiring 45b. In the eleventh embodiment, although not limited thereto, a first reference potential of, for example, 0 V is applied as the power supply potential to the power feeding wiring 45b. The application of the power supply potential to the power feeding wiring 45b is held during photoelectric conversion by the photoelectric conversion unit 24 or during driving of the pixel transistors (AMP, SEL, RST, FDG, and TRV) included in the readout circuit 15K.

As shown in FIG. 36, the power feeding wiring 45b is formed on, for example, a third wiring layer 45. In addition, the power feeding wiring 45b is electrically connected to the conductor 28 of the separation region 25 via a power feeding contact electrode 44b as a contact portion which stretches across the interlayer insulating films 44 and 41 of the multilayer wiring layer 40. In other words, the conductor 28 of the separation region 25 is electrically connected via the power feeding contact electrode 44b to the power feeding wiring 45b to which the power supply potential is applied in a periphery of the pixel array portion 2A.

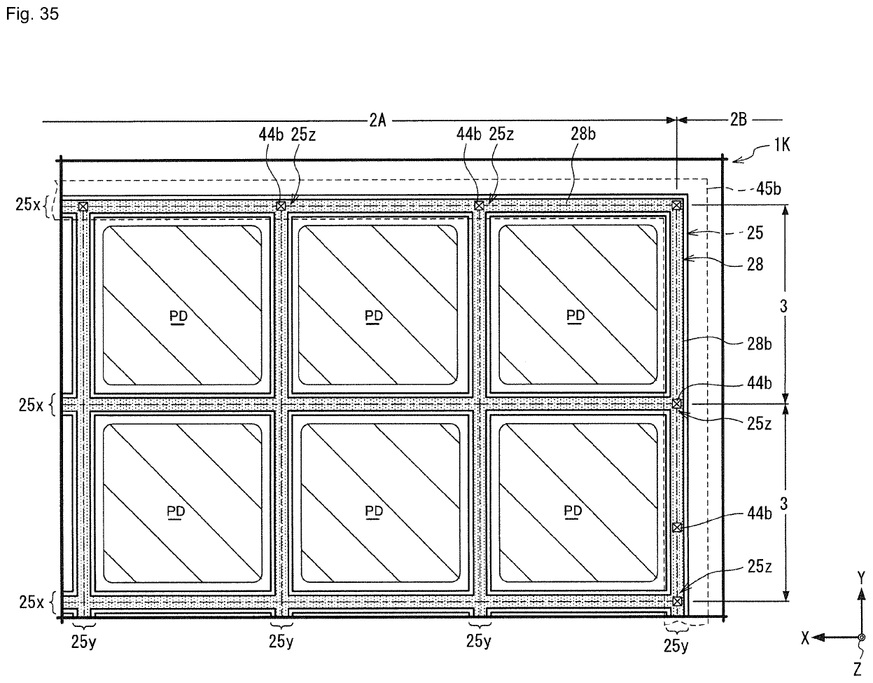

As shown in FIGS. 34A and 34B, the separation region 25 is constituted of a grid-like planar pattern. In addition, as shown in FIG. 35, the conductor 28 is also constituted of a grid-like planar pattern in a similar manner to the separation region 25. Furthermore, the conductor 28 includes an annular portion 28v which stretches so as to enclose a periphery of the pixel array portion 2A in a plan view and which overlaps with the power feeding wiring 45b. Of the conductor 28, an inner side enclosed by the annular portion 28v has a grid-like planar pattern.

As shown in FIGS. 34A and 35, the power feeding contact electrode 44b is scattered in plurality over the periphery of the pixel array portion 2A. In addition, the power feeding contact electrodes 44b are arranged at positions overlapping the separation region 25 in a plan view. Furthermore, a power supply potential applied to the power feeding wiring 45b is supplied to the conductor 28 of the separation region 25 via the power feeding contact electrodes 44b and a potential of the conductor 28 is fixed to the supplied power supply potential. For example, the power feeding contact electrodes 44b is constituted of a high-melting point metal film such as a tungsten (W) film or a titanium (Ti) film.

As shown in FIGS. 34A and 35, the power feeding contact electrodes 44b are preferably provided in intersection portions 25z where an X first portion 25x which stretches in the X direction of the separation region 25 and the second portion 25y which stretches in the Y direction of the separation region 25 intersect with each other in the periphery of the pixel array portion 2A. However, as in the eleventh embodiment, the power feeding contact electrodes 44b may be provided in the separation region 25 between the intersection portions 25z.

Note that a configuration in which the bonding pad 14 to which the power supply potential is applied from the outside among the plurality of bonding pads 14 shown in FIG. 33 and the power feeding wiring 45b are electrically connected to each other may be adopted.

### Main Effects of Eleventh Embodiment

Next, the main effects of the eleventh embodiment will be described.

As described above, in the solid-state imaging apparatus 1K according to the eleventh embodiment, the conductor 28 of the separation region 25 is electrically connected via the power feeding contact electrode 44b to the power feeding wiring 45b to which the power supply potential is applied in a periphery of the pixel array portion 2A.

Therefore, for example, by applying a first reference potential of 0 V to the power feeding wiring 45b and fixing the potential of the conductor 28 of the separation region 25 to the first reference potential, in two photoelectric conversion regions 21 that are adjacent to each other via the separation region 25, propagation of noise that is attributable to a capacitive coupling of parasitic capacitances between pixel transistors of one photoelectric conversion region 21 and pixel transistors of the other photoelectric conversion region 21 can be suppressed in a similar manner to the first embodiment described earlier. Accordingly, the solid-state imaging apparatus 1K according to the eleventh embodiment can also improve image quality in a similar manner to the solid-state imaging apparatus 1A according to the first embodiment described earlier. In addition, reliability can be further improved.

Note that the conductor 28 of the separation region 25 may be constituted of an n-type semiconductor film or a metal film.

In addition, although not illustrated in FIG. 36, even in the solid-state imaging apparatus 1K according to the eleventh embodiment, the color filter 55 and the microlens 56 shown in FIG. 6 are provided on the side of the light incident surface (the side of the second surface S2) of the semiconductor layer 20.

### Twelfth Embodiment

A solid-state imaging apparatus 1L according to a twelfth embodiment of the present technique is basically configured in a similar manner to the solid-state imaging apparatus 1K according to the eleventh embodiment described above but differs in the following aspects.

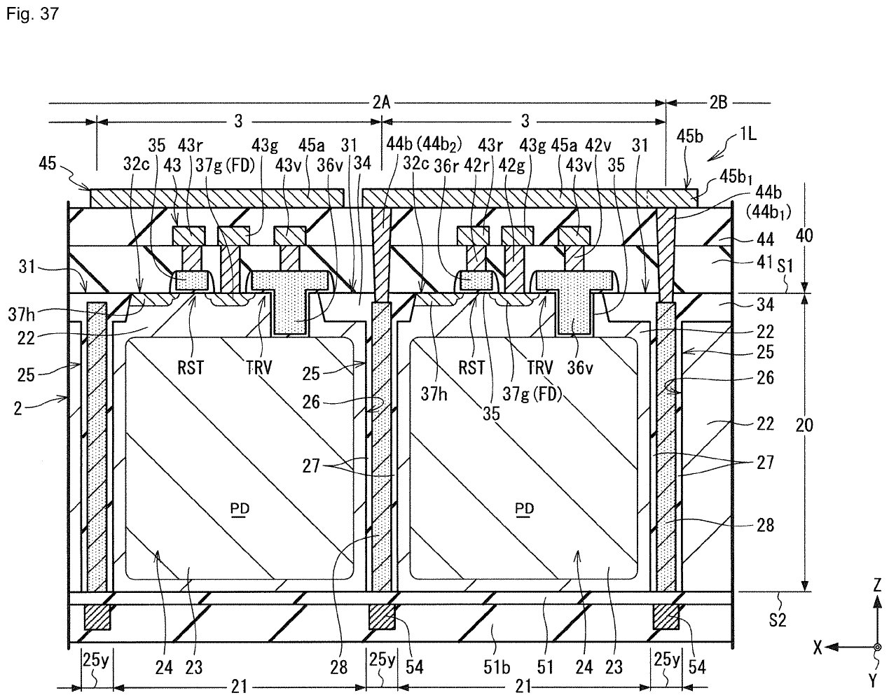

Specifically, as shown in FIG. 37, in the solid-state imaging apparatus 1L according to the twelfth embodiment, the power feeding contact electrode 44b is provided at a position overlapping with the separation region 25 in the periphery of the pixel array portion 2A in a plan view and also provided at a position overlapping with the separation region 25 that is further inward from the periphery of the pixel array portion 2A. In addition, the conductor 28 of the separation region 25 is electrically connected to the power feeding wiring 45b of the multilayer wiring layer 40 via the power feeding contact electrode 44b provided in the periphery of the pixel array portion 2A and via the power feeding contact electrode 44b provided further inward from the periphery of the pixel array portion 2A. In the twelfth embodiment, the power feeding wiring 45b includes a main line portion 45b₁ which overlaps with the separation region 25 in the periphery of the pixel array portion and a sub-line portion 45b₂ which stretches toward an inner side of the pixel array portion 2A from the main line portion 45b₁.

Even with the solid-state imaging apparatus 1L according to the twelfth embodiment, similar effects to those of the solid-state imaging apparatus 1K according to the eleventh embodiment described above can be obtained.

Although not illustrated in FIG. 37, even in the solid-state imaging apparatus 1L according to the twelfth embodiment, the color filter 55 and the microlens 56 shown in FIG. 6 are provided on the side of the light incident surface (the side of the second surface S2) of the semiconductor layer 20.

### Thirteenth Embodiment

A solid-state imaging apparatus 1M according to a thirteenth embodiment of the present technique is basically configured in a similar manner to the solid-state imaging apparatus 1K according to the eleventh embodiment described above but differs in the following aspects.

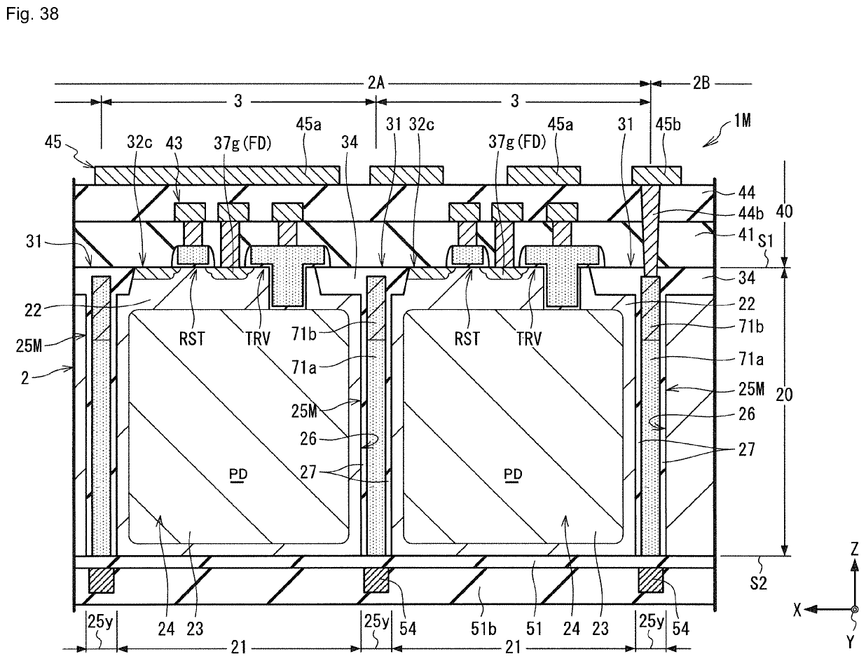

Specifically, as shown in FIG. 38, the solid-state imaging apparatus 1M according to the thirteenth embodiment includes a separation region 25M in place of the separation region 25 shown in FIG. 36 according to the eleventh embodiment described above. Other configurations are more or less the same as those in the eleventh embodiment described above.

As shown in FIG. 38, the separation region 25M according to the thirteenth embodiment includes the conductor 71b provided so as to be separated from the second surface S2 of the semiconductor layer 20 in an upper part on the side of the first surface S1 of the semiconductor layer 20. In addition, the power feeding wiring 45b is electrically connected to the conductor 71b of the separation region 25M via the power feeding contact electrode 44b in the periphery of the pixel array portion 2A.

The separation region 25M includes: the separation insulating film 27 provided along the inner wall of the excavated portion 26 that stretches in the thickness direction (Z direction) of the semiconductor layer 20; and the conductor 71b and the non-conductor 71a which are provided in the excavated portion 26 via the separation insulating film 27 and which are sequentially arranged in a depth direction from the side of the first surface S1 of the semiconductor layer 20.

The separation insulating film 27 stretches in the thickness direction of the semiconductor layer 20, and one end of the separation insulating film 27 is coupled to the element separation region 31 while another end on the opposite side to the one end reaches the second surface S2 of the semiconductor layer 20.

The non-conductor 71a stretches in the thickness direction (Z direction) of the semiconductor layer 20, and one end of the non-conductor 71a is coupled to the conductor 71b while another end on the opposite side to the one end reaches the second surface S2 of the semiconductor layer 20. The conductor 71b stretches in the thickness direction (Z direction) of the semiconductor layer 20, and one end of the conductor 71b is coupled to the element separation region 31 while another end on the opposite side to the one end is coupled to the one end of the non-conductor 71a.

Each of the non-conductor 71a and the conductor 71b is electrically separated by the separation insulating film 27 from the respective p-type well regions 22 of the photoelectric conversion regions 21 that are adjacent to each other. Each of the non-conductor 71a and the conductor 71b is constituted of, for example, a semiconductor film. For example, the non-conductor 71a is constituted of a non-conductive (non-conducting) silicon film (non-doped silicon film). For example, the conductor 71b is constituted of a p-type silicon film (doped silicon film).

Even with the solid-state imaging apparatus 1M according to the thirteenth embodiment, similar effects to those of the solid-state imaging apparatus 1K according to the eleventh embodiment described above can be obtained. Furthermore, although not illustrated in FIG. 38, even in the solid-state imaging apparatus 1M according to the thirteenth embodiment, the color filter 55 and the microlens 56 shown in FIG. 6 are provided on the side of the light incident surface (the side of the second surface S2) of the semiconductor layer 20.

### Fourteenth Embodiment

A solid-state imaging apparatus 1N according to a fourteenth embodiment of the present technique is basically configured in a similar manner to the solid-state imaging apparatus 1K according to the eleventh embodiment described above but differs in the following aspects.

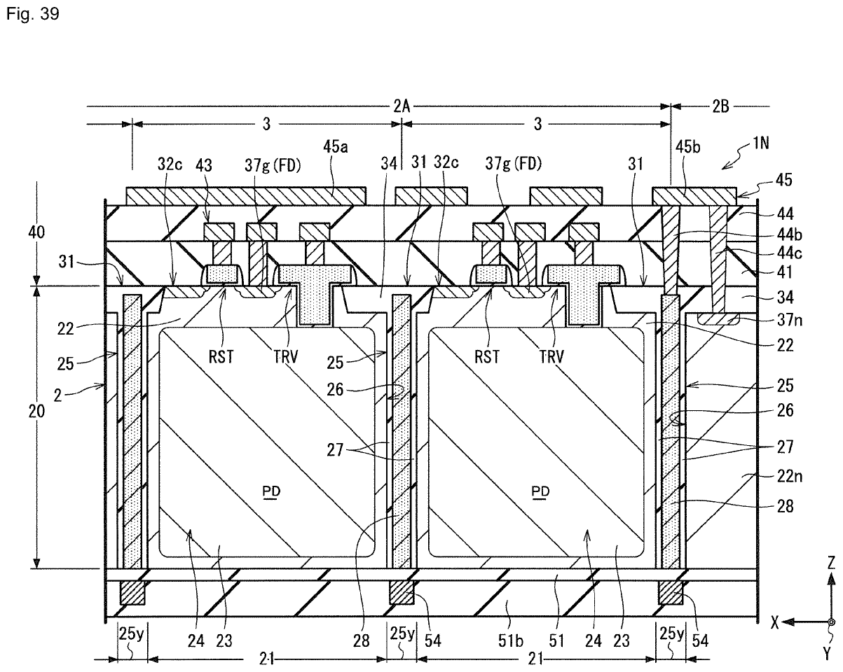

Specifically, as shown in FIG. 39, the solid-state imaging apparatus 1N according to the fourteenth embodiment further includes a p-type peripheral well region 22n provided on the semiconductor layer 20 in the peripheral portion 2B on an outer side of the pixel array portion 2A. In addition, the solid-state imaging apparatus 1N according to the fourteenth embodiment further includes, on the side of the first surface S1 of the semiconductor layer 20, a p-type power feeding contact region 37n provided in an upper part of the p-type peripheral well region 22n and a power feeding contact electrode 44c embedded across the interlayer insulating films 44 and 41 of the multilayer wiring layer 40 and the element separation region 31. Furthermore, one end of the power feeding contact electrode 44c is electrically and mechanically connected to the power feeding wiring 45b while another end on the opposite side to the one end is electrically and mechanically connected to the power feeding contact electrode 37n. In other words, the p-type peripheral well region 22n is electrically connected to the power feeding wiring 45b via the p-type power feeding contact region 37n and the power feeding contact electrode 44c.

The p-type peripheral well region 22n is constituted of a p-type semiconductor region. For example, the p-type peripheral well region 22n is formed by a same process as the p-type well region 22.

The p-type power feeding contact region 37n is constituted of a p-type semiconductor region with a higher impurity concentration than the p-type peripheral well region 22n and reduces ohmic contact resistance with the power feeding contact electrode 44c.

A power supply potential applied to the power feeding wiring 45b is supplied to the p-type peripheral well region 22n via the power feeding contact electrode 44c and the p-type power feeding contact region 37n and a potential of the p-type peripheral well region 22n is fixed to the power supply potential. In other words, the potential of the p-type peripheral well region 22n is fixed to the power supply potential together with the conductor 28 of the separation region 25.

As described in the first embodiment presented earlier, the power supply potential is supplied to the respective p-type well regions 22 of the plurality of photoelectric conversion regions 21 through the power feeding contact region 37z of the power feeding region 32z and the potential of the p-type well regions 22 is fixed to the power supply potential. Therefore, in the solid-state imaging apparatus 1N according to the fourteenth embodiment, the potential of the p-type well regions 22 (including 22n) and the potential of the conductor 28 of the separation region 25 can be made the same.

Even with the solid-state imaging apparatus 1N according to the fourteenth embodiment, similar effects to those of the solid-state imaging apparatus 1K according to the eleventh embodiment described above can be obtained.

In addition, with the solid-state imaging apparatus 1N according to the fourteenth embodiment, since the potential of the p-type well regions 22 (including 22n) and the potential of the conductor 28 of the separation region 25 can be made the same, a potential difference in a vicinity of a contact interface between the conductor 28 and the adjacent p-type well region 22 is eliminated or, in other words, an electric field is relaxed and an effect of improving white spots is obtained.

Although not illustrated in FIG. 39, even in the solid-state imaging apparatus 1N according to the fourteenth embodiment, the color filter 55 and the microlens 56 shown in FIG. 6 are provided on the side of the light incident surface (the side of the second surface S2) of the semiconductor layer 20.

### Fifteenth Embodiment

A solid-state imaging apparatus 1P according to a fifteenth embodiment of the present technique is basically configured in a similar manner to the solid-state imaging apparatus 1K according to the eleventh embodiment described above but differs in the following aspects.

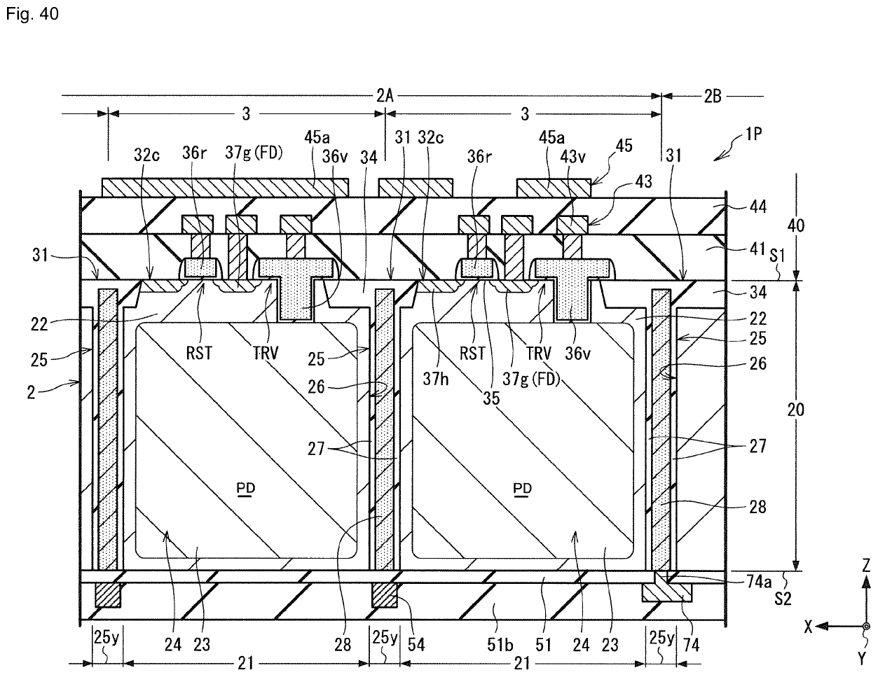

Specifically, as shown in FIG. 40, the solid-state imaging apparatus 1P according to the fifteenth embodiment includes a power feeding contact electrode (contact portion) 74a and a power feeding wiring 74 in place of the power feeding contact electrode 44b and the power feeding wiring 45b shown in FIG. 36 according to the eleventh embodiment described above. Other configurations are more or less the same as those in the eleventh embodiment described above.

As shown in FIG. 40, the power feeding wiring 74 is provided via the insulating film 51 on the side of the second surface S2 of the semiconductor layer 20. In addition, the power feeding wiring 74 is electrically connected to the conductor 28 of the separation region 25 via the power feeding contact portion 74a embedded in the insulating film 51 on the side of the second surface S2 of the semiconductor layer 20. The power feeding contact portion 74a according to the fifteenth embodiment is constituted of, for example, a part of the power feeding wiring 74. The power feeding contact portion 74a may be constituted of a power feeding contact electrode that is separate from the power feeding wiring 74 as in the case of the power feeding contact electrode 44b shown in FIG. 36 of the eleventh embodiment described above.

A power supply potential is applied to the power feeding wiring 74. A potential of the conductor 28 of the separation region 25 is fixed to the power supply potential applied to the transparent electrode 52. The power feeding wiring 74 is electrically connected to a power supply generation circuit (drive circuit) provided in the peripheral portion 2B of the semiconductor chip 2 in a similar manner to the eleventh embodiment described above and the power supply potential (for example, a first reference potential of 0 V) supplied from the power supply generation circuit is applied to the power feeding wiring 74. The application of the power supply potential to the power feeding wiring 74 and the fixing of the potential of the conductor 28 to the power supply potential are held during photoelectric conversion by the photoelectric conversion unit 24 or during driving of the pixel transistors (AMP, SEL, RST, FDG, and TRL) included in the readout circuit 15.

Although not illustrated in detail, the power feeding wiring 74 is provided in the periphery of the pixel array portion 2A in a similar manner to the power feeding wiring 45b according to the eleventh embodiment described above. In addition, for example, the power feeding wiring 74 has an annular planar pattern which stretches so as to enclose the periphery of the pixel array portion 2A.

Although not illustrated in detail, the power feeding contact portion 74a is scattered in plurality over the periphery of the pixel array portion 2A in a similar manner to the power feeding contact electrodes 44b according to the eleventh embodiment described above.

In addition, the power feeding contact portions 74b are arranged at positions overlapping the separation region 25 in a plan view. Furthermore, a power supply potential applied to the power feeding wiring 74 is supplied to the conductor 28 of the separation region 25 via the power feeding contact portions 74a and a potential of the conductor 28 is fixed to the supplied power supply potential.

The power feeding contact portions 74a are also preferably provided in intersection portions 25z where an X first portion 25x which stretches in the X direction of the separation region 25 and the second portion 25y which stretches in the Y direction of the separation region 25 intersect with each other in the periphery of the pixel array portion 2A in a similar manner to the power feeding contact electrode 44b according to the eleventh embodiment described above. In addition, as in the eleventh embodiment described above, the power feeding contact portions 74a may be provided in the separation region 25 between the intersection portions 25z.

A configuration in which the bonding pad 14 to which the power supply potential is applied from the outside among the plurality of bonding pads 14 shown in FIG. 33 and the power feeding wiring 74 are electrically connected to each other may be adopted. Even with the solid-state imaging apparatus 1P according to the fifteenth embodiment, similar effects to those of the solid-state imaging apparatus 1K according to the eleventh embodiment described above can be obtained.

In addition, although not illustrated in FIG. 40, even in the solid-state imaging apparatus 1P according to the fifteenth embodiment, the color filter 55 and the microlens 56 shown in FIG. 6 are provided on the side of the light incident surface (the side of the second surface S2) of the semiconductor layer 20.

### Sixteenth Embodiment

In a sixteenth embodiment, a technique of suppressing image quality degradation attributable to a parasitic capacitance by providing a barrier conductor between two contact electrodes will be described.

A solid-state imaging apparatus 1Q according to a sixteenth embodiment of the present technique is basically configured in a similar manner to the solid-state imaging apparatus 1C according to the third embodiment described above but differs in the following aspects.

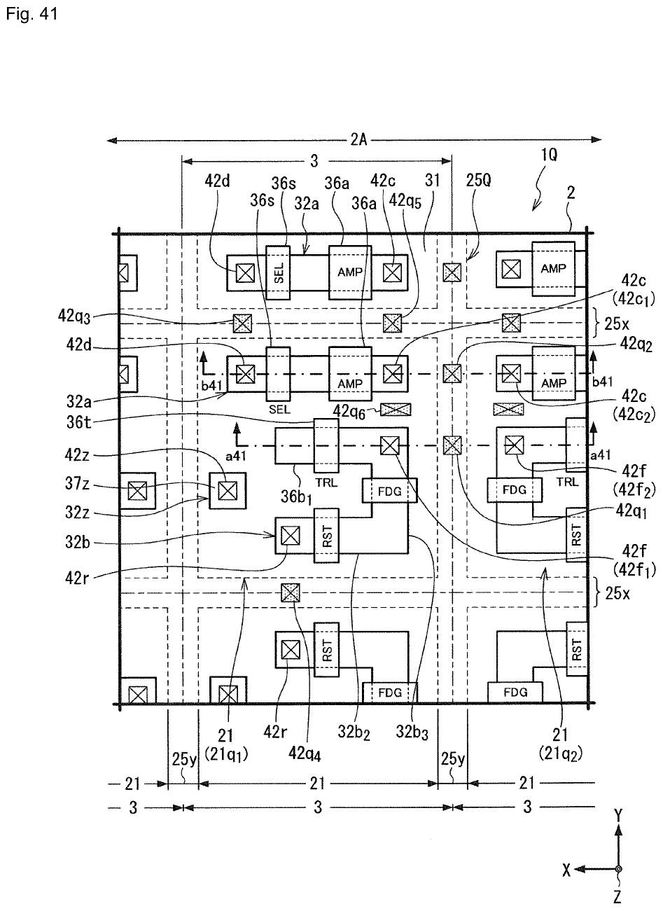

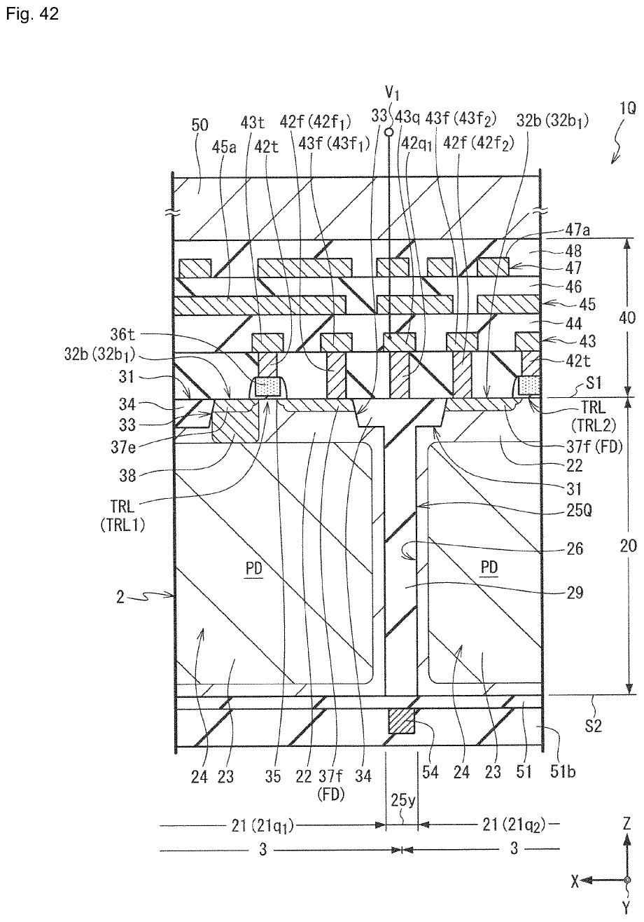

Specifically, as shown in FIGS. 41 and 42, the solid-state imaging apparatus 1Q according to the sixteenth embodiment includes an inter-pixel separation region 25Q in place of the separation region 25C shown in FIGS. 14 and 15 of the third embodiment described above. In addition, the solid-state imaging apparatus 1Q according to the sixteenth embodiment newly includes contact electrodes 42q₁ and 42q₂ and a wiring 43q. Other configurations are more or less the same as those in the third embodiment described above.

In the sixteenth embodiment, the element separation region 31 corresponds to a specific example of the “separation region” according to the present technique and the contact electrodes 42q₁ and 42q₂ correspond to a specific example of the “barrier conductor” according to the present technique.

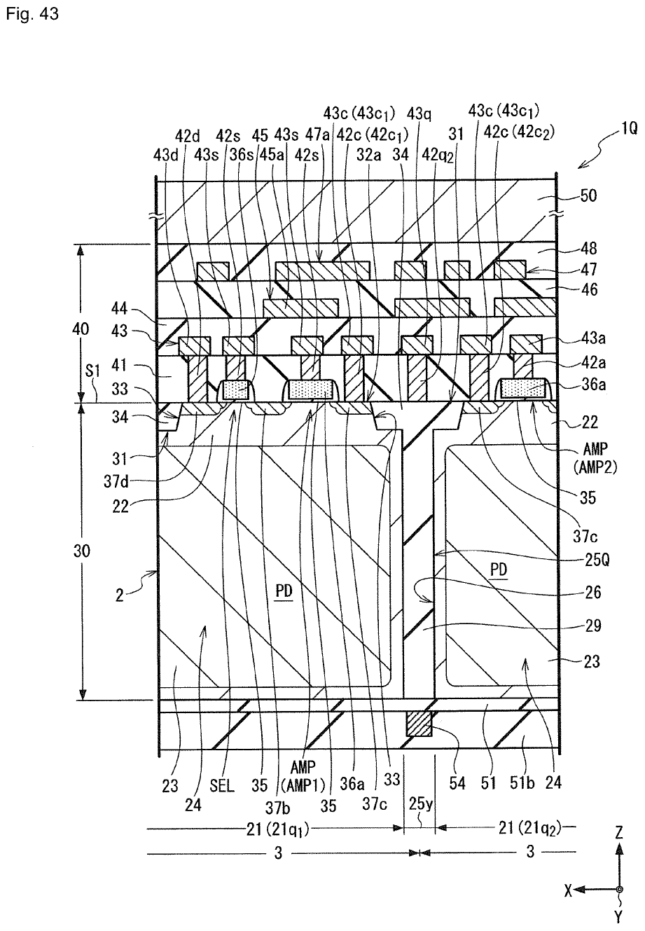

In addition, although not illustrated in FIGS. 42 and 43, even in the solid-state imaging apparatus 1Q according to the sixteenth embodiment, the color filter 55 and the microlens 56 shown in FIG. 15 are provided on the side of the light incident surface (the side of the second surface S2) of the semiconductor layer 20.

### <Element Separation Region>

As shown in FIGS. 41 and 42, the element separation region 31 according to the sixteenth embodiment is constructed of an STI structure in which the insulating film 34 is selectively embedded in the groove 33 which is provided in a surface layer portion on the side of the first surface S1 of the semiconductor layer 20 and which is depressed from the side of the first surface S1 toward the side of the second surface S2 of the semiconductor layer 20 in a similar manner to the element separation region 31 according to the first embodiment (refer to FIGS. 5 and 6) and the element separation region 31 according to the third embodiment (refer to FIGS. 14 and 15).

### <Element Formation Region>

As shown in FIGS. 41, 42, and 43, the first element formation region 32a and the second element formation region 32b which are partitioned by the element separation region 31 are provided for each photoelectric conversion region 21 (pixel 3) on the side of the first surface S1 of the semiconductor layer 20 in a similar manner to the third embodiment described above.

As shown in FIG. 41, the first element formation region 32a and the second element formation region 32b are disposed so as to be adjacent to each other in the Y direction in one photoelectric conversion region 21. The first element formation region 32a is constituted of a striped planar pattern created by stretching a planar pattern in a plan view in the X direction. The second element formation region 32b is constituted of a C-shaped planar pattern having the first portion 32b₁ and the second portion 32b₂, each of which stretches in the X direction and separates from each other in the Y direction, and the third portion 32c₃ which stretches in the Y direction and which is coupled to a side of one end of each of the first portion 32b₁ and the second portion 32b₂. In addition, the second element formation region 32b is disposed in an orientation which causes the first portion 32b₁ to be positioned on the side of the first element formation region 32a and the first portion 32b₁ and the second portion 32b₂ to be stretched along the first element formation region 32a in a similar manner to the second element formation region 32b according to the third embodiment described above. While a planar pattern of the first element formation region 32a and the second element formation region 32 is exemplified in FIG. 41, the planar pattern of the first element formation region 32a and the second element formation region 32 is not limited to the example shown in FIG. 41 and may be another planar pattern.

As shown in FIG. 41, the amplifying transistor AMP and the selection transistor SEL are provided by being connected in series in the first element formation region 32a in a similar manner to the third embodiment described above. In addition, in a similar manner to the third embodiment described above, in the second element formation region 32b, the first portion 32b₁ is provided with the transfer transistor TRL, the second portion 32b₂ is provided with the reset transistor RST, and the third portion 32b₃ is provided with the switching transistor FDG. While an arrangement pattern of pixel transistors (AMP, SEL, RST, FDG, and TRL) is exemplified in FIG. 41, the arrangement pattern of pixel transistors is not limited to the example in FIG. 41 and may be another arrangement pattern.

### <Amplifying Transistor and Selection Transistor>

As shown in FIG. 43, in a similar manner to the first embodiment described above, the amplifying transistor AMP includes the gate insulating film 35 provided on the first element formation region 32a on the side of the first surface S1 of the semiconductor layer 20, the gate electrode 36a provided on the first element formation region 32a via the gate insulating film 35, and a side wall spacer provided on a side wall of the gate electrode 36a so as to enclose the gate electrode 36a. In addition, the amplifying transistor AMP further includes a channel formation region in which a channel (conduction path) is formed in the p-type well region 22 directly beneath the gate electrode 36a and a pair of main electrode regions 37b and 37c which are provided in the p-type well region 22 so as to separate from each other in a channel length direction (gate length direction) and to sandwich the channel formation region and which function as a source region and a drain region.

In a similar manner to the first embodiment described above, the selection transistor SEL includes the gate insulating film 35 provided on the first element formation region 32a on the side of the first surface S1 of the semiconductor layer 20, the gate electrode 36s provided on the first element formation region 32a via the gate insulating film 35, and a side wall spacer provided on a side wall of the gate electrode 36s so as to enclose the gate electrode 36s. In addition, the selection transistor SEL further includes a channel formation region in which a channel (conduction path) is formed in the p-type well region 22 directly beneath the gate electrode 36s and the pair of main electrode regions 37d and 37b which are provided in the p-type well region 22 so as to separate from each other in the channel length direction (gate length direction) and to sandwich the channel formation region and which function as a source region and a drain region.

Even in the sixteenth embodiment, as shown in FIG. 43, the amplifying transistor AMP and the selection transistor SEL share one main electrode region (source region) 37b of the amplifying transistor AMP and the other main electrode region (drain region) 37b of the selection transistor SEL.

### <Transfer Transistor>

As shown in FIG. 42, in a similar manner to the third embodiment described above, the transfer transistor TRL includes the gate insulating film 35 provided on the second element formation region 32b on the side of the first surface S1 of the semiconductor layer 20, the gate electrode 36t provided on the second element formation region 32b via the gate insulating film 35, and a side wall spacer provided on a side wall of the gate electrode 36t so as to enclose the gate electrode 36t. In addition, the transfer transistor TRL further includes a channel formation region in which a channel (conduction path) is formed in the p-type well region 22 directly beneath the gate electrode 36t and a pair of main electrode regions 37e and 37f which are provided in the p-type well region 22 so as to separate from each other in the channel length direction (gate length direction) and to sandwich the channel formation region and which function as a source region and a drain region. Furthermore, unlike the amplifying transistor AMP and the selection transistor SEL described above, the transfer transistor TRL further includes the n-type relay region 38 which is provided in the p-type well region 22 between the one main electrode region 37e and the n-type semiconductor region 23 and which is electrically connected to each of the one main electrode region 37e and the n-type semiconductor region 23. The n-type relay region 38 is constituted of an n-type semiconductor region.

In the present embodiment, while the transfer transistor TRL has a lateral configuration in which the pair of main electrode regions (source region and drain region) are disposed so as to be separated from each other in a direction (X direction or a Y direction) that is orthogonal to the thickness direction (Z direction) of the semiconductor layer 20, alternatively, the transfer transistor TRL may have a vertical configuration in which a part or all of the gate electrode is embedded in a groove part of the semiconductor layer 20 via the gate insulating film.

### <Reset Transistor and Switching Transistor>

Although not illustrated in detail, each of the reset transistor RST and the switching transistor FDG shown in FIG. 41 is configured in a similar manner to the amplifying transistor AMP and the selection transistor SEL described above. In addition, the reset transistor RST and the switching transistor FDG share one main electrode region (source region) of the reset transistor RST and the other main electrode region (drain region) of the switching transistor FDG.

### <Inter-Pixel Separation Region>

As shown in FIGS. 42 and 43, the inter-pixel separation region 25Q according to the sixteenth embodiment is basically configured in a similar manner to the separation region 25C according to the third embodiment described above but differs in a structure of a longitudinal cross-section along the thickness direction of the semiconductor layer 20. Specifically, the inter-pixel separation region 25Q according to the sixteenth embodiment includes the excavated portion 26 provided on the semiconductor layer 20 and a filling insulating film 29 which fills the excavated portion 26. As a material of the filling insulating film 29, for example, a silicon oxide film can be used.

The inter-pixel separation region 25Q stretches in the thickness direction of the semiconductor layer 20, and one end of the inter-pixel separation region 25Q is coupled to the element separation region 31 while another end on the opposite side to the one end reaches the second surface S2 of the semiconductor layer 20. In addition, the inter-pixel separation region 25Q has a grid-like planar pattern in which the first portion 25x which stretches in the X direction and the second portion 25y which stretches in the Y direction are orthogonal to each other in a similar manner to the separation region 25 according to the first embodiment and the separation region 25C according to the third embodiment described earlier. Furthermore, in each photoelectric conversion region 21 of the plurality of photoelectric conversion regions 21, both ends in the X direction are partitioned by the two second portions 25y adjacent to each other of the inter-pixel separation region 25Q and both ends in the Y direction are partitioned by the two first portions 25x adjacent to each other of the inter-pixel separation region 25Q.

### <Planar Pattern of Element Separation Region and Planar Arrangement Pattern of Pixel Transistors>

As shown in FIG. 41, in the two photoelectric conversion regions 21 that are adjacent to each other in the X direction, a planar pattern of each of the element formation regions (32a and 32b) and a planar arrangement pattern of the pixel transistors (AMP, SEL, TRL, RST, and FDG) are an inverse pattern with the inter-pixel separation region 25Q (25y) between the two photoelectric conversion regions 21 as an inversion axis. In addition, in the two photoelectric conversion regions 21 that are adjacent to each other in the Y direction, a planar pattern of each of the element formation regions (32a and 32b) and a planar arrangement pattern of the pixel transistors (AMP, SEL, TRL, RST, and FDG) are an inverse pattern with the inter-pixel separation region 25Q (25y) between the two photoelectric conversion regions 21 as an inversion axis. In other words, the pixel array portion 2A according to the sixteenth embodiment includes the photoelectric conversion regions 21 of which pixel transistors with the same functions are adjacent to each other via the inter-pixel separation region 25Q in a plan view in a similar manner to the first and third embodiments described above. FIGS. 42 and 43 illustrate, as an example, two photoelectric conversion regions 21 (21q₁ and 21q₂) of which respective transfer transistors TRL and respective amplifying transistors AMP are adjacent to each other in the X direction.

As shown in FIG. 42, of the respective transfer transistors TRL (TRL1 and TRL2) of two photoelectric conversion regions 21 (21q₁ and 21q₂) that are adjacent to each other, the other main electrode regions 37f among pairs of main electrode regions 37e and 37f are adjacent to each other via the element separation region 31.

In addition, as shown in FIG. 43, of the respective amplifying transistors AMP (AMP1 and AMP2) of two photoelectric conversion regions 21 (21q₁ and 21q₂) that are adjacent to each other, the other main electrode regions 37c among pairs of main electrode regions 37b and 37c are adjacent to each other via the element separation region 31. Note that the arrangement pattern of the photoelectric conversion regions 21 is not limited to the inverse pattern shown in FIG. 41 and may be another arrangement pattern.

### <Multilayer Wiring Layer>

As shown in FIGS. 42 and 43, the multilayer wiring layer 40 is provided on the side of the first surface S1 of the semiconductor layer 20. The multilayer wiring layer 40 according to the sixteenth embodiment is configured in a similar manner to the multilayer wiring layers 40 according to the first and third embodiments described earlier. In addition, the multilayer wiring layer 40 according to the sixteenth embodiment newly includes contact electrodes 42q₁ and 42q₂ and a wiring 43q. The contact electrodes 42q₁ and 42q₂ are provided on the interlayer insulating film 41 of the multilayer wiring layer 40. The wiring 43q is formed on the first wiring layer. The interlayer insulating film 41 is provided so as to cover the pixel transistors (AMP, SEL, RST, FDG, and TRL) on the side of the first surface S1 of the semiconductor layer 20.

As shown in FIG. 42, in the two photoelectric conversion regions 21 (21q₁ and 21q₂), the other main electrode region 37f of the transfer transistor TRL1 provided in the one photoelectric conversion region 21q₁ is electrically connected to the wiring 43f (43f₁) formed on the first wiring layer 43 of the multilayer wiring layer 40 via the contact electrode 42f (42f₁) that is embedded in the interlayer insulating film 41 of the multilayer wiring layer 40. In addition, the other main electrode region 37f of the transfer transistor TRL2 provided in the other photoelectric conversion region 21q₂ is electrically connected to the wiring 43f (43f₂) formed on the first wiring layer 43 of the multilayer wiring layer 40 via the contact electrode 42f (42f₂) that is embedded in the interlayer insulating film 41 of the multilayer wiring layer 40. The wiring 43f₁ and the wiring 43f₂ are respectively individually electrically connected to the input side of the readout circuit 15 described earlier which is provided for each photoelectric conversion region 21 (pixel 3).

As shown in FIG. 43, in the two photoelectric conversion regions 21 (21q₁ and 21q₂), the other main electrode region 37c of the amplifying transistor AMP1 provided in the one photoelectric conversion region 21q₁ is electrically connected to the wiring 43c (43c₁) formed on the first wiring layer 43 of the multilayer wiring layer 40 via the contact electrode 42c (42c₁) that is embedded in the interlayer insulating film 41 of the multilayer wiring layer 40. In addition, the other main electrode region 37b of the amplifying transistor AMP2 provided in the other photoelectric conversion region 21q₂ is electrically connected to the wiring 43c (43c₂) formed on the first wiring layer 43 of the multilayer wiring layer 40 via the contact electrode 42c (42c₂) that is embedded in the interlayer insulating film 41 of the multilayer wiring layer 40.

In this case, in the sixteenth embodiment, the contact electrodes 42f₁ and 42f₂ shown in FIG. 42 correspond to specific examples of the “first and second contact electrode” according to the present technique and the contact electrodes 42c₁ and 42c₂ shown in FIG. 43 correspond to specific examples of the “first and second contact electrode” according to the present technique. In addition, the contact electrodes 42q₁ and 42q₂ correspond to specific examples of the “barrier conductor” according to the present technique.

As shown in FIGS. 41 and 42, the contact electrode 42q₁ as a barrier conductor is provided between the contact electrode 42f₁ and the contact electrode 42f₂ in a plan view. The contact electrode 42q₁ is embedded in the interlayer insulating film 41 in a similar manner to the contact electrode 42f₁ and the contact electrode 42f₂. In addition, the contact electrode 42q₁ is electrically connected to the wiring 43q formed on the first wiring layer 43 of the multilayer wiring layer 40.

In addition, as shown in FIGS. 41 and 43, the contact electrode 42q₂ as a barrier conductor is provided between the contact electrode 42c₁ and the contact electrode 42c₂ in a plan view. The contact electrode 42q₂ is embedded in the interlayer insulating film 41 in a similar manner to the contact electrode 42c₁ and the contact electrode 42c₂. In addition, the contact electrode 42q₂ is electrically connected to the wiring 43q in a similar manner to the contact electrode 42q₁.

As shown in FIGS. 42 and 43, each of the contact electrodes 42q₁ and 42q₂ is provided so as to overlap with the element separation region 31 and the inter-pixel separation region 25Q in a plan view. In other words, each of the contact electrodes 42q₁ and 42q₂ is provided on the inter-pixel separation region 25Q via the element separation region 31. In addition, each of the contact electrodes 42q₁ and 42q₂ stretches in a film thickness direction (Z direction) of the interlayer insulating film 41, with one end corrected to a surface of the element separation region 31 and the other end electrically and mechanically connected to the wiring 43q.

As shown in FIGS. 42 and 43, the wiring 43q is electrically connected to each of the contact electrodes 42q₁ and 42q₂. In addition, in the sixteenth embodiment, although not limited thereto, a first reference potential V₁ as the power supply potential is applied to the wiring 43q. In other words, the first reference potential V₁ is applied (supplied) via the wiring 43q to each of the contact electrodes 42q₁ and 42q₂ and a potential of each of the contact electrodes 42q₁ and 42q₂ is fixed to the first reference potential V₁. For example, 0 V is applied as the first reference potential V₁.

Although not illustrated, for example, the wiring 43q is electrically connected to a power generation circuit (drive circuit) which supplies a constant power supply potential and the first reference potential V₁ that is supplied from the power generation circuit is applied to the wiring 43q. The application (supply) of the first reference potential V₁ to the wiring 43q is held during photoelectric conversion by the photoelectric conversion unit 24 or during driving of the pixel transistors (AMP, SEL, RST, FDG, and TRL) included in the readout circuit 15.

Note that the wiring 43q may be configured to be electrically connected to the bonding pad 14 to which the power supply potential is applied from the outside among the plurality of bonding pads 14 shown in FIG. 1.

As shown in FIG. 42, the wiring 43q is provided between wirings 43f₁ and 43f₂ in a plan view. In addition, as shown in FIG. 43, the wiring 43q is provided between wirings 43c₁ and 43c₂ in a plan view.

As shown in FIG. 42, although the contact electrode 42q₁ is not limited thereto, a shape and a size of a transverse cross-section thereof (a cross section in a direction orthogonal to a stretching direction (Z direction) of the contact electrode 42q₁) is the same as the contact electrodes 42f₁ and 42f₂. In addition, although the contact electrode 42q₂ is not limited thereto, a shape and a size of a transverse cross-section thereof (a cross section in a direction orthogonal to a stretching direction (Z direction) of the contact electrode 42q₂) is the same as the contact electrodes 42c₁ and 42c₂. The contact electrodes 42q₁ and 42q₂ can be formed in a same process as the contact electrodes 42f (42f₁ and 42f₂) and 42c (42c₁ and 42c₂) and, in this case, the contact electrodes 42q₁ and 42q₂ are constituted of a same material as the contact electrodes 42f and 42c.

### Main Effects of Sixteenth Embodiment

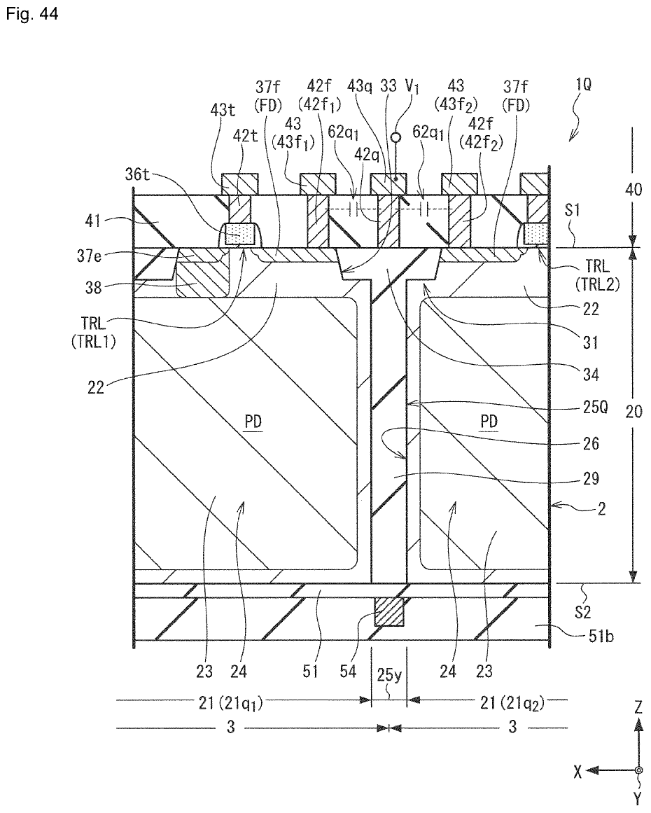

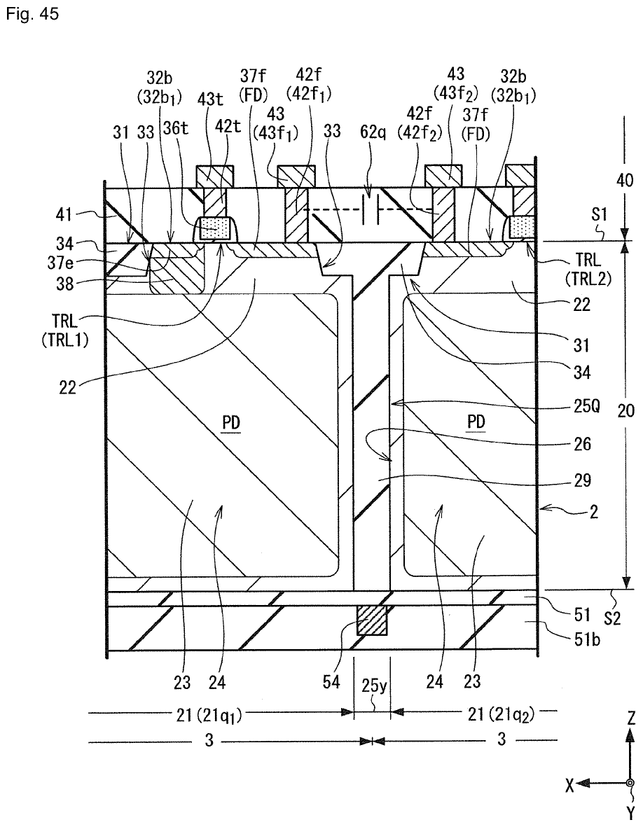

Next, the main effects of the sixteenth embodiment will be described using FIGS. 44 and 45.

FIG. 44 is a longitudinal cross-sectional view for describing an effect of the sixteenth embodiment. FIG. 45 is a longitudinal cross-sectional view schematically showing a longitudinal cross-sectional structure according to a comparative example.

As shown in FIG. 45, in the comparative example, in the two photoelectric conversion regions 21 (21q₁ and 21q₂) lined up in the X direction, the other main electrode region 37f of the transfer transistor TRL1 provided in the one photoelectric conversion region 21q₁ and the other main electrode region 37f of the transfer transistor TRL2 provided in the other photoelectric conversion region 21q₂ are adjacent to each other via the element separation region 31. In addition, the contact electrode 42f₁ is connected to the main electrode region 37f of the transfer transistor TRL1 and the contact electrode 42f₂ is connected to the main electrode region 37f of the transfer transistor TRL2. In other words, the two contact electrodes 42f₁ and 42f₂ are arranged adjacent to each other.

When the two contact electrodes 42f₁ and 42f₂ are arranged adjacent to each other in this manner, as shown in FIG. 45, a parasitic capacitance (coupling capacitance) 62q with one contact electrode 42f₁ as one electrode and the other contact electrode 42f₂ as another electrode is formed. In addition, via the parasitic capacitance 62q, noise (a fluctuation of potential) during operation of one transfer transistor TRL1 propagates from the one contact electrode 42f₁ to the other contact electrode 42f₂ and, conversely, noise during operation of the other transfer transistor TRL2 propagates from the other contact electrode 42f₂ to the one contact electrode 42f₁. The propagation of noise between the two contact electrodes 42f₁ and 42f₂ causes a degradation in image quality and reduces reliability.

Specifically, to provide a description with reference to FIG. 15 of the third embodiment described above, between pixels 3 (Gr pixels 3) including the red (R) color filter 55 and pixels 3 (Gb pixels 3) including the blue (B) color filter 55, the photoelectric conversion units 24 are connected via conductive paths to different readout circuits 15. Therefore, as shown in FIG. 45, due to the propagation of noise between the contact electrodes 42f₁ and 42f₂ via the parasitic capacitance 62q, an output level difference occurs between the Gr pixels 3 and the Gb pixels 3 and a variance in output is created among the pixels 3. The variance in output among the pixels 3 causes a decline in image quality and must be resolved in order to improve reliability.

In contrast, as shown in FIG. 44, in the sixteenth embodiment, the contact electrode 42q₁ is provided between the contact electrode 42f₁ and the contact electrode 42f₂. In addition, the contact electrode 42q₁ is electrically connected to the wiring 43q to which, for example, the first reference potential V₁ of 0 V is applied. As a result, although parasitic capacitances 62q₁ are respectively formed between the contact electrode 42f₁ and the contact electrode 42q₁ and between the contact electrode 42f₂ and the contact electrode 42q₁, noise (a fluctuation of potential) can be absorbed by the wiring 42q and the parasitic capacitance between the contact electrode 42f₁ and the contact electrode 42f₂ can be reduced. In other words, the propagation of noise (a fluctuation of potential) between the contact electrode 42f₁ and the contact electrode 42f₂ can be suppressed.

Since the propagation of noise (a fluctuation of potential) between the two contact electrodes 42f₁ and the contact electrode 42f₂ can be suppressed, a variation in output among the pixels 3 attributable to an output level difference between the Gr pixels 3 and the Gb pixels 3 can be suppressed and a degradation in image quality can be suppressed. In other words, image quality can be improved. Therefore, the solid-state imaging apparatus 1Q according to the sixteenth embodiment is capable of improving image quality. In addition, with the solid-state imaging apparatus 1Q according to the sixteenth embodiment, a degradation in image quality can be suppressed and reliability can be further improved.

In recent years, since there is a tendency towards a shorter distance between the two contact electrodes 42f₁ and 42f₂ with the miniaturization of photoelectric conversion regions 21 in light detection apparatuses such as solid-state imaging apparatuses and ranging apparatuses, the suppression of the propagation of noise (a fluctuation of potential) by arranging the contact electrode 42q₁ between the two contact electrodes 42f₁ and 42f₂ as in the sixteenth embodiment is important. Therefore, by suppressing the propagation of noise between the two contact electrodes 42f₁ and 42f₂, miniaturization of the photoelectric conversion regions 21 can be achieved while suppressing a degradation in image quality.

In the solid-state imaging apparatus 1Q according to the sixteenth embodiment, the wiring 43q to which a potential is to be applied is arranged between the wiring 43f₁ connected to the contact electrode 42f₁ and the wiring 43f₂ connected to the contact electrode 42f₂. As a result, since the propagation of noise (a fluctuation of potential) between the wiring 43f₁ and the wiring 43f₂ can also be suppressed, further miniaturization of the photoelectric conversion regions 21 can be achieved while suppressing a degradation in image quality.

As shown in FIG. 43, in the solid-state imaging apparatus 1Q according to the sixteenth embodiment, in two photoelectric conversion regions 21q₁ and 21q₂ that are adjacent to each other, the other main electrode region 37c of the amplifying transistor AMP1 provided in one photoelectric conversion region 21q₁ and the other main electrode region 37c of the amplifying transistor AMP2 provided in the other photoelectric conversion region 21q₂ are adjacent to each other via the element separation region 31. In addition, the contact electrode 42c₁ is connected to the main electrode region 37c of the amplifying transistor AMP1 and the contact electrode 42c₂ is connected to the main electrode region 37c of the amplifying transistor AMP2. Furthermore, the two contact electrodes 42c₁ and 42c₂ are adjacent to each other in the X direction. In addition, the contact electrode 42q₂ is also provided between the two contact electrodes 42c₁ and 42c₂. Furthermore, the contact electrode 42q₂ is electrically connected to the wiring 43q to which, for example, the first reference potential V₁ of 0 V is to be applied in a similar manner to the contact electrode 42q₁ described above. Therefore, with the solid-state imaging apparatus 1Q according to the sixteenth embodiment, the propagation of noise (a fluctuation of potential) between the contact electrode 42c₁ and the contact electrode 42c₂ can be suppressed in a similar manner to the suppression of propagation of noise between the two contact electrodes 42f₁ and 42f₂ described above.

In the present sixteenth embodiment, the suppression of propagation of noise between the two contact electrodes 42c₁ and 42c₂ respectively individually connected to the main electrode regions 37f of the respective transfer transistors TRL1 and TRL2 and the suppression of propagation of noise between the two contact electrodes 42c₁ and 42c₂ respectively individually connected to the main electrode regions 37c of the respective amplifying transistors AMP1 and AMP2 of two photoelectric conversion regions 21q₁ and 21q₂ that are adjacent to each other has been described. However, the present technique is not limited to the suppression of propagation of noise between the two contact electrodes 42f₁ (42c₁) and 42f₂ (42c₂) and obviously can suppress the propagation of noise between two contact electrodes respectively connected to the main electrode regions of two other pixel transistors that are adjacent to each other via the element separation region 31.

For example, as shown in FIG. 41, by providing a contact electrode 42q₃ between two contact electrodes 42d respectively individually connected to the respective main electrode regions of two selection transistors SEL that are adjacent to each other via the element separation region 31 in the Y direction, the propagation of noise between the two contact electrodes 42d can be suppressed.

In addition, as shown in FIG. 41, by providing a contact electrode 42q₄ between two contact electrodes 42r respectively individually connected to the respective main electrode regions of two reset transistors RST that are adjacent to each other via the element separation region 31 in the Y direction, the propagation of noise between the two contact electrodes 42r can be suppressed.

Furthermore, as shown in FIG. 41, by providing a contact electrode 42q₅ between two contact electrodes 42c respectively individually connected to the respective main electrode regions of two amplifying transistors AMP that are adjacent to each other via the element separation region 31 in the Y direction, the propagation of noise between the two contact electrodes 42c can be suppressed.

In addition, as shown in FIG. 41, when the main electrode region 37f (refer to FIG. 42) of the transfer transistor TRL and the main electrode region 37c (refer to FIG. 43) of the amplifying transistor AMP are adjacent to each other via the element separation region 31 in one photoelectric conversion region 21, by providing a contact electrode 42q₆ between the contact electrode 42f connected to the main electrode region 37f of the transfer transistor TRL and the contact electrode 42c connected to the main electrode region 37c of the amplifying transistor AMP, the propagation of noise between the two contact electrodes 42f and 42c can be suppressed.

In other words, by providing a barrier conductor between two contact electrodes respectively individually connected to the respective main electrode regions of two pixel transistors that are adjacent to each other via the element separation region 31, the present technique enables the propagation of noise between the two contact electrodes 42f and 42c to be suppressed. The barrier conductor need not be provided between every two contact electrodes and may be selectively provided in consideration of a degree of propagation of noise, a layout, or the like.

Note that the contact electrodes 42q₃ to 42q₆ according to the sixteenth embodiment also correspond to the “barrier conductor” according to the present technique.

### Modification of Sixteenth Embodiment

### First Modification

In the sixteenth embodiment described above, a case where transverse cross-sectional shapes and sizes of the contact electrodes 42q₁ and 42q₂ are the same as transverse cross-sectional shapes and sizes of two contact electrodes (42f₁ and 42f₂, 42c₁ and 42c₂) that are adjacent to each other has been described. However, the transverse cross-sectional shapes and the sizes of the contact electrodes 42q₁ and 42q₂ need not necessarily be the same as the two contact electrodes (42f₁ and 42f₂, 42c₁ and 42c₂). The point is that the contact electrodes 42q₁ and 42q₂ need only be arranged between the two contact electrodes (42f₁ and 42f₂, 42c₁ and 42c₂) in a plan view.

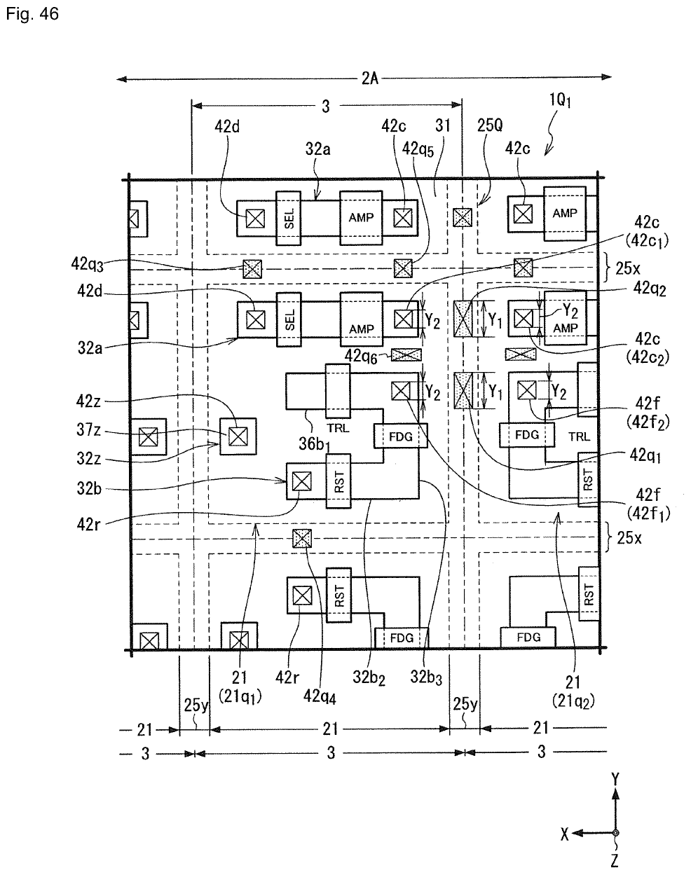

For example, as shown in FIG. 46, a width Y1 in the Y direction of the contact electrode 42q₁ (42q₂) may be made larger than a width Y2 in the Y direction of the contact electrodes 42f₁ and 42f₂ (42c₁ and 42c₂) so as to cross between two contact electrodes 42f₁ (42c₁) and 42f₂ (42c₂) that are lined up so as to be separated from each other in the X direction. In addition, although not illustrated, the width Y1 in the Y direction of the contact electrode 42q₁ (42q₂) may be made smaller than the width Y2 in the Y direction of the contact electrodes 42f₁ and 42f₂ (42c₁ and 42c₂).

In this case, the contact electrode 42q₁ (42q₂) functions as a barrier that suppresses propagation of noise between the two contact electrodes 42f₁ and 42f₂ (42c₁ and 42c₂). Therefore, the contact electrode 42q₁ (42q₂) is preferably provided so as to cross between the two contact electrodes 42f₁ and 42f₂ (42c₁ and 42c₂) in a plan view.

Even with a solid-state imaging apparatus 1Q1 according to the first modification of the sixteenth embodiment, similar effects to those of the solid-state imaging apparatus 1Q according to the sixteenth embodiment described above can be obtained.

### Second Modification

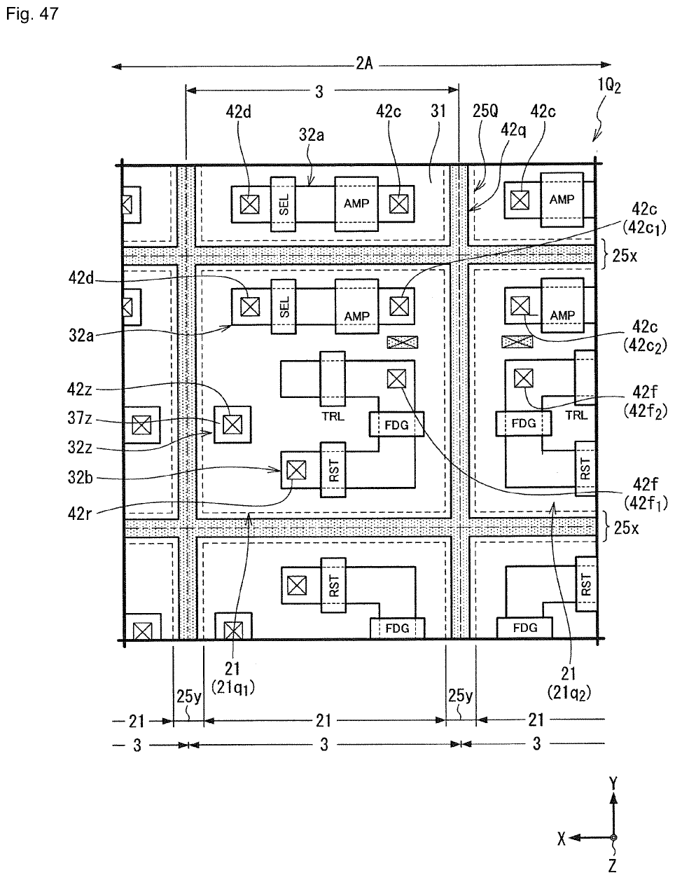

In the sixteenth embodiment described above, as shown in FIG. 41, a case where there is a scattering of contact electrodes 42q₁ to 42q₅ has been described. In contrast, as shown in FIG. 47, in a second modification of the sixteenth embodiment, the contact electrode 42q is constituted of a grid-like planar pattern similar to that of the inter-pixel separation region 25Q. In this case, the contact electrode 42q is a planar pattern which encloses a periphery of the photoelectric conversion region 21 for each photoelectric conversion region 21 in a plan view. In other words, the contact electrode 42q is a planar pattern which individually encloses each of two photoelectric conversion regions 21 that are adjacent to each other.

Even with a solid-state imaging apparatus 1Q2 according to the second modification of the sixteenth embodiment, similar effects to those of the solid-state imaging apparatus 1Q according to the sixteenth embodiment described above can be obtained.

### Third Modification

In the sixteenth embodiment described above, as a structure in a longitudinal direction of the contact electrodes 42q₁ and 42q₂, a structure in which one end of each of the contact electrodes 42q₁ and 42q₂ is connected to a surface of the element separation region 31 has been described as shown in FIGS. 42 and 43.

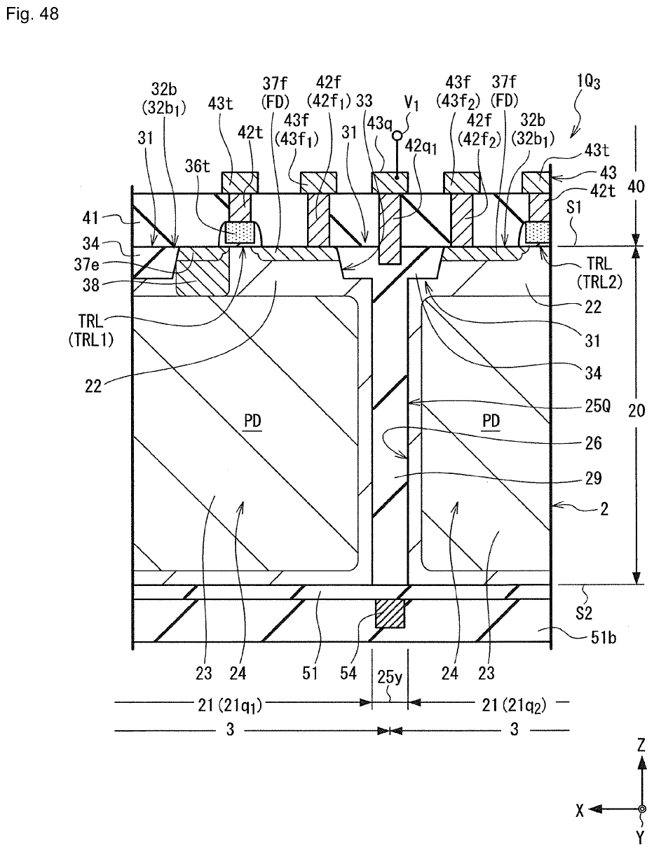

In contrast, as shown in FIG. 48, in a third modification of the sixteenth embodiment, one end of the contact electrode 42q₁ is provided inside the element separation region 31. In other words, the contact electrode 42q₁ is stretched along the interlayer insulating film 41 and the element separation region 31. In yet other words, the contact electrode 42q₁ is stretched between the two contact electrodes 42f₁ and 42f₂ and the two transfer transistors TRL1 and TRL2. Specifically, the contact electrode 42q₁ is provided between the two contact electrodes 42q₁ and 42q₂ and also provided between the respective main electrode regions 37f of the two transfer transistors TRL1 and TRL2.

With a solid-state imaging apparatus 103 according to the third modification of the sixteenth embodiment, in two transfer transistors TRL1 and TRL2 provided adjacent to each other via the element separation region 31, a parasitic capacitance between the contact electrode 42f₁ connected to the main electrode region 37f of one transfer transistor TRL1 and the contact electrode 42f₂ connected to the main electrode region 37f of the other transfer transistor TRL2 can be reduced and, at the same time, a parasitic capacitance between the main electrode region 37f of the one transfer transistor TRL1 and the main electrode region 37f of the other transfer transistor TRL2 can be reduced. In other words, the propagation of noise (a fluctuation of potential) between the contact electrode 42f₁ and the contact electrode 42f₂ can be suppressed and, at the same time, the propagation of noise (a fluctuation of potential) between the main electrode region 37f of the one transfer transistor TRL1 and the main electrode region 37f of the other transfer transistor TRL2 can be suppressed. Therefore, the solid-state imaging apparatus 103 according to the third modification of the sixteenth embodiment is capable of further improving image quality. In addition, with the solid-state imaging apparatus according to the third modification of the sixteenth embodiment, a degradation in image quality can be suppressed and reliability can be further improved.

While the contact electrode 42q₁ is exemplified in the third modification of the sixteenth embodiment, the other contact electrodes 42q₂ to 42q₆ can also be configured so as to stretch along the interlayer insulating film 41 and the element separation region 31 in a similar manner to the contact electrode 42q₁.

### Fourth Modification

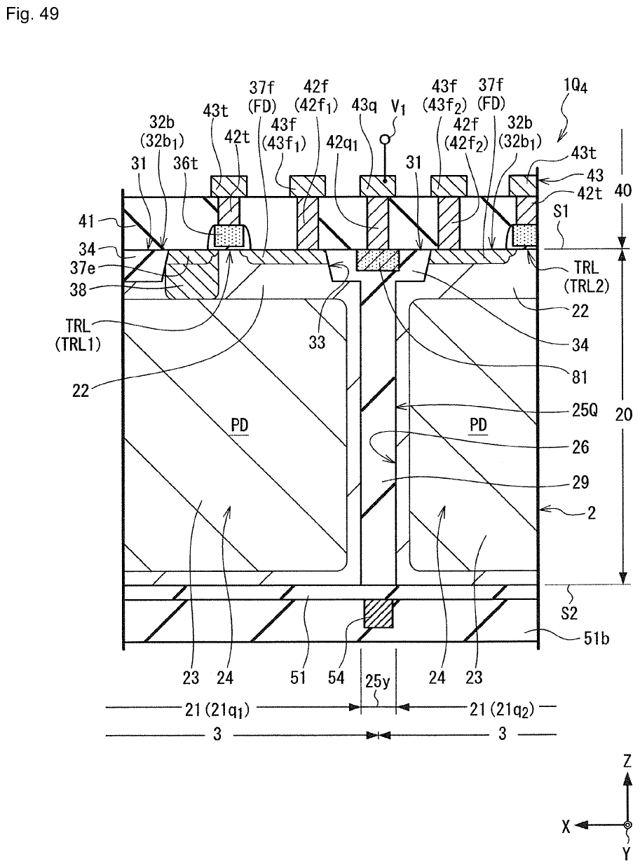

As shown in FIG. 49, in a fourth modification of the sixteenth embodiment, an embedded conductor 81 that is embedded in the element separation region 31 between two contact electrodes 42f₁ and 42f₂ in a plan view is provided. In addition, the embedded conductor 81 is provided between the main electrode region 37f of the transfer transistor TRL1 and the main electrode region 37f of the transfer transistor TRL2. Furthermore, one end of the contact electrode 42q₁ is electrically and mechanically connected to the embedded conductor 81 and another end on an opposite side to the one end is electrically and mechanically connected to the wiring 43q.

Even with a solid-state imaging apparatus 104 according to the fourth modification of the sixteenth embodiment, similar effects to those of the solid-state imaging apparatus according to the third modification of the sixteenth embodiment described above can be obtained.

While the contact electrode 42q₁ is exemplified in the fourth modification of the sixteenth embodiment, the other contact electrodes 42q₂ to 42q₆ can also be configured so that one end is electrically and mechanically connected to the embedded conductor 81 that is embedded in the element separation region 31 and the other end is electrically and mechanically connected to the wiring 43q in a similar manner to the contact electrode 42q₁.

The embedded conductor 81 may be scattered in a similar manner to the contact electrodes 42q₁ to 42q₆ shown in FIG. 41 of the sixteenth embodiment described above and may be constituted of a grid-like planar pattern in a similar manner to the inter-pixel separation region 25Q. When the embedded conductor 81 is to be scattered, the embedded conductor 81 is preferably provided so as to cross between two contact electrodes in a plan view. As the embedded conductor 81, for example, a semiconductor film into which an impurity for reducing a resistance value has been introduced, a metal film, or the like can be used.

### Fifth Modification

In the sixteenth embodiment and the first to fourth embodiments of the sixteenth embodiment described above, as shown in FIG. 42, a case where the first reference potential V₁ of 0 V is applied as the power supply potential to be applied to the wiring 43q has been described. However, as the power supply potential to be applied to the wiring 43q, a second reference potential V₂ that is a positive potential higher than the first reference potential V₁ or a third reference potential V₃ that is a negative potential lower than the first reference potential V₁ may be applied. Even in this case, similar effects to those of the sixteenth embodiment and the first to fourth embodiments of the sixteenth embodiment described above can be obtained.

### Sixth Modification

Instead of fixing the potential of the wiring 43q to the power supply potential, the wiring 43q may be placed in an electrically floating state. In this case, the wiring 43q preferably has a capacitance that enables noise (a fluctuation of potential) between the two contact electrodes 42f₁ and 42f₂ to be absorbed. For example, the wiring 43q is routed inside the wiring layer 43 and a parasitic capacitance with a wiring of a different potential is added to the wiring 43q. Even in this case, similar effects to those of the sixteenth embodiment and the first to fifth modifications of the sixteenth embodiment described above can be obtained.

Note that the method of placing the wiring 43q in a floating state and adding a parasitic capacitance with a wiring of a different potential to the wiring 43q can also be applied in the sixteenth embodiment and the first to fourth modifications of the sixteenth embodiment described above.

### Seventeenth Embodiment

A solid-state imaging apparatus 1R according to a seventeenth embodiment of the present technique is basically configured in a similar manner to the solid-state imaging apparatus 1Q according to the sixteenth embodiment described above but differs in the following aspects.

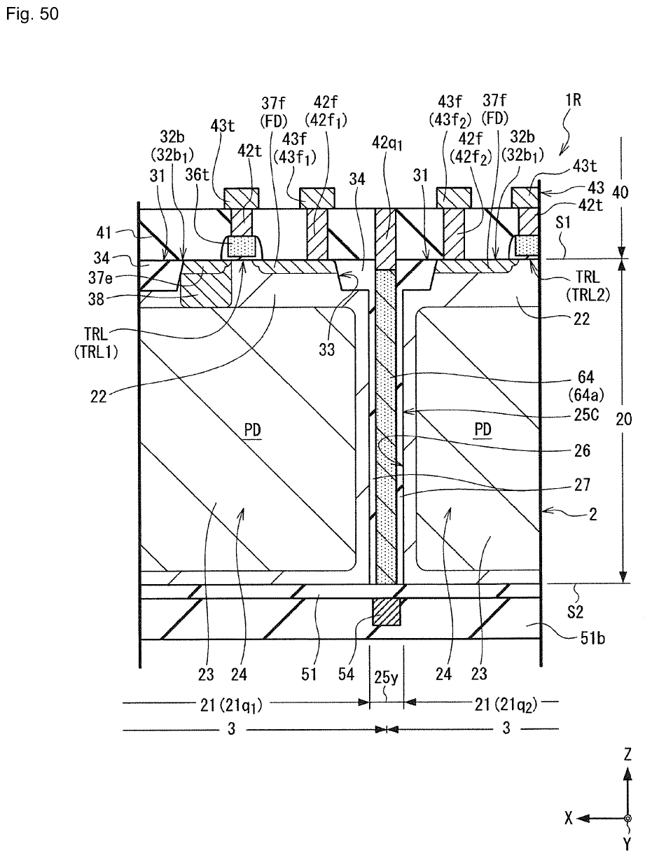

Specifically, as shown in FIG. 50, the solid-state imaging apparatus 1R according to the sixteenth embodiment includes the separation region 25C shown in FIG. 15 of the third embodiment described above in place of the inter-pixel separation region 25Q shown in FIG. 42 of the sixteenth embodiment described above. In addition, one end of the contact electrode 42q₁ is electrically and mechanically connected to the floating conductor 64 of the separation region 25C. Furthermore, while the wiring 43q is provided in the sixteenth embodiment described above, the wiring 43q is not provided in the present seventeenth embodiment.

Although not illustrated in FIG. 50, even in the solid-state imaging apparatus 1R according to the seventeenth embodiment, the color filter 55 and the microlens 56 shown in FIG. 42 are provided on the side of the light incident surface (the side of the second surface S2) of the semiconductor layer 20.

The potential of the floating conductor 64 is not fixed to the power supply potential and the floating conductor 64 is in an electrically floating state. In addition, since the floating conductor 64 stretches in the thickness direction of the semiconductor layer 20 and a shape in a plan view is a grid-like planar pattern, the floating conductor 64 has enough capacitance to absorb noise (a fluctuation of potential) between the two contact electrodes 42f₁ and 42f₂.

Therefore, even with the solid-state imaging apparatus 1R according to the seventeenth embodiment, similar effects to those of the sixteenth embodiment and the first to sixth modifications of the sixteenth embodiment described above can be obtained.

While the contact electrode 42q₁ is exemplified in the seventeenth embodiment, one end of the other contact electrodes 42q₂ to 42q₆ shown in FIG. 42 is also preferably electrically and mechanically connected to the floating conductor 64 of the separation region 25C in a similar manner to the contact electrode 42q₁.

In addition, while a case where the contact electrode 42q₁ as a barrier conductor is connected to the floating conductor 64 of the separation region 25C has been described in the seventeenth embodiment, the floating conductor 64 of the separation region 25C may be used as a potential supplying wiring for supplying potential to the contact electrode 42q₁. In this case, for example, the floating conductor 64 is electrically connected to a power generation circuit (drive circuit) which supplies a constant power supply potential and a power supply potential that is supplied from the power generation circuit is applied to the floating conductor 64. Furthermore, in this case, the floating conductor 64 may be configured to be electrically connected to the bonding pad 14 to which the power supply potential is applied from the outside among the plurality of bonding pads 14 shown in FIG. 1. The point is a barrier conductor may be connected to a conductor in a separation region.

### Eighteenth Embodiment

A solid-state imaging apparatus 1S according to an eighteenth embodiment of the present technique is basically configured in a similar manner to the solid-state imaging apparatus 1Q according to the sixteenth embodiment described above but differs in the following aspects.

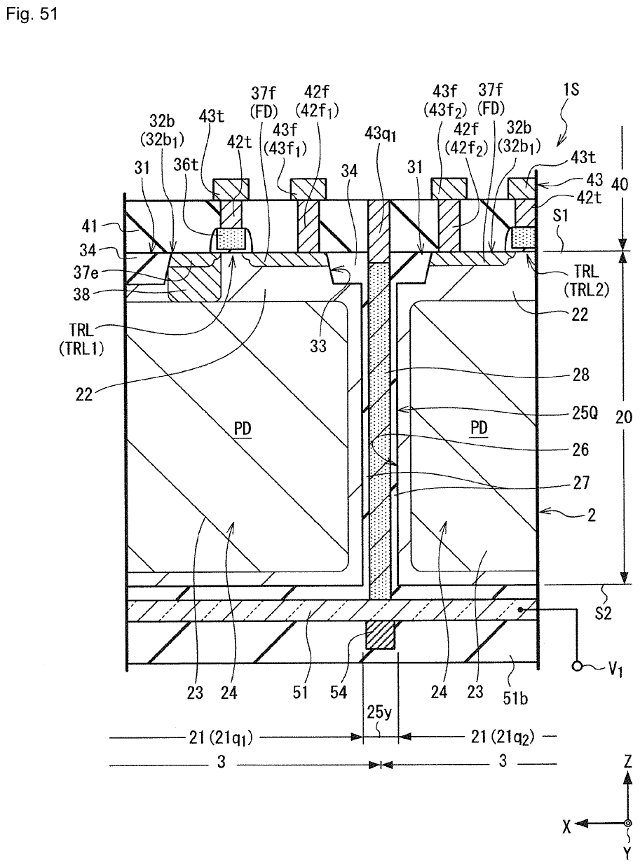

Specifically, as shown in FIG. 51, the solid-state imaging apparatus 1S according to the eighteenth embodiment includes the separation region 25 shown in FIG. 6 of the first embodiment described above in place of the inter-pixel separation region 25Q shown in FIG. 42 of the sixteenth embodiment described above and further includes the transparent electrode 52 shown in FIG. 6. In addition, one end of the contact electrode 42q₁ is electrically and mechanically connected to the conductor 28 of the separation region 25. Furthermore, while the wiring 43q is provided in the sixteenth embodiment described above, even in the present seventeenth embodiment, the wiring 43q shown in FIG. 42 of the sixteenth embodiment described above is not provided in a similar manner to the seventeenth embodiment described above.

Although not illustrated in FIG. 51, even in the solid-state imaging apparatus 1S according to the eighteenth embodiment, the color filter 55 and the microlens 56 shown in FIG. 6 are provided on the side of the light incident surface (the side of the second surface S2) of the semiconductor layer 20.

The first reference potential V₁ is applied to the transparent electrode 52 as a power supply potential (power supply voltage). In addition, the potential of the conductor 28 of the separation region 25 is fixed to the first reference potential V₁ that is applied to the transparent electrode 52. Although not illustrated, for example, the transparent electrode 52 is electrically connected to a power generation circuit (drive circuit) which supplies a constant power supply potential and a power supply potential that is supplied from the power generation circuit is applied to the transparent electrode 52. In the eighteenth embodiment, although not limited thereto, for example, 0 V is applied to the transparent electrode 52 as the first reference potential V₁. The application of the first reference potential V₁ to the transparent electrode 52 and the potential fixing of the first reference potential of the conductor 28 are held during photoelectric conversion by the photoelectric conversion unit 24 or during driving of the pixel transistors (AMP, SEL, RST, FDG, and TRL) included in the readout circuit 15.

The transparent electrode 52 and the conductor 28 of the separation region 25 can be considered (handled) as wirings to which a potential is to be applied. Therefore, the contact electrode 42q₁ according to the eighteenth embodiment is electrically connected to the transparent electrode 52 and the conductor 28 of the separation region 25 to which the power supply potential is to be applied.

As the power supply potential, a second reference potential V₂ that is a positive potential higher than the first reference potential V₁ or a third reference potential V₃ that is a negative potential lower than the first reference potential V₁ may be applied. In addition, the transparent electrode 52 may be configured to be electrically connected to the bonding pad 14 to which the power supply potential is applied from the outside among the plurality of bonding pads 14 shown in FIG. 1.

Even with the solid-state imaging apparatus 1S according to the eighteenth embodiment, similar effects to those of the sixteenth embodiment and the first to sixth modifications of the sixteenth embodiment described above can be obtained.

### Nineteenth Embodiment

A solid-state imaging apparatus 1T according to a nineteenth embodiment of the present technique is basically configured in a similar manner to the solid-state imaging apparatus 1Q according to the sixteenth embodiment described above but differs in a configuration of an element separation region.

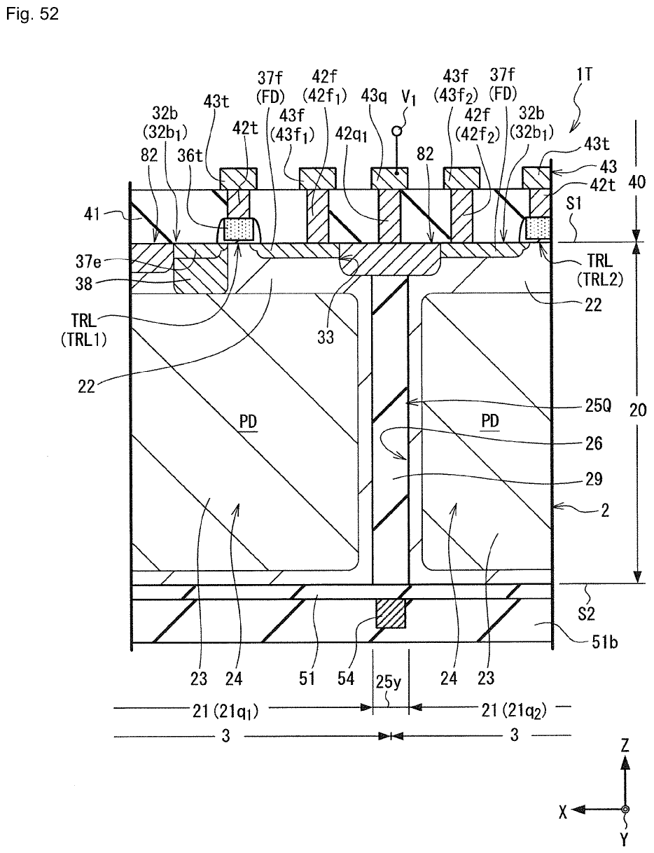

Specifically, as shown in FIG. 52, the solid-state imaging apparatus 1T according to the nineteenth embodiment includes an element separation region 82 constituted of a semiconductor region in place of the element separation region 31 shown in FIG. 42 of the sixteenth embodiment described above. The element separation region 82 is constituted of, for example, a p-type semiconductor region. The element separation region 82 corresponds to a specific example of the “separation region” according to the present technique.

Although not illustrated in FIG. 52, even in the solid-state imaging apparatus 1T according to the nineteenth embodiment, the color filter 55 and the microlens 56 shown in FIG. 42 are provided on the side of the light incident surface (the side of the second surface S2) of the semiconductor layer 20.

In the nineteenth embodiment, one end of the contact electrode 42q₁ is connected to a surface of the element separation region 82 and another end on an opposite side to the one end is electrically and mechanically connected to the wiring 43q. One end of the inter-pixel separation region 25Q is coupled to the element separation region 82 and an opposite side to the one end reaches the side of the second surface S2 of the semiconductor layer 20. The second element formation region 32b and the first element formation region 32a are partitioned by the element separation region 82 and electrically and structurally separated from each other.

While the contact electrode 42q₁ is exemplified in FIG. 52, the other contact electrodes 42q₂ to 42q₆ can also be configured so that one end is connected to the surface of the element separation region 82 and the other end on an opposite side to the one end is electrically and mechanically connected to the respective wirings in a similar manner to the contact electrode 42q₁.

Even with the solid-state imaging apparatus 1T according to the nineteenth embodiment, similar effects to those of the sixteenth embodiment and the first to sixth modifications of the sixteenth embodiment described above can be obtained.

An embedded inter-pixel separation region in which the filling insulating film 29 is embedded in the excavated portion 26 of the semiconductor layer 20 has been described in the sixteenth embodiment described above. However, the present technique can also be applied to cases where a diffused inter-pixel separation region made up of semiconductor regions is used.

In addition, in the sixteenth embodiment described above, the inter-pixel separation region 25Q of which one end is coupled to the element formation region 31 and the opposite side to the one end reaches the second surface S2 of the semiconductor layer 20 has been described. However, the present technique can also be applied in cases where the inter-pixel separation region 25Q is separated from at least one of the element formation region 31 and the second surface S2 of the semiconductor layer 20. Furthermore, while the element separation region 31 has been described as a specific example of the “separation region” according to the present technique in the sixteenth embodiment described above, a combination of the element separation region 31 and the inter-pixel separation region 25Q can be considered (handled) as the “separation region” according to the present technique.

### Twentieth Embodiment

### Example of Application to Electronic Device

The present technique (the technique according to the present disclosure) can be applied to various electronic devices, such as an imaging device such as a digital still camera and a digital video camera, a mobile phone having an imaging function, or other devices having an imaging function.

FIG. 53 is a diagram showing a schematic configuration of an electronic device (for example, a camera) according to a twentieth embodiment of the present technique.

As shown in FIG. 53, an electronic device 200 includes a solid-state imaging apparatus 201, an optical lens 202, a shutter apparatus 203, a drive circuit 204, and a signal processing circuit 205. The electronic device 200 represents an embodiment in which, as the solid-state imaging apparatus 201, the solid-state imaging apparatus according to any one of the first to nineteenth embodiments of the present technique is used in an electronic device (such as a camera).

The optical lens 202 forms an image based on image light (incident light 206) from a subject on an imaging surface of the solid-state imaging apparatus 201. Accordingly, a signal charge is stored for a fixed time period in the solid-state imaging apparatus 201. The shutter apparatus 203 controls a light irradiation period and light-shielding period to the solid-state imaging apparatus 201. The drive circuit 204 supplies drive signals that control a transfer operation of the solid-state imaging apparatus 201 and a shutter operation of the shutter apparatus 203. The drive signal (timing signal) supplied by the drive circuit 204 controls the signal transfer of the solid-state imaging apparatus 201. The signal processing circuit 205 performs various kinds of signal processing on signals (pixel signals) output from the solid-state imaging apparatus 201. An image signal having been subjected to signal processing is stored in a storage medium such as a memory or output to a monitor.

With this configuration, since image quality is improved in the solid-state imaging apparatus 201 in the electronic device 200 according to the twentieth embodiment, image quality can be improved.

The electronic device 200 to which the solid-state imaging apparatuses according to the embodiments described above can be applied is not limited to a camera and the solid-state imaging apparatuses can also be applied to other electronic devices. For example, the solid-state imaging apparatuses may be applied to an imaging apparatus such as a camera module for a mobile device such as a mobile phone or a tablet terminal.

In addition, the present technique can be applied to a general light detection apparatus including a ranging sensor that measures a distance which is also called a time of flight (ToF) sensor and the like in addition to a solid-state imaging apparatus as an image sensor. The ranging sensor is a sensor that emits irradiation light to an object, detects returning reflected light produced by the object by reflecting the irradiation light on a surface thereof, and calculates a distance to the object on the basis of a flight time between emission of the irradiating light and reception of the reflected light. The structure of the element separation region described above can be adopted as a structure of the element separation region of the ranging sensor.

The present technique may also be configured as follows.

(1)

A light detection apparatus, including:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer;
a transistor provided for each of the photoelectric conversion regions on the side of the first surface of the semiconductor layer;
a conductor which is provided in the separation region and which stretches in the thickness direction of the semiconductor layer; and
a transparent electrode which is provided on the side of the second surface of the semiconductor layer, which is electrically connected to the conductor on the side of the second surface of the semiconductor layer, and to which a potential is applied.
   (2)

The light detection apparatus according to (1), wherein the transparent electrode overlaps with the separation region in a plan view.

(3)

The light detection apparatus according to (1) or (2), wherein the transparent electrode is constituted of a solid planar pattern which spreads over the plurality of photoelectric conversion regions in a plan view.

(4)

The light detection apparatus according to (1) or (2), wherein the transparent electrode is constituted of a grid-like planar pattern.

(5)

The light detection apparatus according to (1) or (2), wherein the transparent electrode is constituted of a ring-like planar pattern.

(6)

The light detection apparatus according to (1) or (2), wherein the transparent electrode is constituted of a striped planar pattern.

(7)

The light detection apparatus according to any one of (1) to (6), wherein the conductor is embedded in an excavated portion of the semiconductor layer via a separation insulating film.

(8)

A light detection apparatus, including:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer; and
a transistor provided for each of the photoelectric conversion units on the side of the first surface of the semiconductor layer, wherein
the separation region includes a floating conductor which stretches in the thickness direction of the semiconductor layer and which is in an electrically floating state.
   (9)

The light detection apparatus according to (8), wherein a depth of the floating conductor is 2 μm or more from the first surface of the semiconductor layer.

(10)

The light detection apparatus according to (8) or (9), wherein the floating conductor reaches the second surface of the semiconductor layer.

(11)

The light detection apparatus according to any one of (8) to (10), wherein the floating conductor is separated from the second surface of the semiconductor layer.

(12)

The light detection apparatus according to any one of (8) to (11), wherein the floating conductor is constituted of a conductive semiconductor film or a metal film,

(13)

The light detection apparatus according to any one of (8) to (12), wherein the floating conductor is embedded in an excavated portion of the semiconductor layer via a separation insulating film.

(14)

The light detection apparatus according to any one of (8) to (13), further including a multilayer wiring layer provided on the side of the first surface of the semiconductor layer.

(15)

A light detection apparatus, including:
a semiconductor layer including a first surface and a second surface mutually positioned on opposite sides in a thickness direction; and
a plurality of photoelectric conversion regions provided on the semiconductor layer so as to be adjacent to each other via a separation region that stretches in the thickness direction of the semiconductor layer, wherein each of the plurality of photoelectric conversion regions includes:
a photoelectric conversion unit provided on the semiconductor layer;
a well region provided on the side of the first surface of the semiconductor layer so as to overlap with the photoelectric conversion unit in a plan view; and
a transistor provided in the well region, and
the separation region includes a conductor which stretches in the thickness direction of the semiconductor layer, and
the well region of each of the photoelectric conversion regions which are adjacent to each other via the separation region is electrically connected via the conductor of the separation region.
   (16)

The light detection apparatus according to (15), wherein the conductor is constituted of a semiconductor film of a same conductivity type as the well region.

(17)

The light detection apparatus according to (15) or (16), wherein the conductor includes:
a head portion which is provided on the side of the first surface of the semiconductor layer and which is electrically connected to the well region; and a body portion which protrudes from the head portion with a width narrower than that of the head portion to the side of the second surface of the semiconductor layer.
   (18)

The light detection apparatus according to any one of (15) to (17), wherein the well region is constituted of a first conductivity type, and
the photoelectric conversion region includes:
a first semiconductor region of a second conductivity type; and
a second semiconductor region of a first conductivity type provided between sides of separation regions of the first semiconductor region.
   (19)

The light detection apparatus according to any one of (15) to (18), wherein the plurality of photoelectric conversion regions include:
a first photoelectric conversion region which is provided in the well region and which includes a power feeding contact region to which a potential is applied; and
a second photoelectric conversion region which does not include the power feeding contact region.
   (20)

The light detection apparatus according to any one of (15) to (19), wherein the conductor is electrically connected on the side of the first surface of the semiconductor layer to an electrode to which a potential is applied.

(21)

The light detection apparatus according to any one of (15) to (19), wherein the conductor is electrically connected on the side of the second surface of the semiconductor layer to an electrode to which a potential is applied.

(22)

A light detection apparatus, including:
a semiconductor layer including a first surface and a second surface mutually positioned on opposite sides in a thickness direction; and
a pixel array portion in which a pixel including a photoelectric conversion region partitioned by a separation region that stretches in the thickness direction of the semiconductor layer is arranged in plurality in a two-dimensional planar pattern on the semiconductor layer, wherein
the photoelectric conversion region includes:
a photoelectric conversion unit provided on the semiconductor layer; and
a transistor provided on the side of the first surface of the semiconductor substrate, the separation region includes a conductor which stretches in the thickness direction of the semiconductor layer, and
the conductor is electrically connected via a contact portion to a wiring to which a potential is applied in a periphery of the pixel array portion.
   (23)

The light detection apparatus according to (22), wherein the contact portion is scattered in plurality in a periphery of the pixel array portion.

(24)

The light detection apparatus according to (22) or (23), wherein the contact portion is arranged at a location overlapping with the separation region in a plan view.

(25)

The light detection apparatus according to any one of (22) to (24), wherein
the separation region and the conductor are constituted of a grid-like planar pattern,
the separation region includes a first separation region positioned in a periphery of the pixel array portion and a second separation region positioned further inside from the first separation region, and
the contact portion is respectively arranged at a position overlapping with the first separation region and a position overlapping with the second separation region in a plan view.
   (26)

The light detection apparatus according to any one of (22) to (25), wherein a peripheral well region is provided on the semiconductor layer outside of the pixel array portion, and
the peripheral well region is electrically connected to the wiring.
   (27)

The light detection apparatus according to any one of (22) to (26), further including a multilayer wiring layer which is provided on the side of the first surface of the semiconductor layer and which includes the wiring and the contact portion.

(28)

The light detection apparatus according to any one of (22) to (27), wherein the wiring is provided on the side of the second surface of the semiconductor layer.

(29)

A light detection apparatus, including:
a semiconductor layer including a first surface and a second surface mutually positioned on opposite sides in a thickness direction;
a separation region provided on the semiconductor layer;
first and second transistors of which respective main electrode regions are provided so as to be adjacent to each other via the separation region on the side of the first surface of the semiconductor layer;
an insulating film provided so as to cover the first and second transistors on the side of the first surface of the semiconductor layer;
first and second contact electrodes which are provided on the insulating film and which are respectively individually electrically connected to the respective main electrode regions of the first and second transistors; and
a barrier conductor provided between the first contact electrode and the second contact electrode.
   (30)

The light detection apparatus according to (29), wherein the barrier conductor is electrically connected to a wiring to which a potential is applied.

(31)

The light detection apparatus according to (29) or (30), wherein the barrier conductor is electrically connected to a wiring in an electrically floating state.

(32)

The light detection apparatus according to any one of (29) to (31), wherein the barrier conductor is provided so as to overlap with the separation region.

(33)

The light detection apparatus according to any one of (29) to (32), wherein the barrier conductor crosses between the first contact electrode and the second contact electrode.

(34)

The light detection apparatus according to any one of (29) to (33), further including
a plurality of photoelectric conversion regions partitioned by an inter-pixel separation region which stretches in the thickness direction of the semiconductor layer, wherein the plurality of photoelectric conversion regions include a first photoelectric conversion region provided with the first transistor and a second photoelectric conversion region provided with the second transistor, and
the barrier conductor is constituted of a planar pattern which individually encloses each of the first and second photoelectric conversion regions.
   (35)

The light detection apparatus according to any one of (29) to (34), wherein the barrier conductor is also provided between the main electrode region of the first transistor and the main electrode region of the second transistor.

(36)

The light detection apparatus according to any one of (29) to (35), further including a separating conductor which is provided in the separation region between the main electrode region of the first transistor and the main electrode region of the second transistor and which is electrically connected to the barrier conductor.

(37)

The light detection apparatus according to any one of (29) to (36), wherein the separation region is an element separation region provided on the side of the first surface of the semiconductor layer.

(38)

The light detection apparatus according to any one of (29) to (36), wherein the separation region includes an element separation region which is provided on the side of the first surface of the semiconductor layer and an inter-pixel separation region which stretches from the element separation region toward the side of the second surface of the semiconductor layer.

(39)

An electronic device including: the light detection apparatus according to any one of (1), (8), (15), (22), and (29); an optical lens configured to form an image of image light from a subject on an imaging surface of the light detection apparatus; and a signal processing circuit configured to perform signal processing on a signal output from the light detection apparatus.

The scope of the present technology is not limited to the illustrated and described exemplary embodiments, but includes all embodiments that provide equivalent effects sought after with the present technology. In addition, the scope of the present technology is not limited to combinations of features of the invention defined by the claims, but can be defined by any desired combination of specific features among all disclosed features.

The scope of the present technology is not limited to the illustrated and described exemplary embodiments, but includes all embodiments that provide equivalent effects sought after with the present technology. In addition, the scope of the present technology is not limited to combinations of features of the invention defined by the claims, but can be defined by any desired combination of specific features among all disclosed features.

### REFERENCE SIGNS LIST

1A, 1B, 1C, 1D, 1E, 1F, 1G, 1H, 1I, 1J, 1K, 1L, 1M, 1N, 1P, 1Q, 1R, 1S, 1T Solid-state imaging apparatus
2 Semiconductor chip
2A Pixel array portion
2B Peripheral portion
3 Pixel
4 Vertical drive circuit
5 Column signal processing circuit
6 Horizontal drive circuit
7 Output circuit
8 Control circuit
10 Pixel drive line
11 Vertical signal line
13 Logic circuit
14 Bonding pad
15 Readout circuit
16a First pixel block
16b Second pixel block
20 Semiconductor layer
21, 21D, 21q₁, 21q₂ Photoelectric conversion region
22, 22d p-type well region
23 n-type semiconductor region
24 Photoelectric conversion unit
25, 25C, 25D, 25E, 25F, 25G, 25J, 25M Separation region
25Q Inter-pixel separation region
25x First portion
25y Second portion
26 Excavated portion
27 Separation insulating film
28 Conductor
31 Separation region (element separation region)
32a, 32b, 32c First to third element formation regions
32z Power feeding region
33 Groove portion
34 Insulating film (embedded insulating film)
35 Gate insulating film
36a, 36f, 36r, 36s, 36t, 36v Gate electrode
37b, 37c, 37d, 37e, 37f Main electrode region
37z Power feeding contact region
38 Relay region (n-type semiconductor region)
40 Multilayer wiring layer
41 Interlayer insulating film
42a, 42c, 42c₁, 42c₂, 42d, 42f, 42f₁, 42f₂, 42s, 42t, 42q₁ to 42q₆ Contact electrode
42z Power feeding contact electrode
43 First wiring layer
43a, 43c, 43c₁, 43c₂, 43d, 43f, 43f₁, 43f₂, 43s, 43t, 43q Wiring
43z Power feeding wiring
44 Interlayer insulating film
44b Power feeding contact electrode
45a Wiring
45b Power feeding wiring
45c Power feeding wiring
47a Wiring
48 Protective film
50 Supporting substrate
51 Insulating film
51a Tunnel insulating film
51b Insulating film
52 Transparent electrode
52a Solid planar pattern
53b₁ Grid-like planar pattern
53b₂ Ring-like planar pattern
53b₃, 53b₄ Striped planar pattern
54 Light-shielding film
55 Color filter
56 Microlens
61 Separation region
61a Non-conductor (non-doped silicon film)
61b Conductive portion (doped silicon film)
61c p-type conductive portion
62a₁, 62b₁ First parasitic capacitance
62a2, 62b2 Second parasitic capacitance
62b₃ Third parasitic capacitance
63 Capacitive coupling
64 Floating conductor
64a n-type silicon film
64b p-type silicon film
64c Metal film
65 n-type semiconductor region
66 Conductor
66a p-type silicon film
67 Separation region
68 Non-doped silicon film
70 p-type semiconductor region
71a Non-conductor
71b Conductor
72a First conductor 72b Second conductor
73 Conductor
73a Head portion
73b Body portion
74 Power feeding wiring
74a Power feeding contact portion
81 Embedded conductor
82 Element separation region

1. A light detection apparatus, comprising:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer;
a transistor provided for each of the photoelectric conversion regions on the side of the first surface of the semiconductor layer;
a conductor which is provided in the separation region and which stretches in the thickness direction of the semiconductor layer; and
a transparent electrode which is provided on the side of the second surface of the semiconductor layer, which is electrically connected to the conductor on the side of the second surface of the semiconductor layer, and to which a potential is applied.

2. The light detection apparatus according to claim 1, wherein the transparent electrode overlaps with the separation region in a plan view.

3. The light detection apparatus according to claim 1, wherein the transparent electrode is constituted of a solid planar pattern which spreads over the plurality of photoelectric conversion regions in a plan view.

4. The light detection apparatus according to claim 1, wherein the transparent electrode is constituted of a grid-like planar pattern.

5. The light detection apparatus according to claim 1, wherein the transparent electrode is constituted of a ring-like planar pattern.

6. The light detection apparatus according to claim 1, wherein the transparent electrode is constituted of a striped planar pattern.

7. The light detection apparatus according to claim 1 wherein the conductor is embedded in an excavated portion of the semiconductor layer via a separation insulating film.

8. A light detection apparatus, comprising:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer; and
a transistor provided for each of the photoelectric conversion units on the side of the first surface of the semiconductor layer, wherein
the separation region includes a floating conductor which stretches in the thickness direction of the semiconductor layer and which is in an electrically floating state.

9. The light detection apparatus according to claim 8, wherein a depth of the floating conductor is 2 μm or more from the first surface of the semiconductor layer.

10. The light detection apparatus according to claim 8, wherein the floating conductor reaches the second surface of the semiconductor layer.

11. The light detection apparatus according to claim 8, wherein the floating conductor is separated from the second surface of the semiconductor layer.

12. The light detection apparatus according to claim 8, wherein the floating conductor is constituted of a conductive semiconductor film or a metal film.

13. The light detection apparatus according to claim 11, wherein the floating conductor is embedded in an excavated portion of the semiconductor layer via a separation insulating film.

14. The light detection apparatus according to claim 8, further comprising a multilayer wiring layer provided on the side of the first surface of the semiconductor layer 20.

15. A light detection apparatus, comprising:
a semiconductor layer including a first surface and a second surface mutually positioned on opposite sides in a thickness direction; and
a plurality of photoelectric conversion regions provided on the semiconductor layer so as to be adjacent to each other via a separation region that stretches in the thickness direction of the semiconductor layer, wherein
each of the plurality of photoelectric conversion regions includes:
a photoelectric conversion unit provided on the semiconductor layer; and
a well region provided on the side of the first surface of the semiconductor layer so as to overlap with the photoelectric conversion unit in a plan view; and
a transistor provided in the well region, and
the separation region includes a conductor which stretches in the thickness direction of the semiconductor layer, and
the well region of each of the photoelectric conversion regions which are adjacent to each other via the separation region is electrically connected via the conductor of the separation region.

16. The light detection apparatus according to claim 15, wherein the conductor is constituted of a semiconductor film of a same conductivity type as the well region.

17. The light detection apparatus according to claim 15, wherein the conductor includes: a head portion which is provided on the side of the first surface of the semiconductor layer and which is electrically connected to the well region; and a body portion which protrudes from the head portion with a width narrower than that of the head portion to the side of the second surface of the semiconductor layer.

18. The light detection apparatus according to claim 15, wherein
the well region is constituted of a first conductivity type, and
the photoelectric conversion region includes:
a first semiconductor region of a second conductivity type; and
a second semiconductor region of a first conductivity type provided between sides of separation regions of the first semiconductor region.

19. The light detection apparatus according to claim 15, wherein
the plurality of photoelectric conversion regions include:
a first photoelectric conversion region which is provided in the well region and which includes a power feeding contact region to which a potential is applied; and
a second photoelectric conversion region which does not include the power feeding contact region.

20. The light detection apparatus according to claim 15, wherein the conductor is electrically connected on the side of the first surface of the semiconductor layer to an electrode to which a potential is applied.

21. The light detection apparatus according to claim 15, wherein the conductor is electrically connected on the side of the second surface of the semiconductor layer to an electrode to which a potential is applied.

22. A light detection apparatus, comprising:
a semiconductor layer including a first surface and a second surface mutually positioned on opposite sides in a thickness direction; and
a pixel array portion in which a pixel including a photoelectric conversion region partitioned by a separation region that stretches in the thickness direction of the semiconductor layer is arranged in plurality in a two-dimensional planar pattern on the semiconductor layer, wherein
the photoelectric conversion region includes:
a photoelectric conversion unit provided on the semiconductor layer; and
a transistor provided on the side of the first surface of the semiconductor substrate,
the separation region includes a conductor which stretches in the thickness direction of the semiconductor layer, and
the conductor is electrically connected via a contact portion to a wiring to which a potential is applied in a periphery of the pixel array portion.

23. The light detection apparatus according to claim 22, wherein the contact portion is scattered in plurality in a periphery of the pixel array portion.

24. The light detection apparatus according to claim 22, wherein the contact portion is arranged at a location overlapping with the separation region in a plan view.

25. The light detection apparatus according to claim 22, wherein
the separation region and the conductor are constituted of a grid-like planar pattern,
the separation region includes a first separation region positioned in a periphery of the pixel array portion and a second separation region positioned further inside from the first separation region, and
the contact portion is respectively arranged at a position overlapping with the first separation region and a position overlapping with the second separation region in a plan view.

26. The light detection apparatus according to claim 22, wherein
a peripheral well region is provided on the semiconductor layer outside of the pixel array portion, and
the peripheral well region is electrically connected to the wiring.

27. The light detection apparatus according to claim 22, further comprising a multilayer wiring layer which is provided on the side of the first surface of the semiconductor layer and which includes the wiring and the contact portion.

28. The light detection apparatus according to claim 22, wherein the wiring is provided on the side of the second surface of the semiconductor layer.

29. A light detection apparatus, comprising:
a semiconductor layer including a first surface and a second surface mutually positioned on opposite sides in a thickness direction;
a separation region provided on the semiconductor layer;
first and second transistors of which respective main electrode regions are provided so as to be adjacent to each other via the separation region on the side of the first surface of the semiconductor layer;
an insulating film provided so as to cover the first and second transistors on the side of the first surface of the semiconductor layer;
first and second contact electrodes which are provided on the insulating film and which are respectively individually electrically connected to the respective main electrode regions of the first and second transistors; and
a barrier conductor provided between the first contact electrode and the second contact electrode.

30. The light detection apparatus according to claim 29, wherein the barrier conductor is electrically connected to a wiring to which a potential is applied.

31. The light detection apparatus according to claim 29, wherein the barrier conductor is electrically connected to a wiring in an electrically floating state.

32. The light detection apparatus according to claim 29, wherein the barrier conductor is provided so as to overlap with the separation region.

33. The light detection apparatus according to claim 29, wherein the barrier conductor crosses between the first contact electrode and the second contact electrode.

34. The light detection apparatus according to claim 29, further comprising
a plurality of photoelectric conversion regions partitioned by an inter-pixel separation region which stretches in the thickness direction of the semiconductor layer, wherein
the plurality of photoelectric conversion regions include a first photoelectric conversion region provided with the first transistor and a second photoelectric conversion region provided with the second transistor, and
the barrier conductor is constituted of a planar pattern which individually encloses each of the first and second photoelectric conversion regions.

35. The light detection apparatus according to claim 29, wherein the barrier conductor is also provided between the main electrode region of the first transistor and the main electrode region of the second transistor.

36. The light detection apparatus according to claim 29, further comprising a separating conductor which is provided in the separation region between the main electrode region of the first transistor and the main electrode region of the second transistor and which is electrically connected to the barrier conductor.

37. The light detection apparatus according to claim 29, wherein the separation region is an element separation region provided on the side of the first surface of the semiconductor layer.

38. The light detection apparatus according to claim 29, wherein the separation region includes an element separation region which is provided on the side of the first surface of the semiconductor layer and an inter-pixel separation region which stretches from the element separation region toward the side of the second surface of the semiconductor layer.

39. An electronic device, comprising: a light detection apparatus; an optical lens configured to form an image of image light from a subject on an imaging surface of the light detection apparatus; and a signal processing circuit configured to perform signal processing on a signal output from the light detection apparatus, wherein
the light detection apparatus includes:
a semiconductor layer including a first surface and a second surface mutually positioned on opposite sides in a thickness direction;
a plurality of photoelectric conversion regions provided on the semiconductor layer so as to be adjacent to each other via a separation region that stretches in the thickness direction of the semiconductor layer;
a transistor provided for each of the photoelectric conversion regions on the side of the first surface of the semiconductor layer;
a conductor which is provided in the separation region and which stretches in the thickness direction of the semiconductor layer; and
a transparent electrode which is provided on the side of the second surface of the semiconductor layer, which is electrically connected to the conductor on the side of the second surface of the semiconductor layer, and to which a potential is applied.
